(19) United States
(12) Patent Application Publication
(10) Pub. No.: US 2026/0063993 A1
(43) Pub. Date: Mar. 5, 2026

(54) RESIST COMPOSITION, LAMINATE, AND PATTERNING PROCESS

(71) Applicant: SHIN-ETSU CHEMICAL CO., LTD., Tokyo (JP)

(72) Inventors: Satoshi KUSAMA, Joetsu-shi (JP); Kousuke OHYAMA, Joetsu-shi (JP); Shun KIKUCHI, Joetsu-shi (JP); Ryo NISHIKAWA, Joetsu-shi (JP); Masaki OHASHI, Joetsu-shi (JP)

(73) Assignee: SHIN-ETSU CHEMICAL CO., LTD., Tokyo (JP)

(21) Appl. No.: 19/316,207

(22) Filed: Sep. 2, 2025

(30) Foreign Application Priority Data
Sep. 3, 2024 (JP) 2024-151803

(51) Int. Cl. G03F 7/004; C09D 173/00; G03F 7/00; G03F 7/038; G03F 7/039; G03F 7/095; G03F 7/30

(52) U.S. Cl. CPC G03F 7/0045; C09D 173/00; G03F 7/0046; G03F 7/0388; G03F 7/039; G03F 7/095; G03F 7/30; G03F 7/70033; G03F 7/70383

(57) ABSTRACT

A resist composition including a hypervalent iodine compound represented by formula (1), a carboxy group-containing compound, and a solvent. In formula (1), “n” represents an integer of 0 to 4 when “m” is 0, an integer of 0 to 6 when “m” is 1, and an integer of 0 to 8 when “m” is 2; R¹, R², and R³ represent a halogen atom or a hydrocarbyl group having 1 to 10 carbon atoms; R⁴ represents a halogen atom or a hydrocarbyl group having 1 to 40 carbon atoms; R⁵ represents a carbonyl group or a hydrocarbylene group having 1 to 10 carbon atom; and I and R⁵ are bonded to adjacent carbon atoms of aromatic ring. This can provide: a resist composition that exhibits excellent sensitivity and resolution in photolithography using a high-energy beam, particularly in electron beam (EB) lithography and EUV lithography; and a patterning process using resist composition.

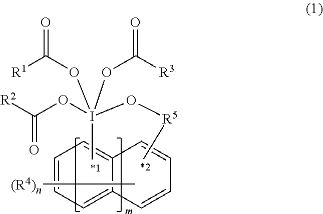

### TECHNICAL FIELD

The present invention relates to: a resist composition; a laminate; and a patterning process using the resist composition.

### BACKGROUND ART

With the expansion of the IoT market, further demands are being placed on LSI for higher integration density, faster speeds, and lower power consumption, resulting in rapid miniaturization of its patterning rules. In particular, logic devices drive the miniaturization. As the advanced miniaturization technology, devices of 10-nm node are manufactured in a mass scale by the double, triple, or quadro-patterning version of immersion ArF lithography. Furthermore, a study of 7-nm node devices by the next-generation extreme ultraviolet ray (EUV) lithography of 13.5 nm wavelength has been started.

As the miniaturization advances, image blurs due to acid diffusion are regarded as a problem (Non Patent Document 1). In order to ensure resolution of fine patterns with a critical dimension of 45 nm or less, it is suggested that not only the enhancement of dissolution contrast, which has been proposed previously, but also controlling of the acid diffusion is important (Non Patent Document 2). However, sensitivity and contrast of chemically amplified resist compositions are enhanced by the acid diffusion. Accordingly, an attempt to minimize the acid diffusion to the limits by lowering temperature of post-exposure baking (PEB) or shortening the PEB time lowers the sensitivity and contrast markedly.

It is effective to control the acid diffusion by adding an acid generator that generates a bulky acid. Accordingly, it has been proposed to copolymerize a polymer with an acid generator in the form of an onium salt having polymerizable olefin. In patterning resist films with a critical dimension of 16 nm or less, however, it is considered that patterning is impossible with chemically amplified resist compositions in view of the acid diffusion. Therefore, it is desired to develop a non-chemically amplified resist composition.

Examples of materials for the non-chemically amplified resist composition include polymethyl methacrylate (PMMA). PMMA is a positive-type resist material whose solubility in an organic solvent developer increases due to decreased molecular weight caused by scission of the main chain by EUV irradiation.

Hydrogensilsesquioxane (HSQ) is a negative-type resist material which turns insoluble in an alkaline developer through crosslinking by a condensation reaction of silanol generated by EUV irradiation. Calixarene substituted with chlorine also functions as a negative-type resist material. These negative-type resist materials have a small molecular size prior to crosslinking and are free from causing blurs due to acid diffusion, and therefore, exhibit smaller edge roughness and very high resolution. Accordingly, such materials have been used as a pattern transfer material to show a resolution limit of an exposure apparatus. These materials, however, are insufficient in sensitivity, and further improvement is required.

The small number of photons in EUV exposure is a factor that causes difficulties in developing a material for EUV lithography. The energy of EUV is much higher than that of an ArF excimer laser beam, and the number of photons in EUV exposure is 1/14 of that of ArF exposure. Furthermore, the size of the pattern formed by EUV exposure is half of that by ArF exposure or less. Therefore, EUV exposure is easily affected by variation in the number of photons. The variation in the number of photons in a radiation light region of extremely short wavelengths is a physical phenomenon of shot noise, and it is impossible to eliminate the influence of the variation. Therefore, so-called probability theory (stochastics) is attracting attention. The influence of the shot noise cannot be eliminated, but how to reduce this influence is under discussion. The influence of the shot noise not only increases the critical dimension uniformity (CDU), but also is observed to cause a phenomenon of blocking a hole at a probability of one to several millions. If a hole gets blocked, conduction failure occurs and a transistor does not function, and the performance of the entire device is adversely affected. Considering sensitivity in practical terms, resist compositions that mainly contain PMMA or HSQ are greatly affected by stochastics, and cannot achieve the desired resolution performance.

The introduction of an element that greatly absorbs EUV light is attracting attention as a means for reducing the influence of the shot noise on the side of the resist. Patent Document 1 proposes a chemically amplified resist composition containing a tin compound that greatly absorbs EUV light. As mentioned above, however, the chemically amplified resist composition cannot achieve excellent resolution performance in EUV lithography in which the critical dimension is expected to increasingly miniaturized.

Patent Document 2 proposes a negative-type resist composition using a tin compound. Because this composition contains tin, which has high absorption of EUV light, as its main component, it improves stochastics and can achieve high sensitivity and high resolution. However, this type of metal resist has many issues, such as insufficient solubility in a resist solvent, storage stability, and defects due to etching residues.

In response to this, Patent Document 3 proposes a positive-type resist composition using a hypervalent iodine compound. Because this composition contains iodine, which has high absorption of EUV light, it exhibits improved stochastics, similar to metal resists, and can achieve high sensitivity and high resolution. Furthermore, because it is composed solely of organic molecules, it can improve the defects associated with metal resists, such as solubility in a developer and residue-related defects. However, its performance as a resist material is still unsatisfactory, and there is a demand to develop resist materials that are useful for even finer patterning.

### CITATION LIST

### Patent Literature

Patent Document 1: JP2018-5224A
Patent Document 2: JP2021-503482A
Patent Document 3: JP2023-167368A

### Non Patent Literature

Non Patent Document 1: SPIE Vol. 5039 p 1 (2003)
Non Patent Document 2: SPIE Vol. 6520 p 65203L-1 (2007)

### SUMMARY OF INVENTION

### Technical Problem

The present invention has been made in view of the above circumstances, and objects of the present invention is to provide: a resist composition that exhibits excellent sensitivity and resolution in photolithography using a high-energy beam, particularly in electron beam (EB) lithography and EUV lithography; a laminate using the resist composition; and a patterning process.

### Solution to Problem

To solve the problems above, the present invention provides a resist composition comprising a hypervalent iodine compound represented by the following formula (1), a carboxy group-containing compound, and a solvent,

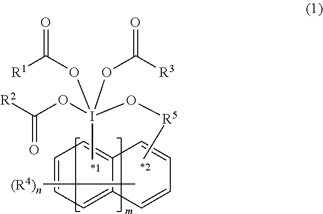

wherein “m” represents an integer of 0 to 2; “n” represents an integer of 0 to 4 when “m” is 0, an integer of 0 to 6 when “m” is 1, and an integer of 0 to 8 when “m” is 2; R¹, R², and R³ represent each independently a halogen atom or a hydrocarbyl group having 1 to 10 carbon atoms and optionally having a heteroatom, and R¹, R², and R³ may be bonded to each other to form a ring; R⁴ represents a halogen atom or a hydrocarbyl group having 1 to 40 carbon atoms and optionally having a heteroatom, R⁴s may be identical to or different from each other when “n” is 2 or greater, and a plurality of R⁴s may be bonded to each other to form a ring together with the carbon atoms of the aromatic ring bonded thereto; R⁵ represents a carbonyl group or a hydrocarbylene group having 1 to 10 carbon atoms and optionally having a heteroatom; and *1 and *2 represent an attachment point to a carbon atom of the aromatic ring in the formula, and *1 and *2 are bonded to adjacent carbon atoms of the aromatic ring.

The inventive resist composition exhibits excellent sensitivity and resolution in photolithography using a high-energy beam, particularly in electron beam (EB) lithography and EUV lithography.

In the present invention, the carboxy group-containing compound may be one or both of a polymer having a repeating unit represented by the following formula (2) and a compound represented by the following formula (3),

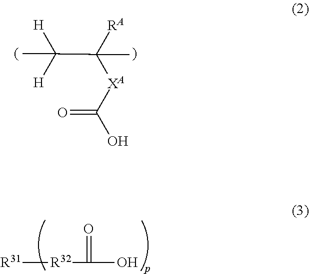

wherein R^{A} represents a hydrogen atom, a halogen atom, a methyl group, or a trifluoromethyl group; X^{A} represents a single bond, a phenylene group, a naphthylene group, or *—C(═O)—O—X^{A1}—, X^{A1} represents a saturated hydrocarbylene group, a phenylene group, or a naphthylene group, each having 1 to 10 carbon atoms, the saturated hydrocarbylene group may have a hydroxy group, an ether bond, an ester bond, or a lactone ring, and “*” represents an attachment point to a carbon atom of the main chain; “p” represents 1, 2, 3, or 4; R³¹ represents a p-valent hydrocarbon group having 1 to 40 carbon atoms or a p-valent heterocyclic group having 2 to 40 carbon atoms, and when “p” is 2, R³¹ may be an ether bond, a carbonyl group, an azo group, a thioether bond, a carbonate bond, a carbamate bond, a sulfinyl group, or a sulfonyl group; part or all of the hydrogen atoms of the p-valent hydrocarbon group or p-valent heterocyclic group may be substituted with a group having a heteroatom, and part of the —CH₂— of the p-valent hydrocarbon group may be substituted with a group having a heteroatom; R³² is a single bond or a hydrocarbylene group having 1 to 20 carbon atoms, and part or all of the hydrogen atoms of the hydrocarbylene group may be substituted with a group having a heteroatom, or part of the —CH₂— of the hydrocarbylene group may be substituted with a group having a heteroatom; and when “p” is 2, 3, or 4, R³²s may be identical to or different from each other.

The carboxy group-containing compound contained in the inventive resist composition is preferably such a polymer or low-molecular compound.

The inventive resist composition preferably further comprises at least one kind of hypervalent iodine compounds represented by the following formula (4) or (5),

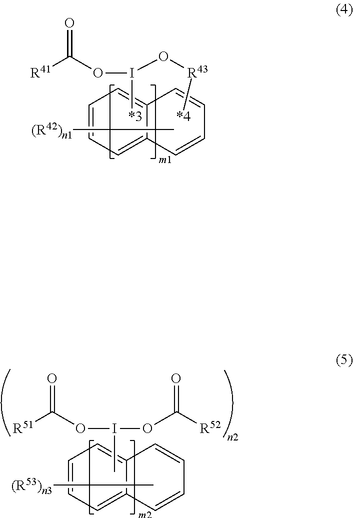

wherein m1 and m2 represent integers from 0 to 2; n1 represents an integer from 0 to 4 when m1 is 0, an integer from 0 to 6 when m1 is 1, and an integer from 0 to 8 when m1 is 2; when m2 is 0, n2 represents an integer from 1 to 3, n3 represents an integer from 0 to 5, and 1≤(n2+n3)≤6 is satisfied, when m2 is 1, n2 represents an integer from 1 to 3, and n3 represents an integer from 0 to 7, and 1≤(n2+n3)≤8 is satisfied, and when m2 is 2, n2 represents an integer from 1 to 3, and n3 represents an integer from 0 to 9, and 1≤(n2+n3)≤10 is satisfied; R⁴¹ represents a halogen atom or a hydrocarbyl group having 1 to 10 carbon atoms and optionally having a heteroatom; R⁴² represents a halogen atom or a hydrocarbyl group having 1 to 40 carbon atoms and optionally having a heteroatom, R⁴²s may be identical to or different from each other when n1 is 2 to 6, and a plurality of R⁴²s may be bonded to each other to form a ring together with the carbon atoms of the aromatic ring bonded thereto; R⁴³ is a carbonyl group or a hydrocarbylene group having 1 to 10 carbon atoms and optionally having a heteroatom; *3 and *4 represent an attachment point to a carbon atom of the aromatic ring in the formula, and *3 and *4 must be bonded to adjacent carbon atoms of the aromatic ring; R⁵¹ and R⁵² represent each independently a halogen atom or a hydrocarbyl group having 1 to 10 carbon atoms and optionally having a heteroatom, R⁵¹ and R⁵² may be bonded to each other to form a ring together with the carbon atoms bonded thereto and with an atom between the carbon atoms, and when n2 is 2 to 3, R⁵¹ and R⁵² may be identical to or different from each other; R⁵³ represents a halogen atom or a hydrocarbyl group having 1 to 40 carbon atoms and optionally having a heteroatom, R⁵³s may be identical to or different from each other when n3 is 2 to 9, and a plurality of R⁵³s may be bonded to each other to form a ring together with the carbon atoms of the aromatic ring bonded thereto.

In the present invention, by including at least one hypervalent iodine compound having such I(III), the reactivity of the composition to light can be controlled and the sensitivity can be adjusted.

Further, the present invention provides a laminate comprising a substrate and a resist film which is a film made of the resist composition formed on the substrate.

The laminate having a resist film obtained from the inventive resist composition has a wide range of uses and is highly useful for resist process technology, since the resist film, which is a film made of the above resist composition, has high sensitivity and exhibits excellent resolution, and is effective for precise fine processing and also applicable both positive and negative patterning.

In this event, the laminate further comprises a resist underlayer film between the substrate and the resist film. The resist film preferably contains a product of a ligand exchange reaction between the hypervalent iodine compound and the carboxy group-containing compound.

The inventive laminate can be configured in such a manner as required.

Further, the present invention provides a patterning process comprising steps of:
forming a resist film on a substrate or on a resist underlayer film of a substrate having a resist underlayer film laminated thereon, using the above resist composition; exposing the resist film by a high-energy beam; and developing the exposed resist film by using a developer.

The inventive patterning process uses a resist composition that exhibits excellent sensitivity and resolution in photolithography using a high-energy beam, particularly in electron beam (EB) lithography and EUV lithography, and is therefore useful for forming even finer patterns.

In this event, an i-line, a KrF excimer laser beam, an ArF excimer laser beam, an electron beam, or an extreme ultraviolet ray is preferably used as the high-energy beam.

The inventive patterning process makes it possible to form even finer patterns by using such a high-energy beam.

In the inventive patterning process, as the developer mentioned above, it is possible to use one that dissolves exposed areas and does not dissolve unexposed areas, and also one that dissolves unexposed areas and does not dissolve exposed areas.

The inventive patterning process can form positive or negative patterns by appropriately selecting a developer, and can therefore be widely applied to the formation of various fine patterns.

### Advantageous Effects of Invention

The inventive resist composition achieves both high sensitivity and high resolution, and is extremely useful for forming fine patterns, particularly in EB lithography and EUV lithography.

### DESCRIPTION OF EMBODIMENTS

As a result of their diligent study to achieve the above objects, the inventors found that resist compositions mainly containing a specific hypervalent iodine compound and a carboxy group-containing compound (polymer or low-molecular compound) provide a resist film that exhibit extremely high sensitivity and excellent resolution, resulting in being extremely effective for precise fine processing, and have completed the present invention.

That is, the present invention is a resist composition comprising a hypervalent iodine compound represented by the following formula (1), a carboxy group-containing compound, and a solvent,

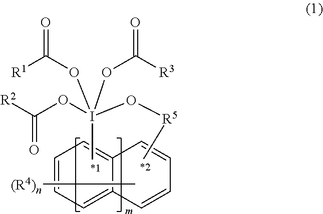

wherein “m” represents an integer of 0 to 2; “n” represents an integer of 0 to 4 when “m” is 0, an integer of 0 to 6 when “m” is 1, and an integer of 0 to 8 when “m” is 2; R¹, R², and R³ represent each independently a halogen atom or a hydrocarbyl group having 1 to 10 carbon atoms and optionally having a heteroatom, and R¹, R², and R³ may be bonded to each other to form a ring; R⁴ represents a halogen atom or a hydrocarbyl group having 1 to 40 carbon atoms and optionally having a heteroatom, R⁴s may be identical to or different from each other when “n” is 2 or greater, and a plurality of R⁴s may be bonded to each other to form a ring together with the carbon atoms of the aromatic ring bonded thereto; R⁵ represents a carbonyl group or a hydrocarbylene group having 1 to 10 carbon atoms and optionally having a heteroatom; and *1 and *2 represent an attachment point to a carbon atom of the aromatic ring in the formula, and *1 and *2 are bonded to adjacent carbon atoms of the aromatic ring.

Hereinafter, embodiments of the present invention will be described in detail. However, the present invention is not limited thereto. In this description, numerical ranges by endpoints are intended to include all values subsumed within that range (e.g., “0 to 3” includes 0, 1, 2, and 3).

### [Resist Composition]

The inventive resist composition, as main components, a predetermined hypervalent iodine compound, a carboxy group-containing compound, and a solvent.

### [Hypervalent Iodine Compound]

A hypervalent iodine compound is a general term used to refer to iodine compounds that have valence electrons beyond the octet rule formally. Examples include tricoordinate iodine compounds (iodine(III) compounds) with an oxidation number of +3 and pentacoordinate iodine compounds (iodine(V) compounds) with an oxidation number of +5.

The hypervalent iodine compound as the main component of the inventive resist composition is a pentacoordinate hypervalent iodine compound represented by the following formula (1).

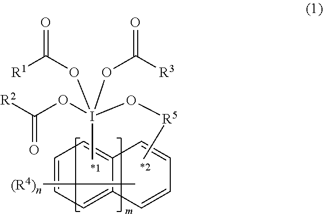

wherein “m” represents an integer of 0 to 2; “n” represents an integer of 0 to 4 when “m” is 0, an integer of 0 to 6 when “m” is 1, and an integer of 0 to 8 when “m” is 2; R¹, R², and R³ represent each independently a halogen atom or a hydrocarbyl group having 1 to 10 carbon atoms and optionally having a heteroatom, and R¹, R², and R³ may be bonded to each other to form a ring; R⁴ represents a halogen atom or a hydrocarbyl group having 1 to 40 carbon atoms and optionally having a heteroatom, R⁴s may be identical to or different from each other when “n” is 2 or greater, and a plurality of R⁴s may be bonded to each other to form a ring together with the carbon atoms of the aromatic ring bonded thereto; R⁵ represents a carbonyl group or a hydrocarbylene group having 1 to 10 carbon atoms and optionally having a heteroatom; and *1 and *2 represent an attachment point to a carbon atom of the aromatic ring in the formula, and *1 and *2 are bonded to adjacent carbon atoms of the aromatic ring.

In the formula (1), “m” represents an integer of 0 to 2. “n” represents an integer of 0 to 4 when “m” is 0, an integer of 0 to 6 when “m” is 1, and an integer of 0 to 8 when “m” is 2. “n” is preferably 0 to 8, more preferably 0 to 6, further preferably 0 to 4, even further preferably an integer of 0 to 2, and most preferably 0 or 1. When m is 0, the aromatic ring is a benzene ring.

In the general formula (1), R¹, R², and R³, each independently represents a halogen atom or a hydrocarbyl group having 1 to 10 carbon atoms and optionally having a heteroatom. Specific examples of the halogen atom include a fluorine atom, a chlorine atom, a bromine atom, and an iodine atom. The hydrocarbyl group having 1 to 10 carbon atoms may be saturated or unsaturated, and may be linear, branched, or cyclic. Specific examples thereof include: alkyl groups having 1 to 10 carbon atoms, such as a methyl group, an ethyl group, an n-propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 10 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, and an adamantyl group; alkenyl groups having 2 to 10 carbon atoms, such as a vinyl group and an allyl group; aryl groups having 6 to 10 carbon atoms, such as a phenyl group and a naphthyl group; and groups obtained by combining these groups. Furthermore, part or all of the hydrogen atoms of the hydrocarbyl groups may be substituted with a group having a heteroatom, such as an oxygen atom, a sulfur atom, a nitrogen atom, or a halogen atom, and part of the —CH₂— of the hydrocarbyl groups may be substituted with a group having a heteroatom, such as an oxygen atom, a sulfur atom, or a nitrogen atom. The resulting hydrocarbyl groups may have a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc. As R¹, a hydrocarbyl group having 1 to 4 carbon atoms or a fluorinated hydrocarbyl group having 1 to 4 carbon atoms is preferable, and a hydrocarbyl group having 1 to 4 carbon atoms is more preferable.

In the general formula (1), R⁴ represents a halogen atom or a hydrocarbyl group having 1 to 40 carbon atoms and optionally having a heteroatom. Specific examples of the halogen atom include a fluorine atom, a chlorine atom, a bromine atom, and an iodine atom. The hydrocarbyl group having 1 to 40 carbon atoms may be saturated or unsaturated, and may be linear, branched, or cyclic. Specific examples thereof include: alkyl groups having 1 to 40 carbon atoms, such as a methyl group, an ethyl group, an n-propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; and aryl groups having 6 to 40 carbon atoms, such as a phenyl group, a naphthyl group, and an anthracenyl group. Furthermore, part or all of the hydrogen atoms of the hydrocarbyl groups may be substituted with a group having a heteroatom, such as an oxygen atom, a sulfur atom, a nitrogen atom, or a halogen atom, and part of the —CH₂— of the hydrocarbyl groups may be substituted with a group having a heteroatom, such as an oxygen atom, a sulfur atom, or a nitrogen atom. The resulting hydrocarbyl groups may have a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc. When “n” is 2 or more, R⁴s may be identical to or different from each other, and a plurality of R⁴s may be bonded to each other to form a ring together with the carbon atoms of the aromatic ring bonded thereto. R⁴ can substitute at any position on the aromatic ring in the formula (1).

In the general formula (1), R⁵ represents a carbonyl group or a hydrocarbylene group having 1 to 10 carbon atoms and optionally having a heteroatom. The hydrocarbylene group having 1 to 10 carbon atoms may be saturated or unsaturated, and may be linear, branched, or cyclic. Specific examples thereof include: alkylene groups having 1 to 10 carbon atoms, such as a methanediyl group, an ethane-1,1-diyl group, an ethane-1,2-diyl group, a propane-1,1-diyl group, a propane-1,2-diyl group, a propane-1,3-diyl group, a propane-2,2-diyl group, a butane-2,3-diyl group, a butane-1,4-diyl group, a 2-methylpropane-1,2-diyl group, a pentane-1,5-diyl group, a hexane-1,6-diyl group, a heptane-1,7-diyl group, an octane-1,8-diyl group, a nonane-1,9-diyl group, and a decane-1,10-diyl group; cyclic saturated hydrocarbylene groups having 3 to 10 carbon atoms, such as a cyclopentanediyl group, a cyclohexanediyl group, a norbornanediyl group, an adamantanediyl group, and a tricyclo[5.2.1.0^{2,6}]decanediyl group; alkenylene groups having 2 to 10 carbon atoms, such as a vinylene group and a propynylene group; arylene groups having 6 to 10 carbon atoms, such as a phenylene group, a methylphenylene group, an ethylphenylene group, an n-propylphenylene group, an isopropylphenylene group, an n-butylphenylene group, and a naphthylene group; and groups obtained by combining these groups. Furthermore, part or all of the hydrogen atoms of the hydrocarbylene groups may be substituted with a group having a heteroatom, such as an oxygen atom, a sulfur atom, a nitrogen atom, or a halogen atom, and part of the —CH₂— of the hydrocarbylene groups may be substituted with a group having a heteroatom, such as an oxygen atom, a sulfur atom, or a nitrogen atom. The resulting hydrocarbylene groups may have a hydroxy group, a cyano group, a halogenated alkyl group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc. As R⁵, a carbonyl group, a hydrocarbylene group having 1 to 4 carbon atoms, or a fluorinated hydrocarbylene group having 1 to 4 carbon atoms is preferable.

In the general formula (1), *1 and *2 each represent an attachment point to a carbon atom of the aromatic ring in the formula, provided that *1 and *2 are bonded to adjacent carbon atoms of the aromatic ring. As combinations of such “*1”, “*2”, and “m”, the seven cases shown below are possible.

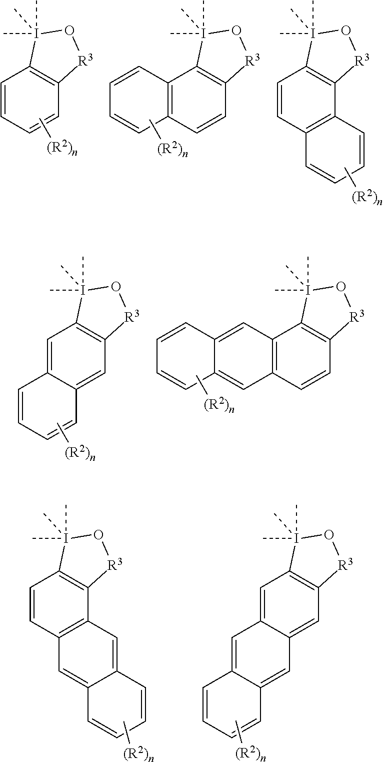

In the formulae, “n”, R², and R³ are as defined above. A dotted line represents an attachment point to an acloxy group, R¹—C(═O)—O—, (R¹—C(═O)—O—, R²—C(═O)—O—, or R³—C(═O)—O—.

Specific examples of the hypervalent iodine compounds represented by the formula (1) include the following, but are not limited thereto. In the following formulae, Me represents a methyl group.

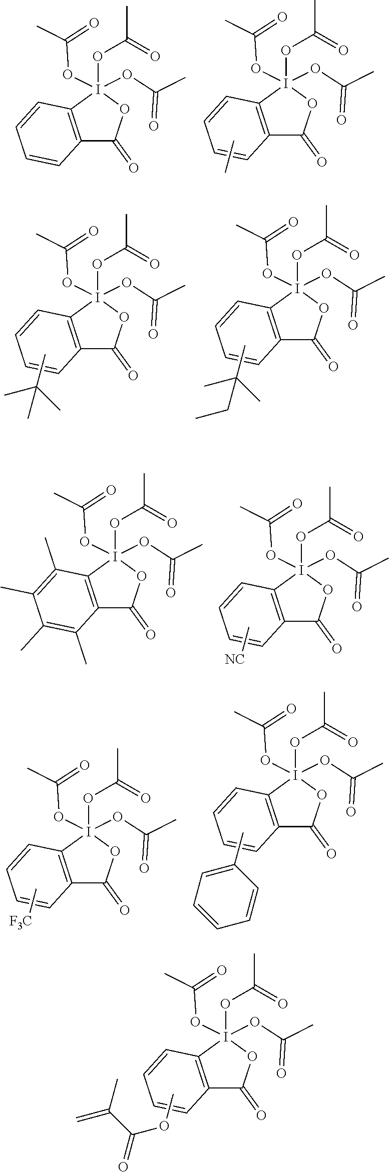

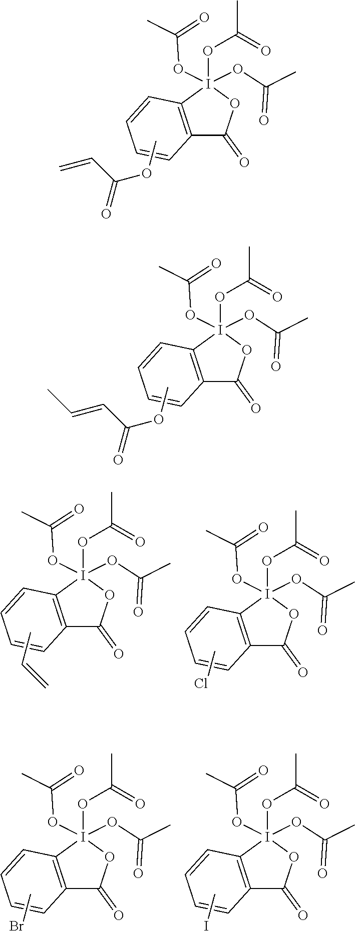

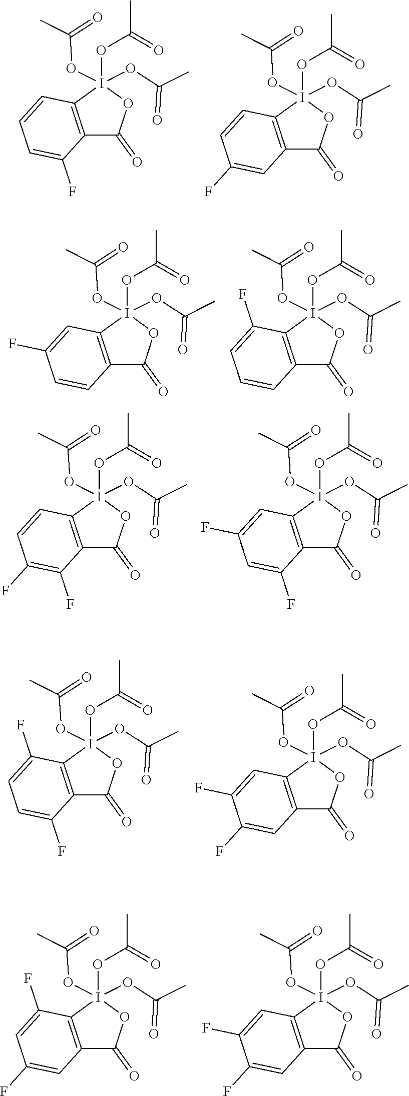

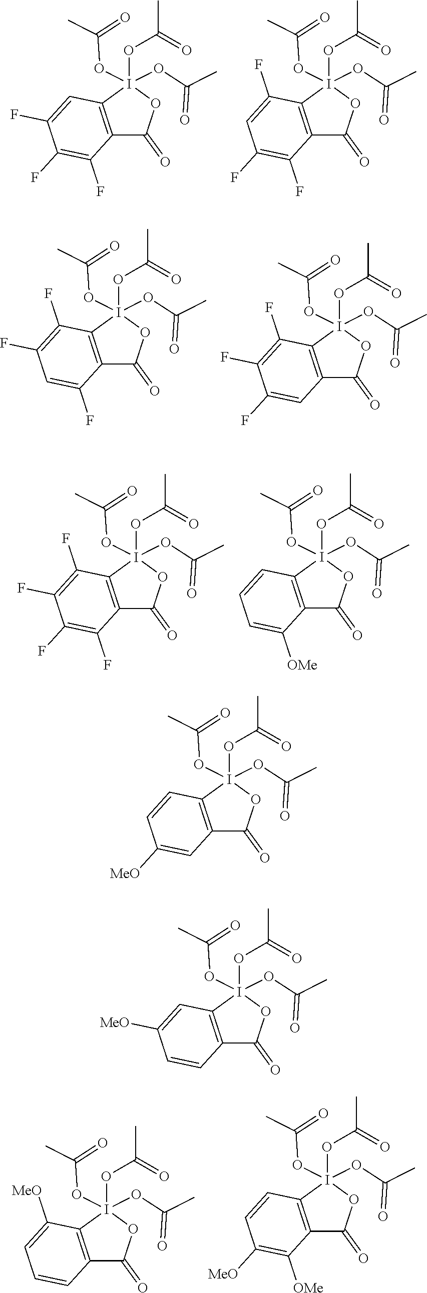

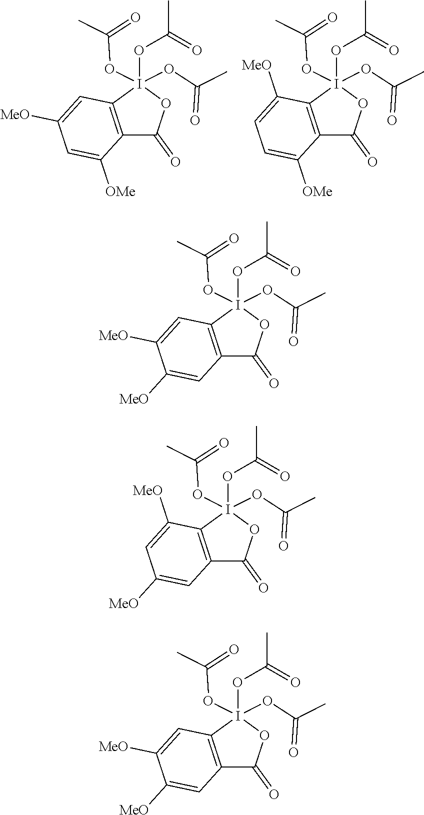

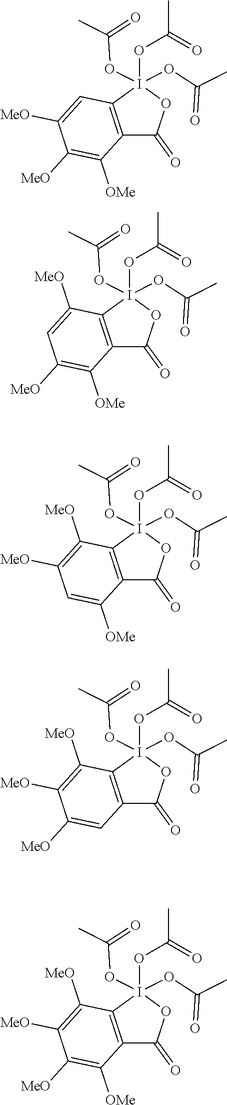

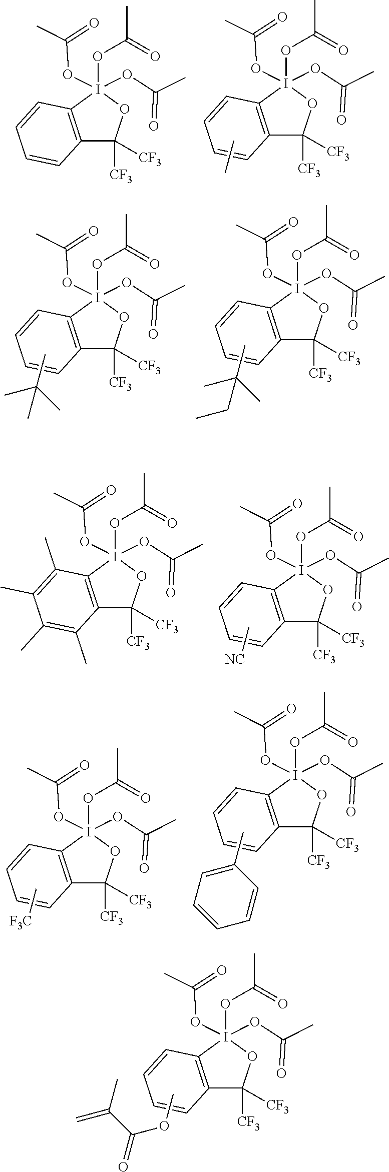

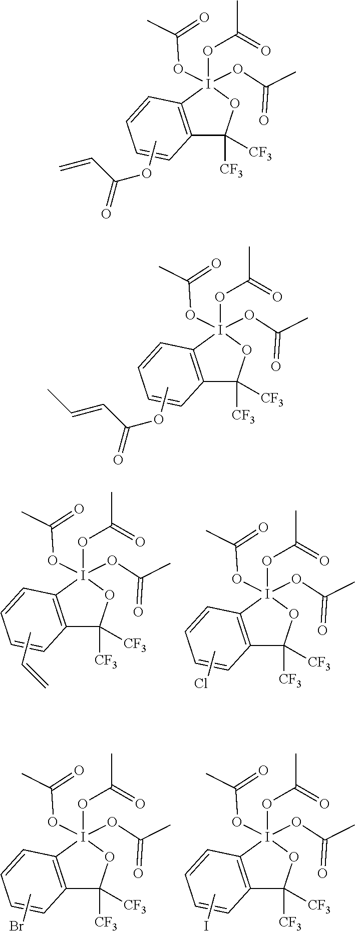

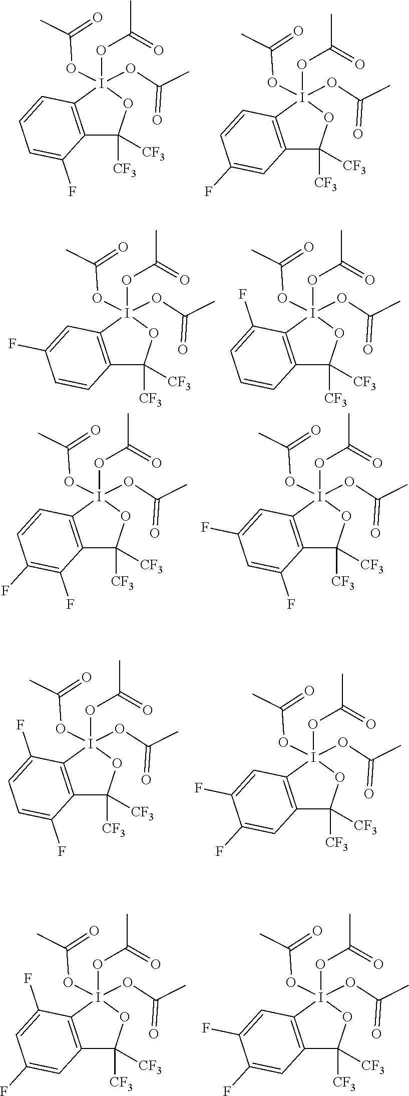

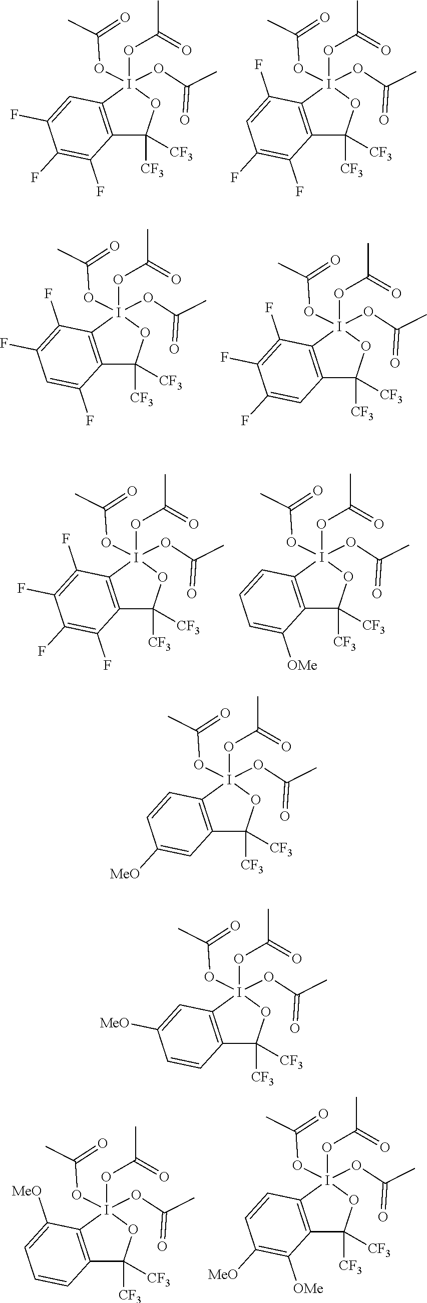

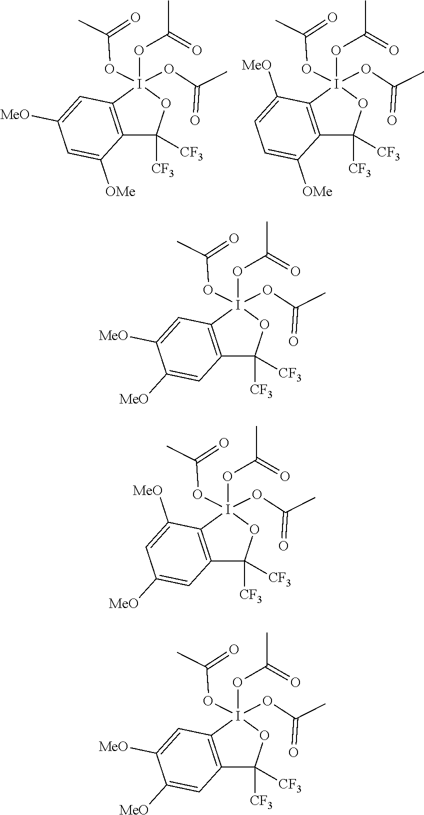

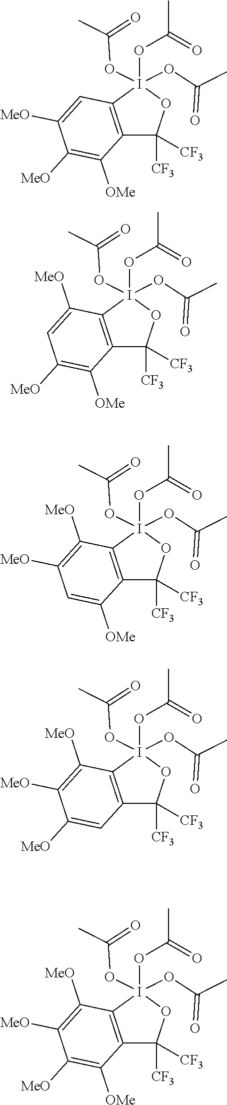

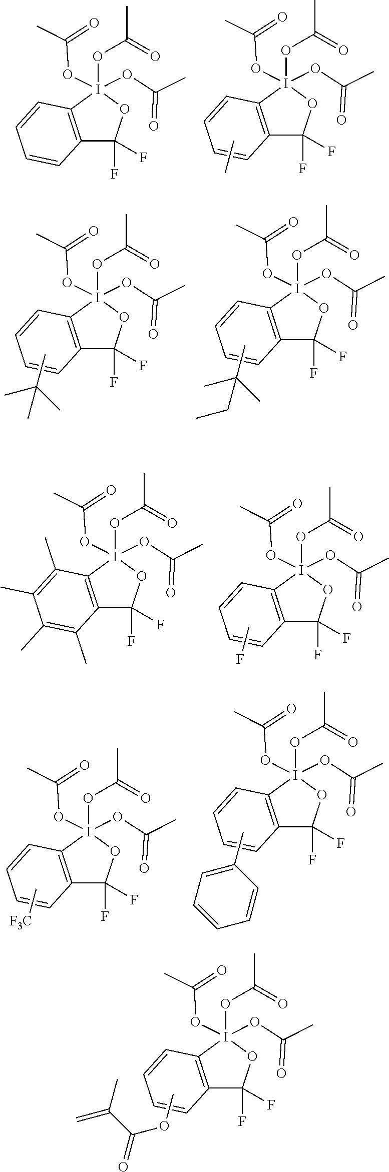

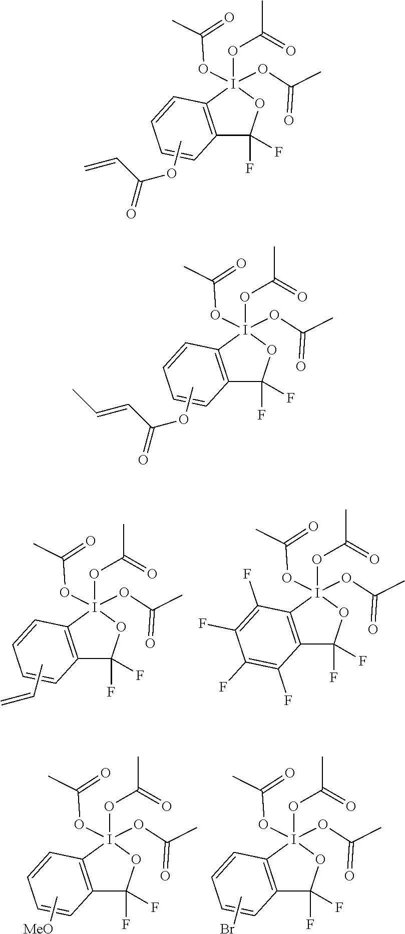

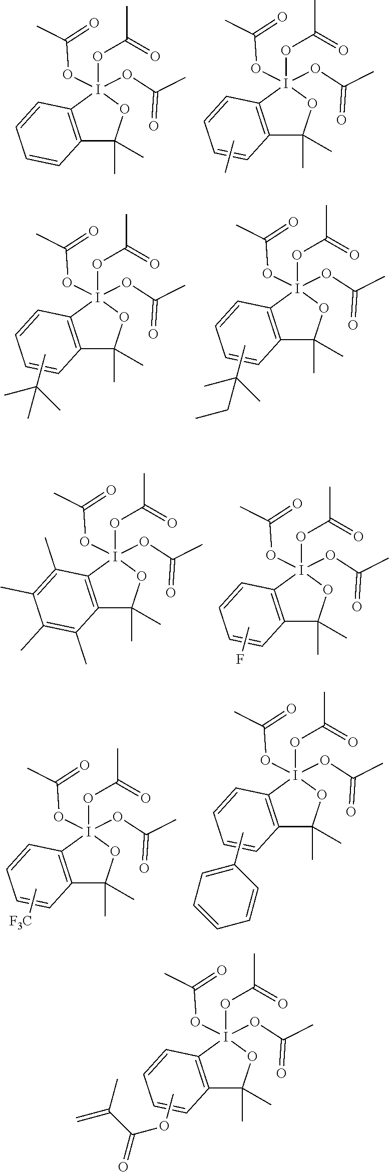

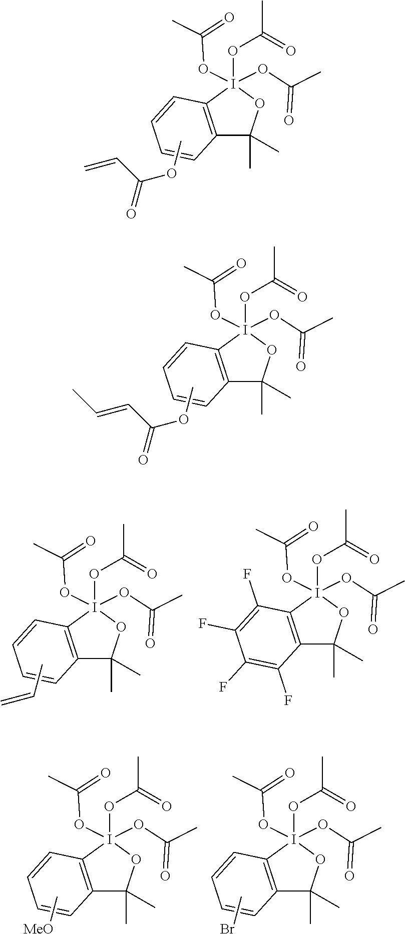

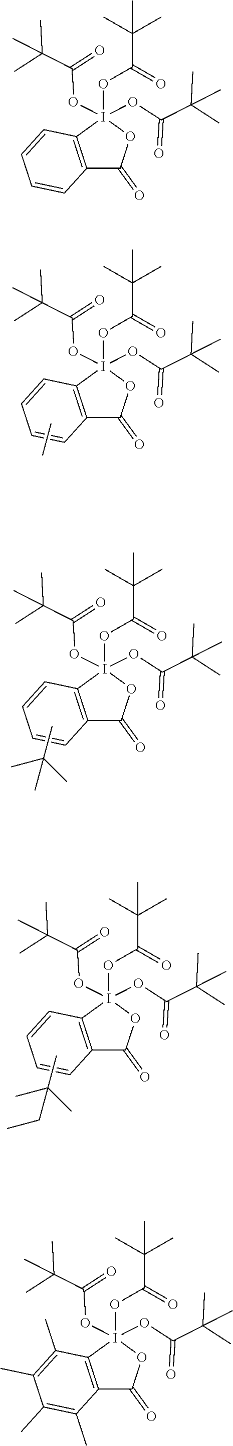

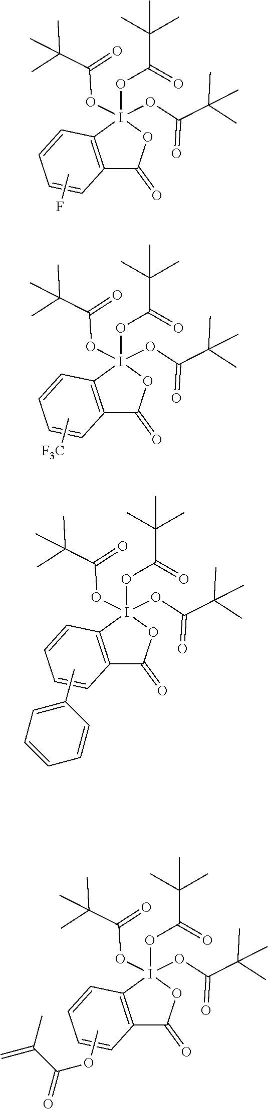

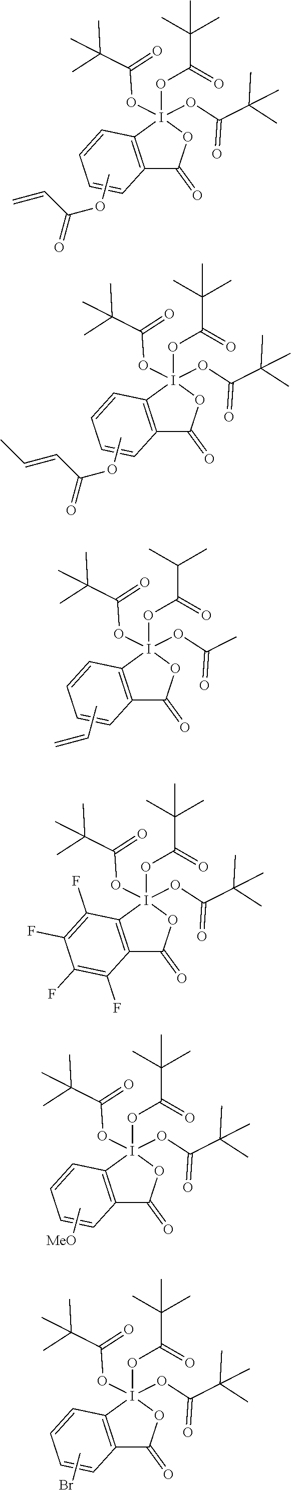

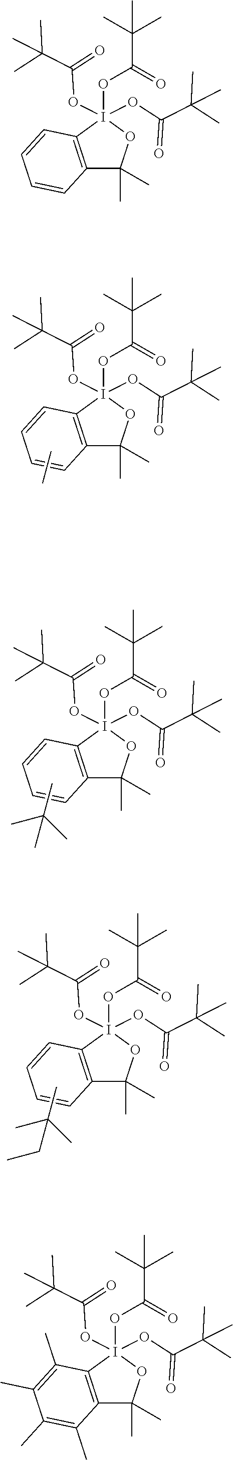

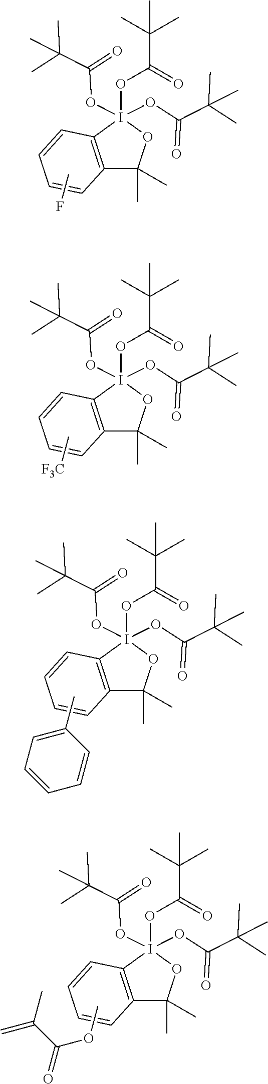

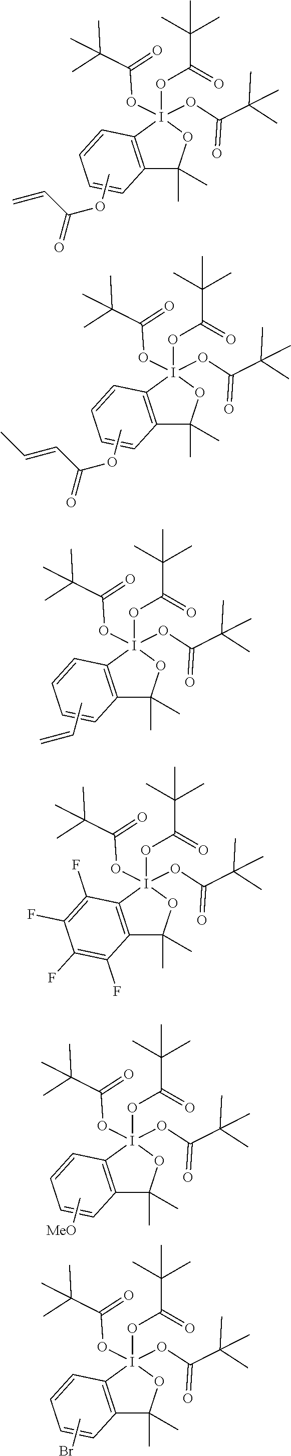

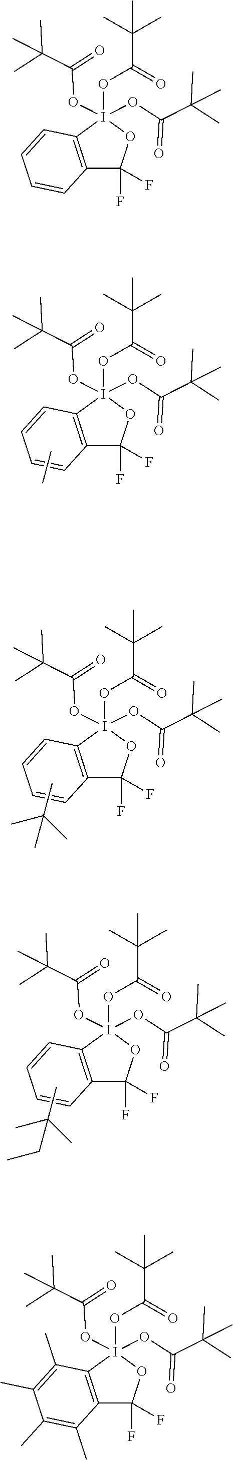

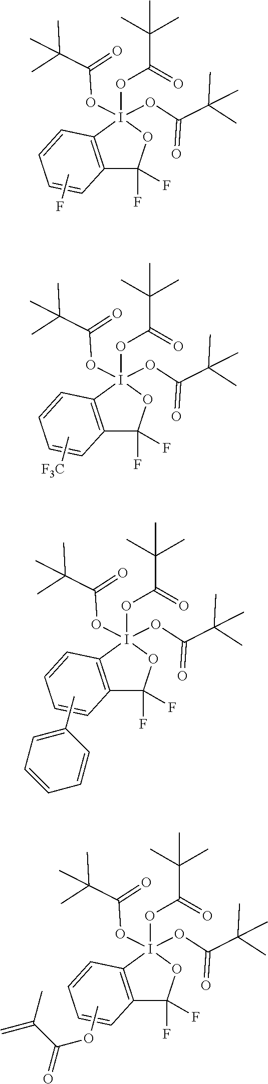

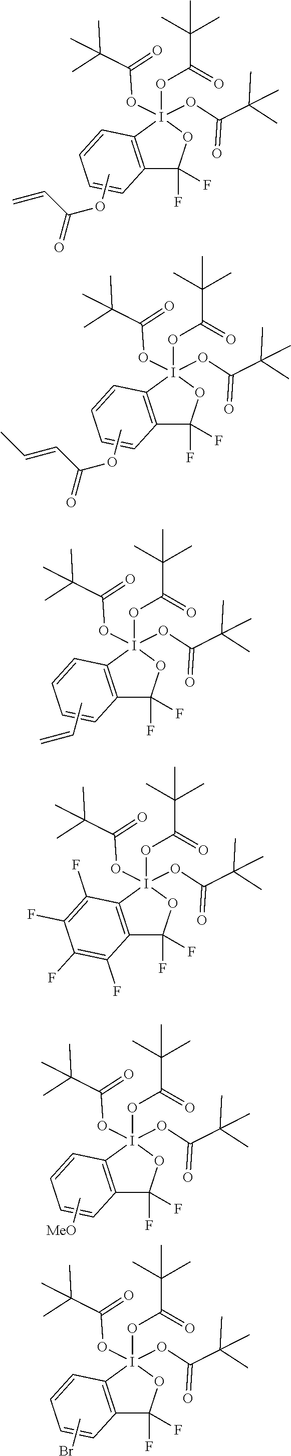

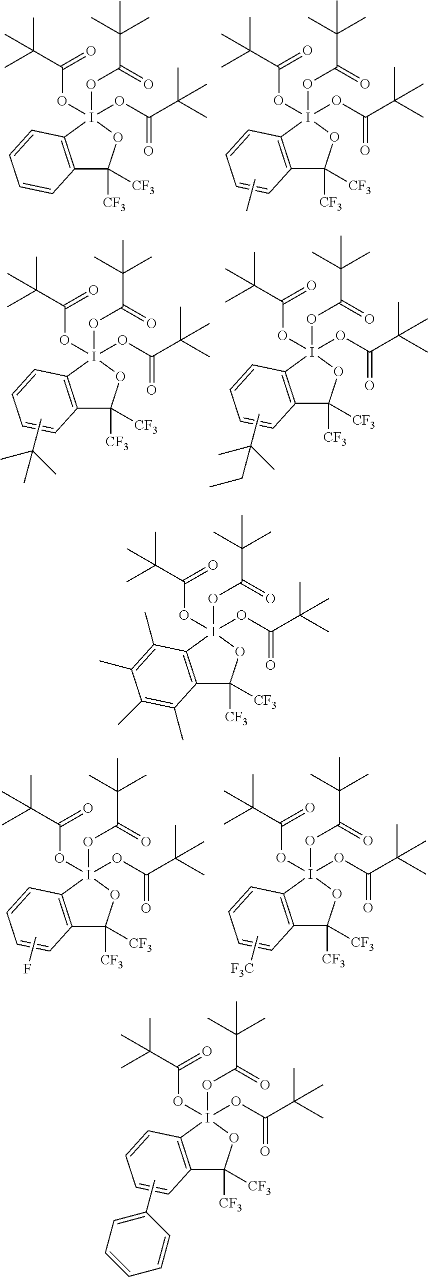

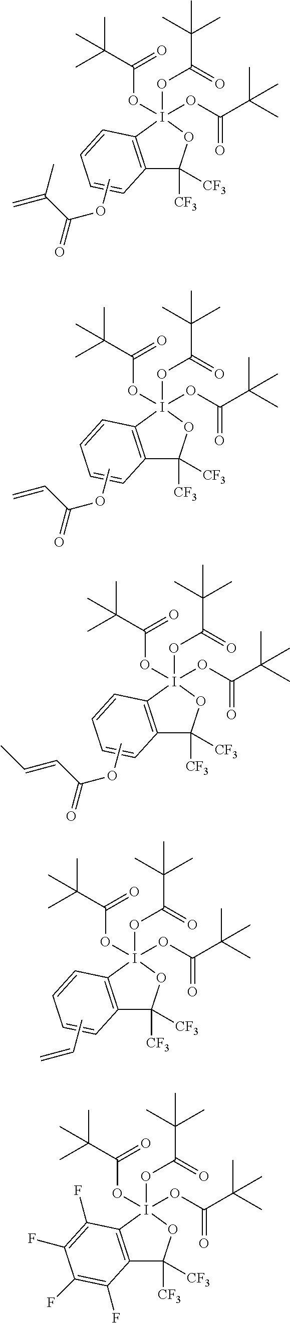

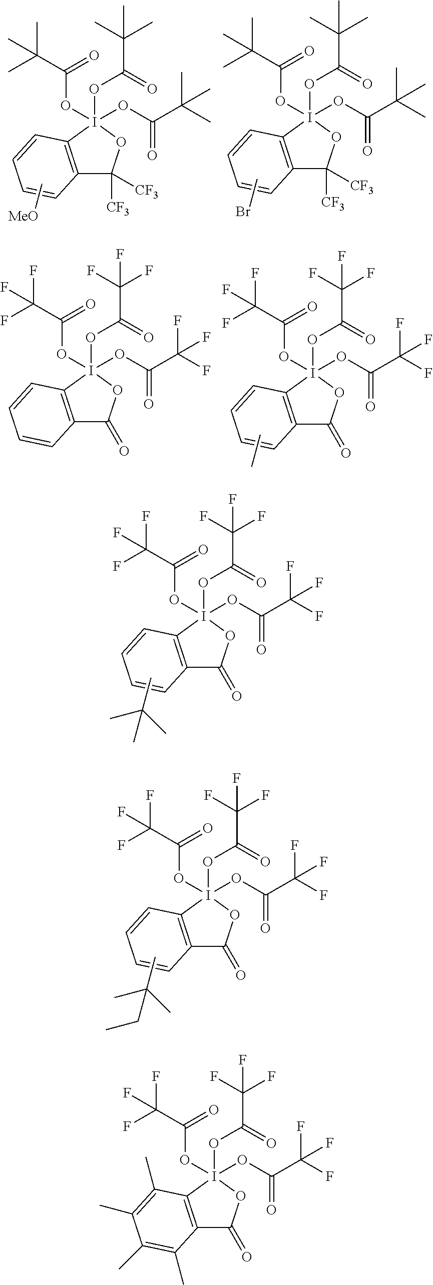

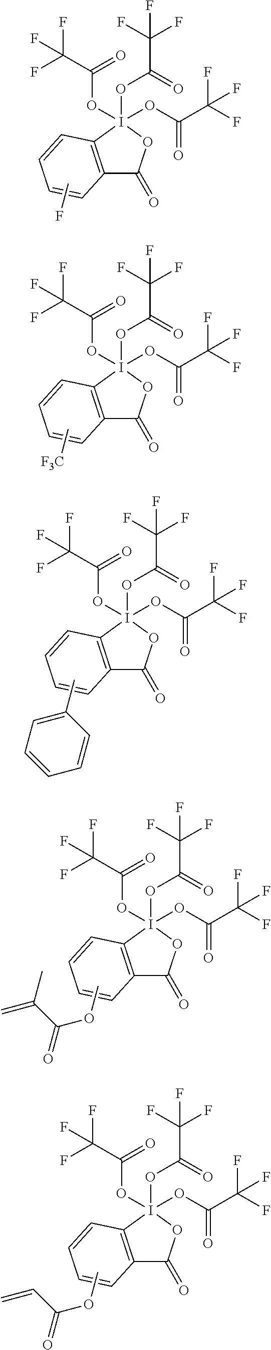

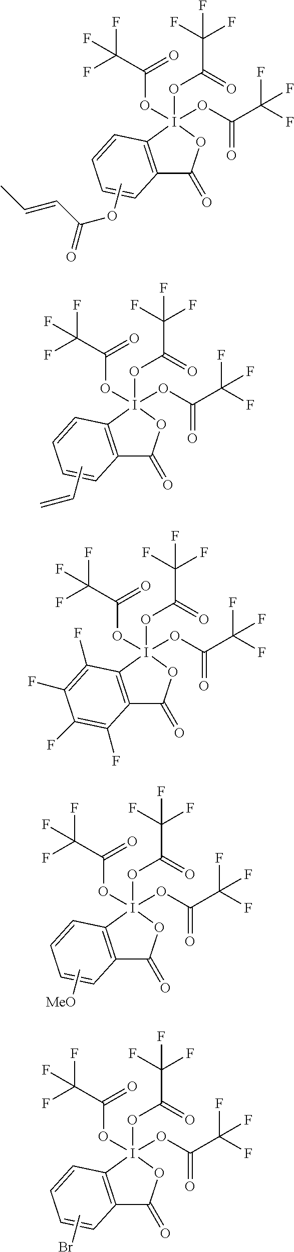

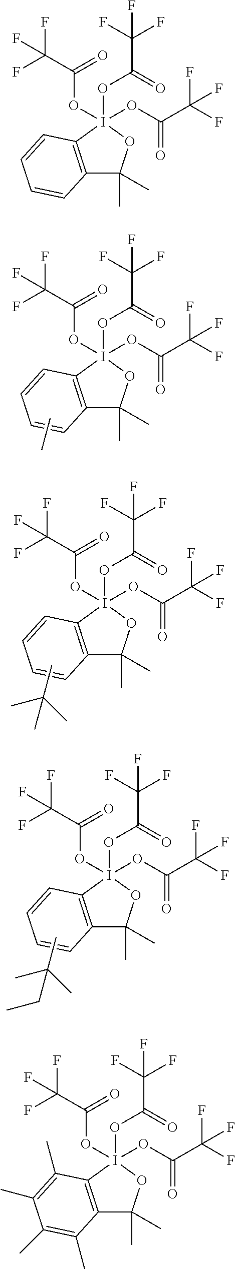

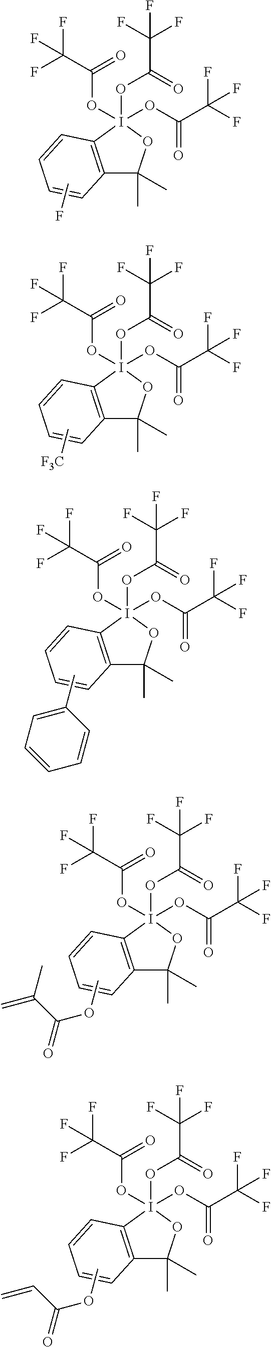

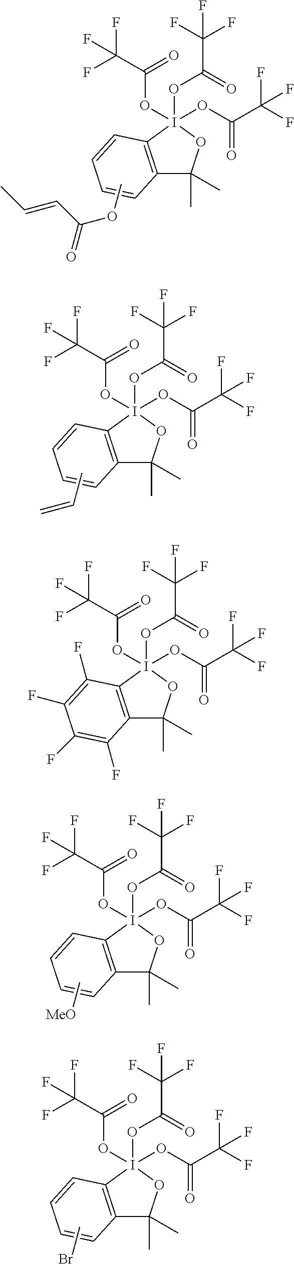

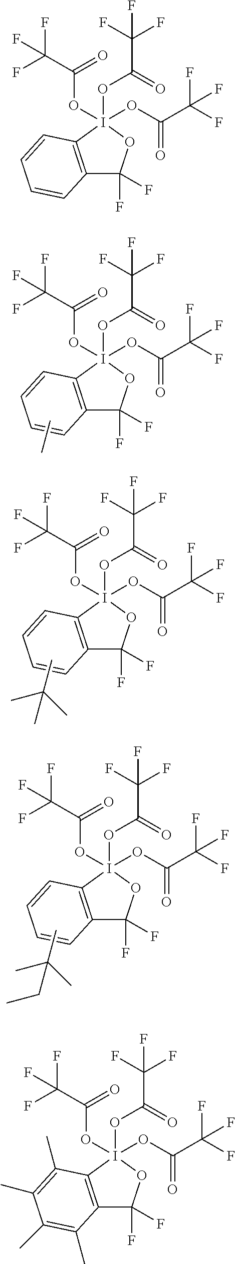

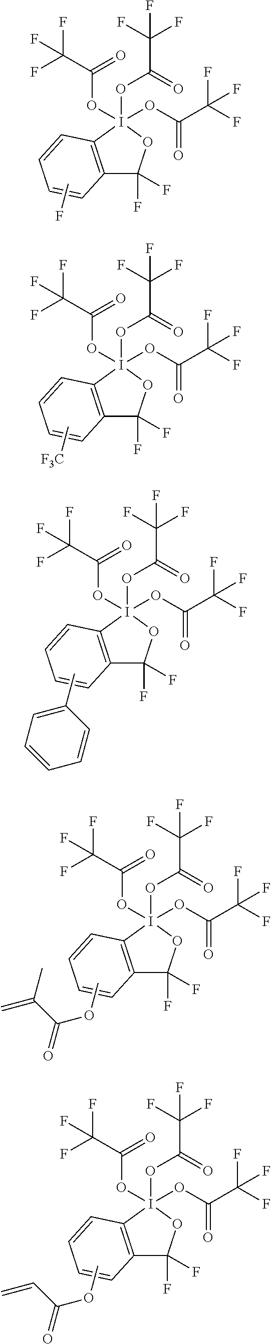

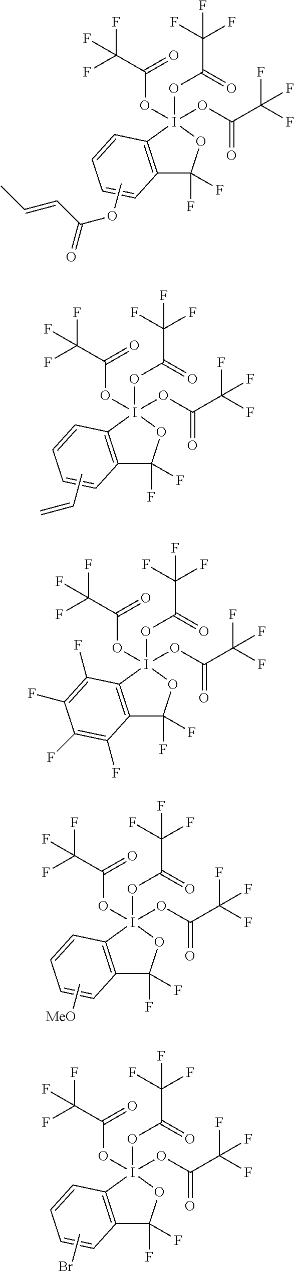

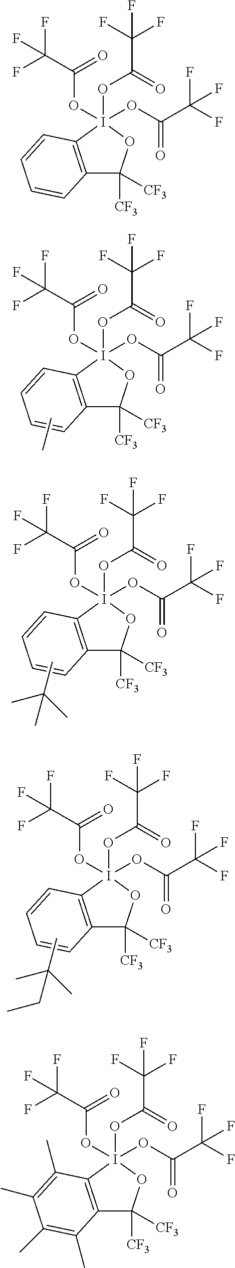

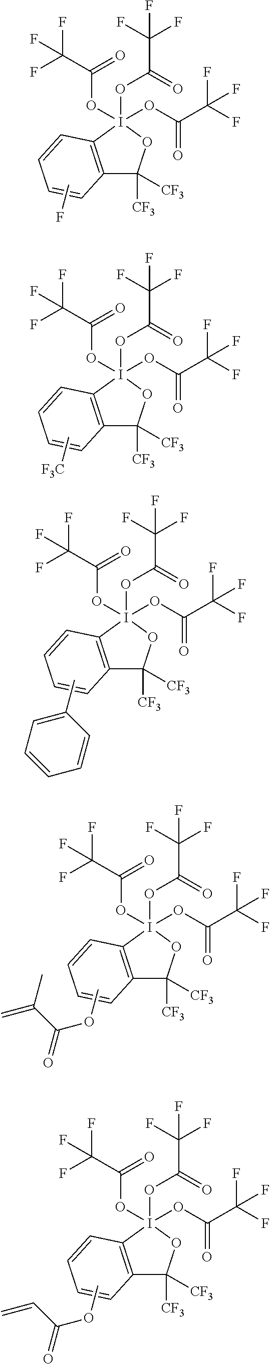

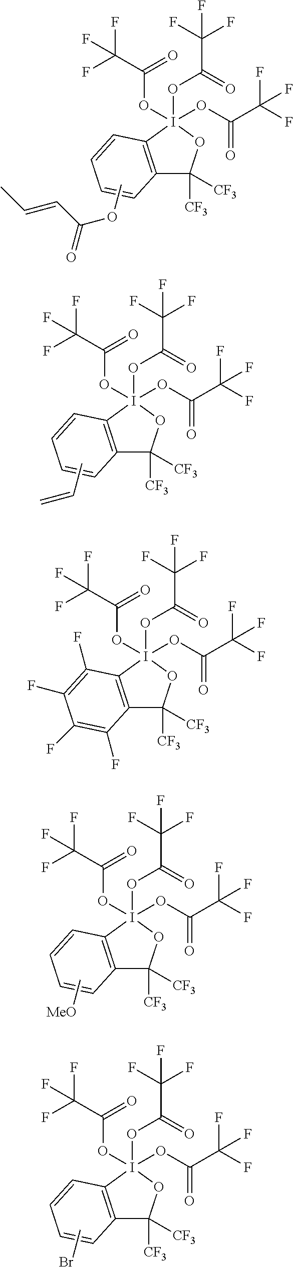

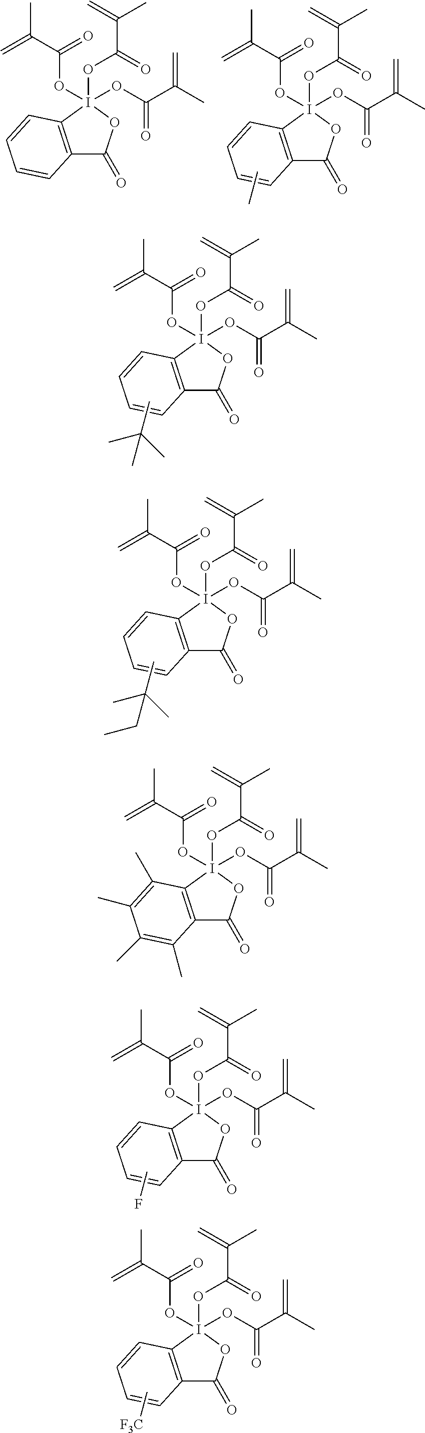

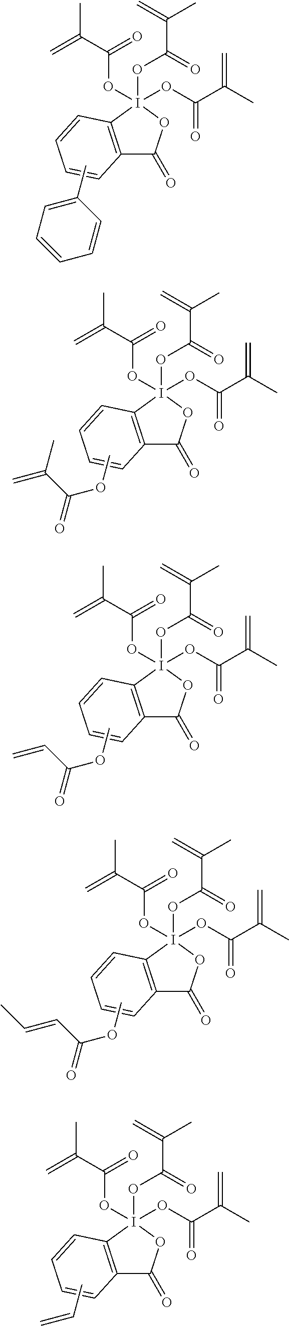

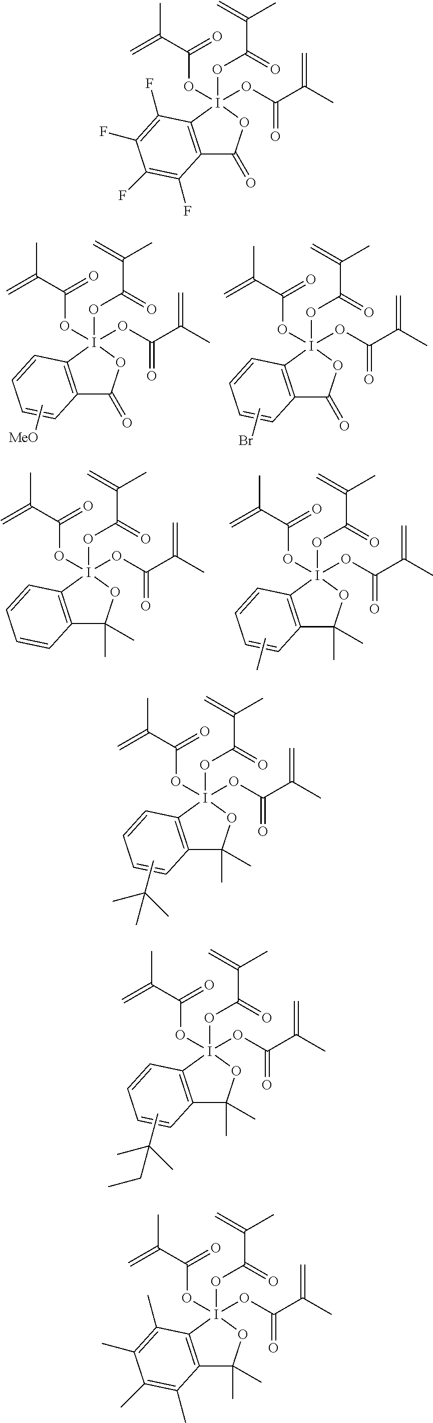

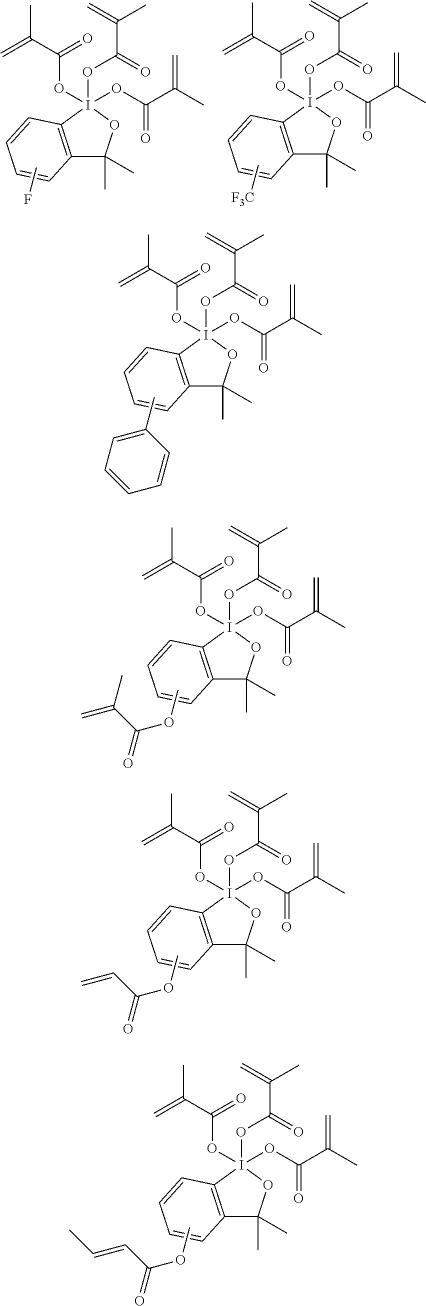

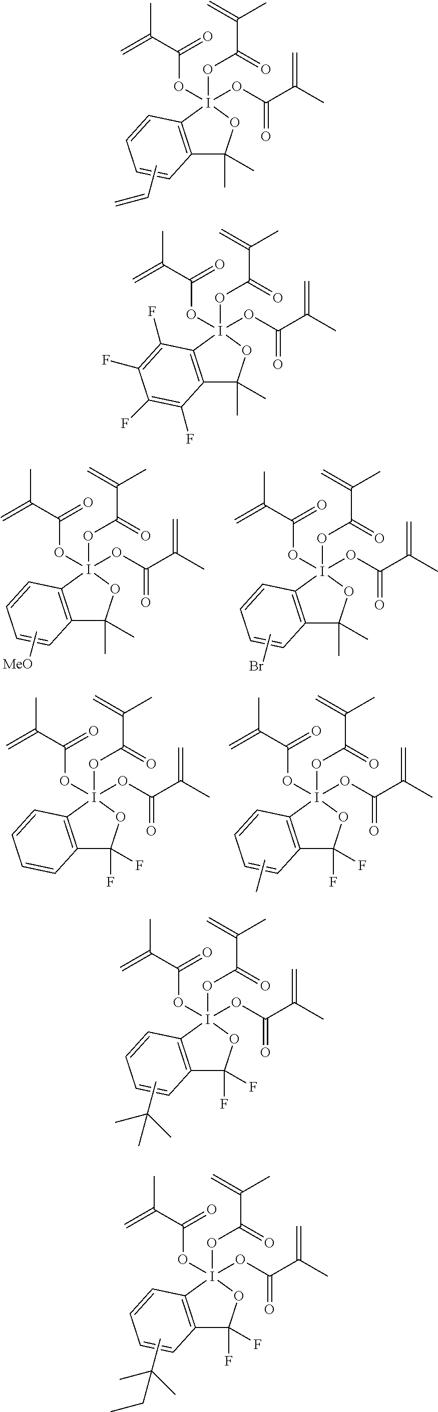

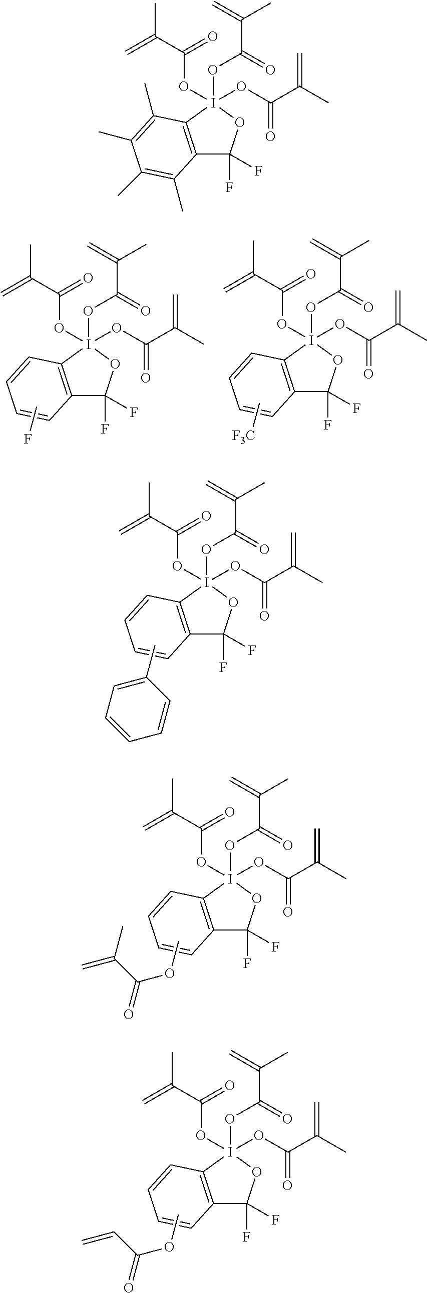

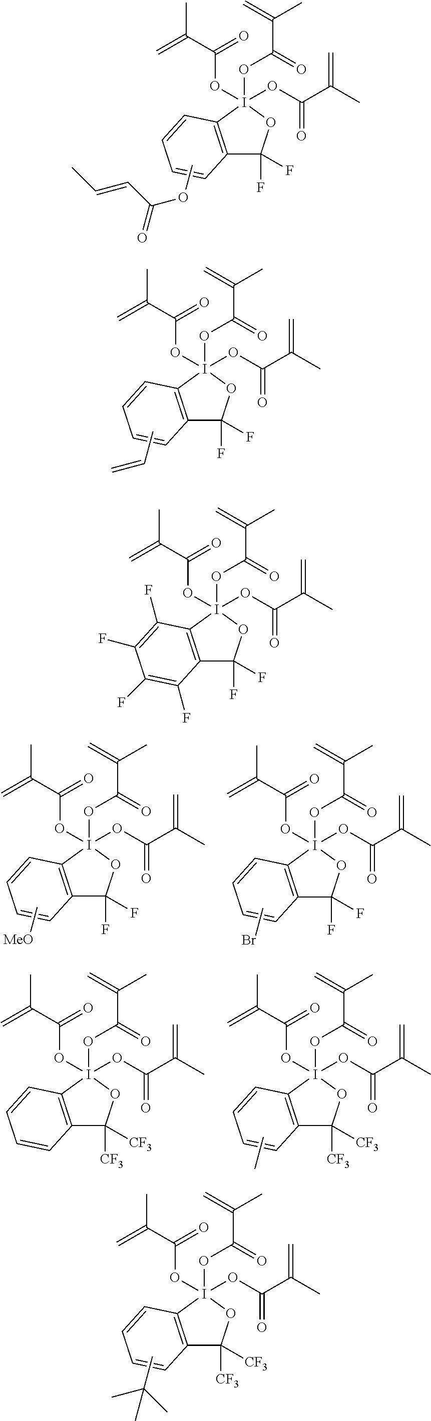

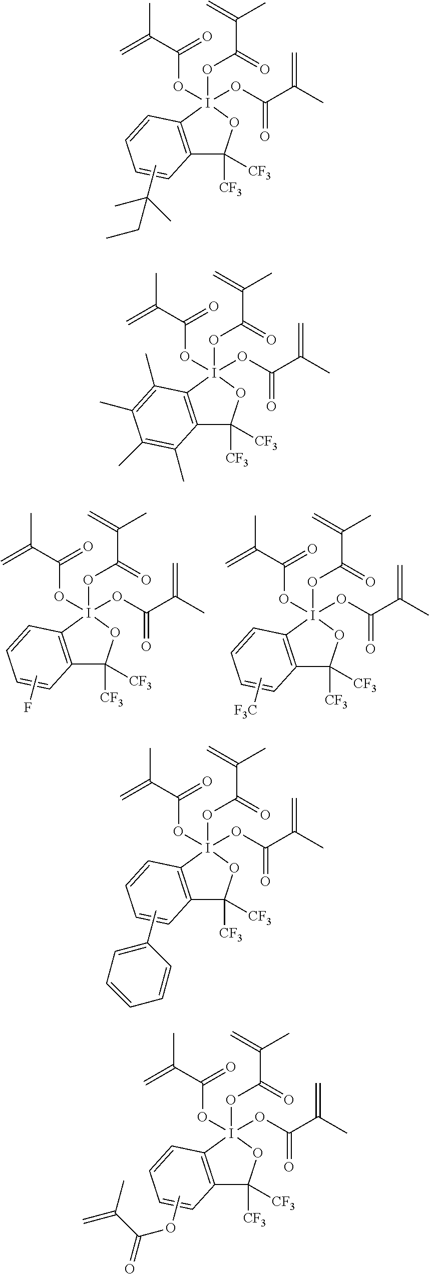

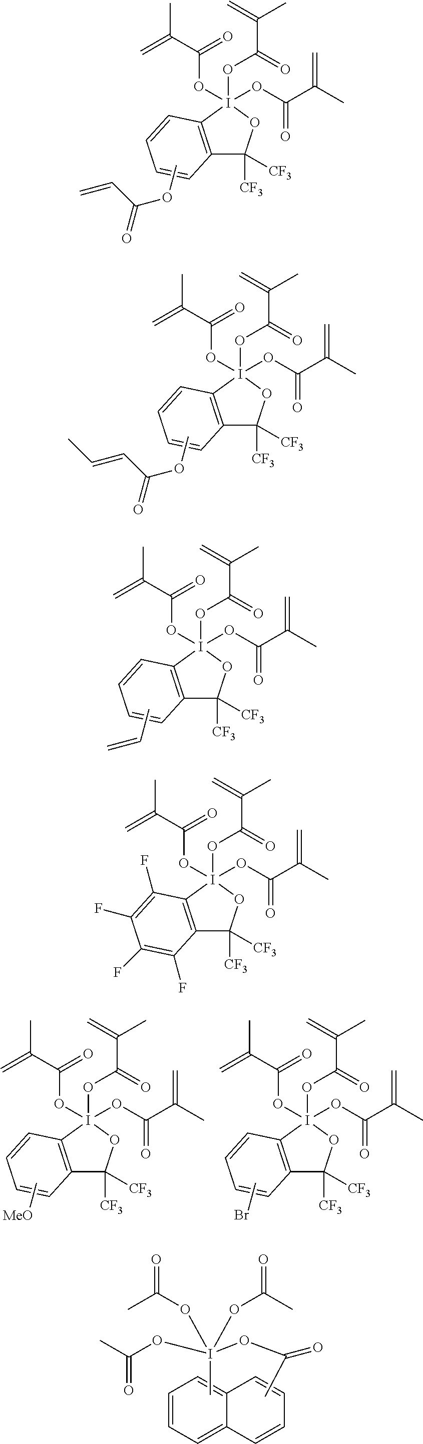

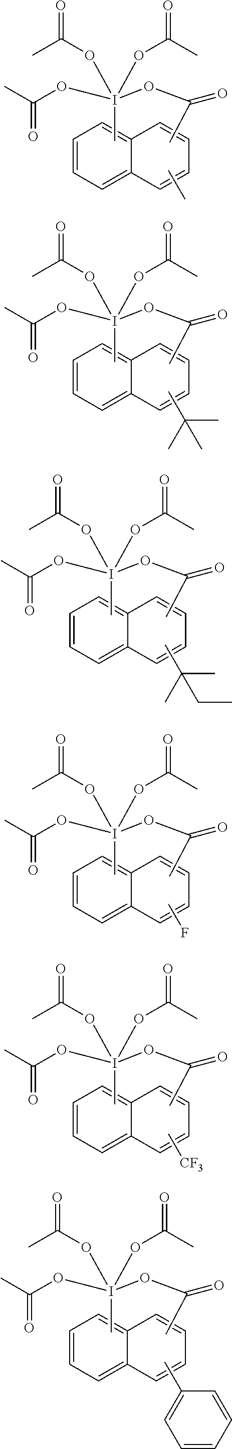

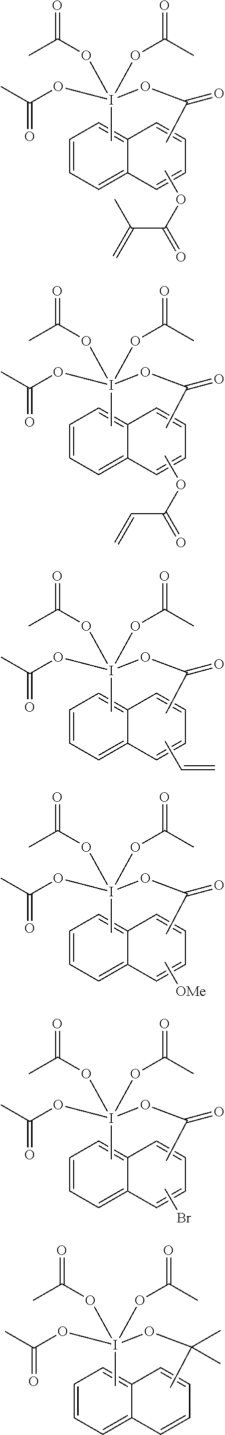

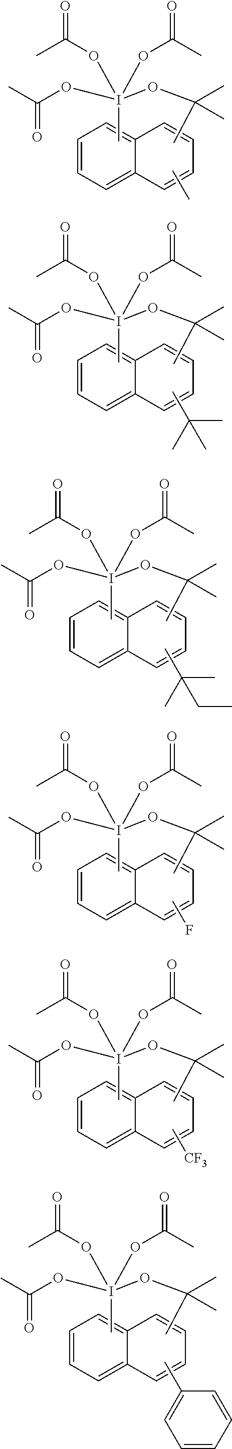

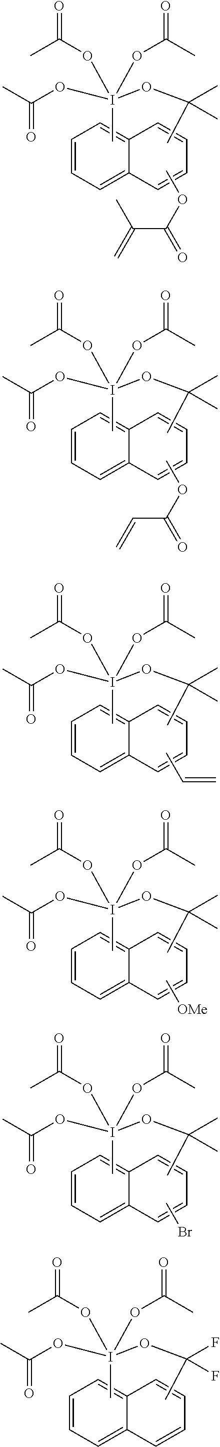

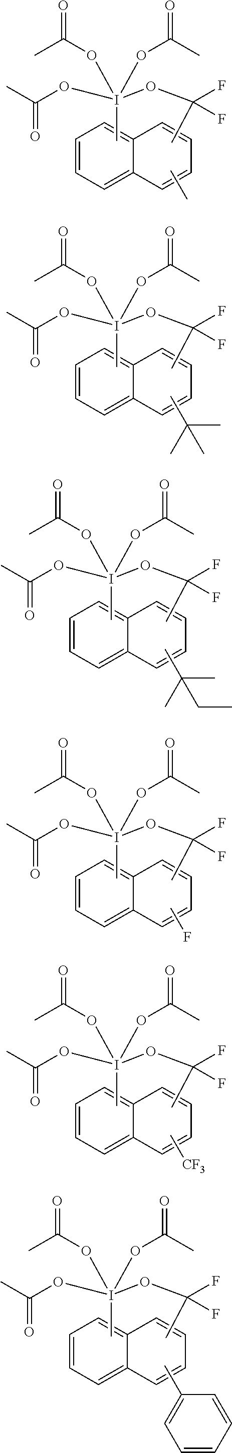

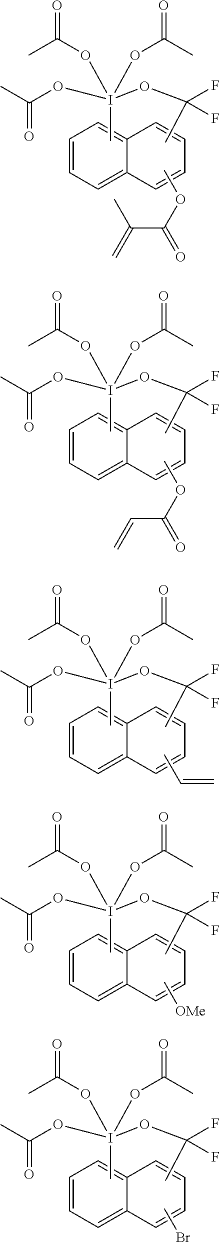

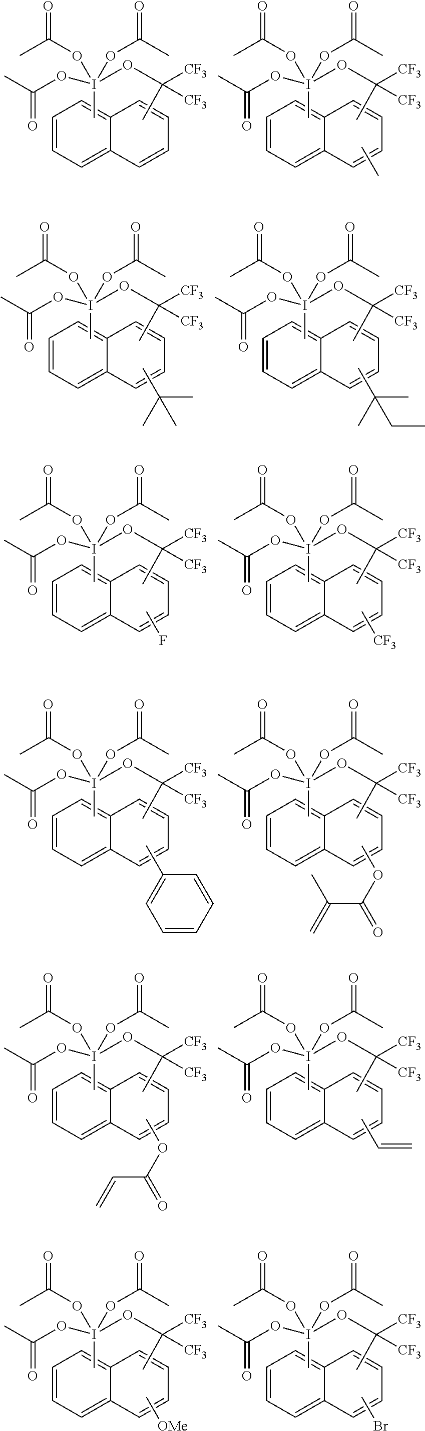

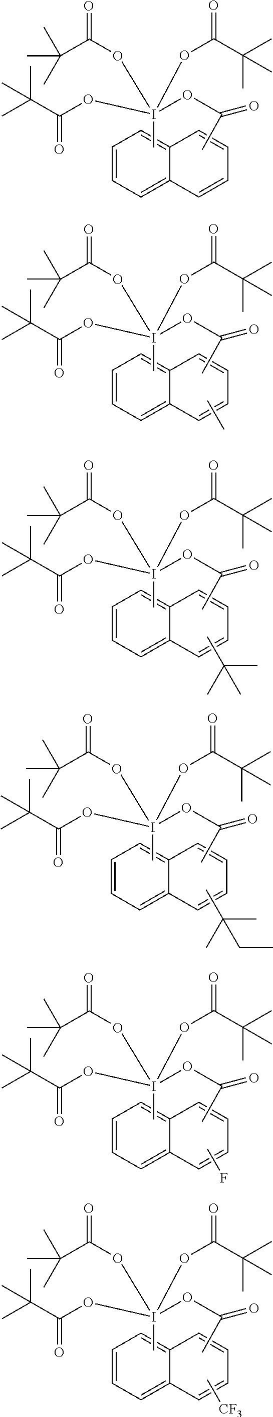

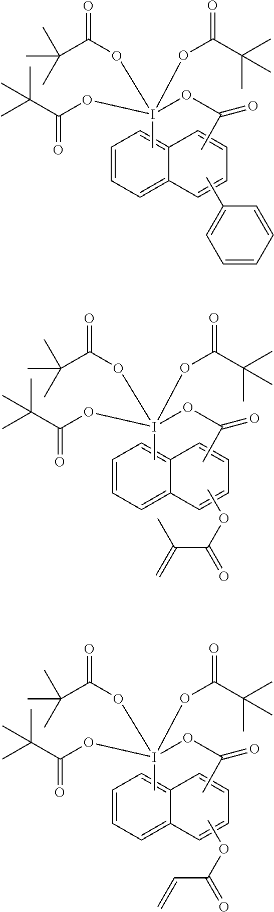

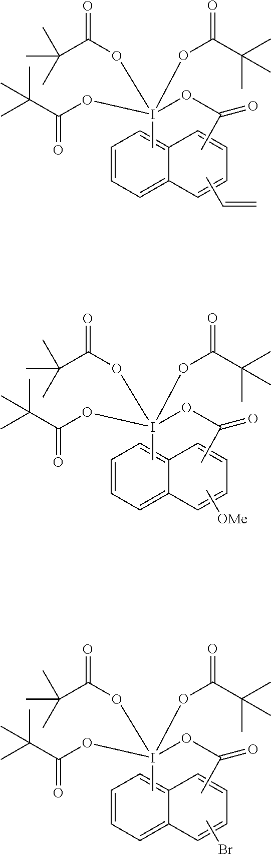

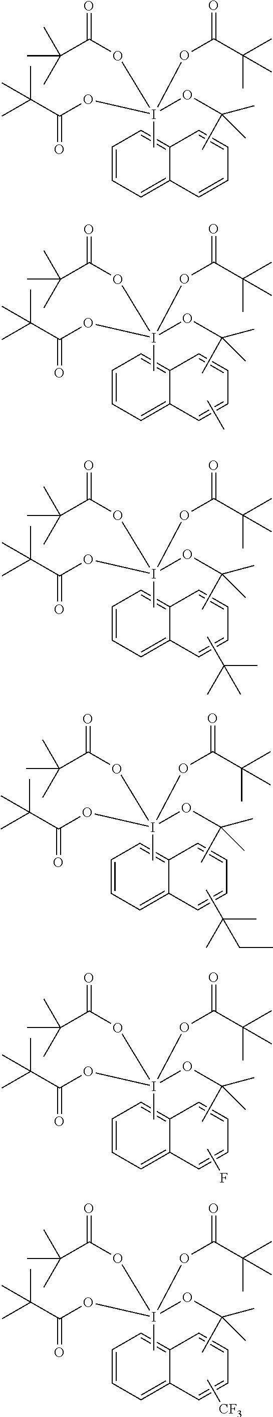

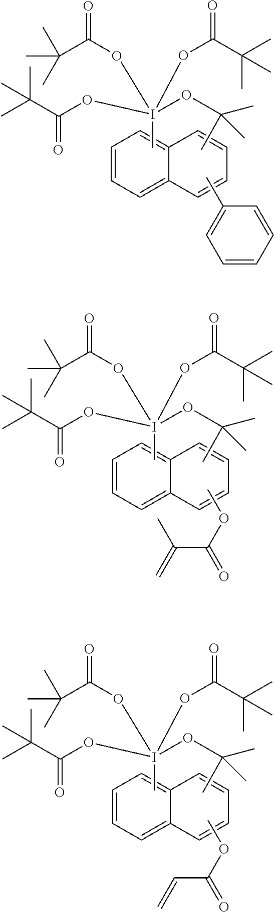

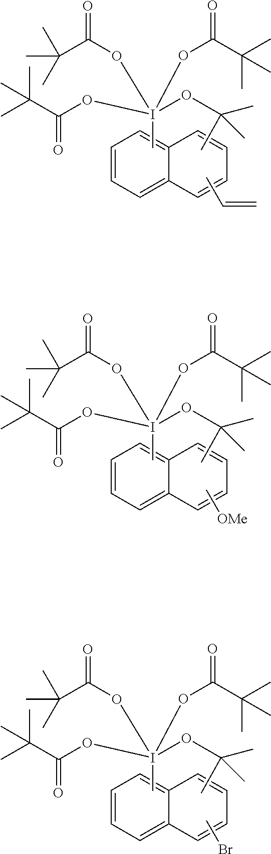

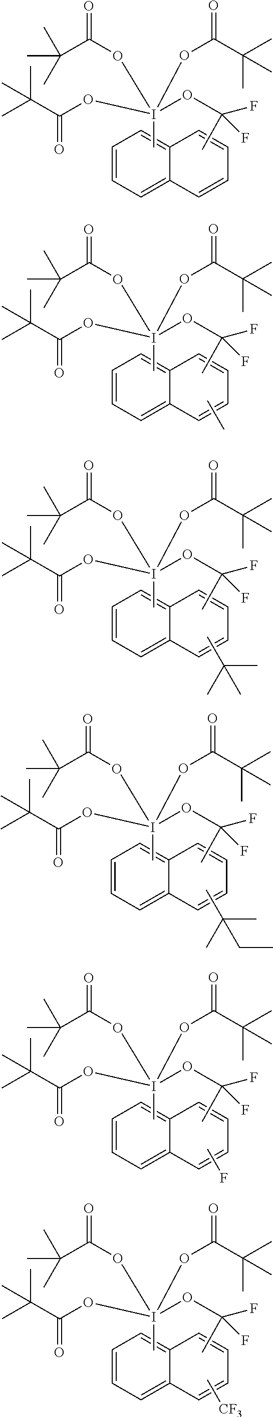

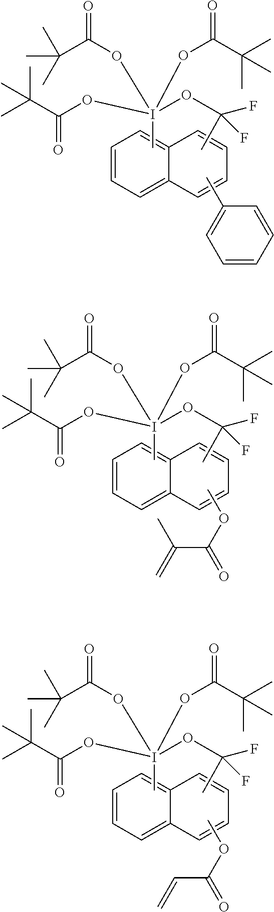

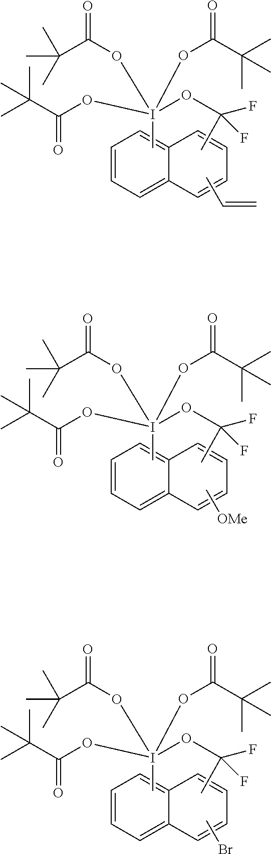

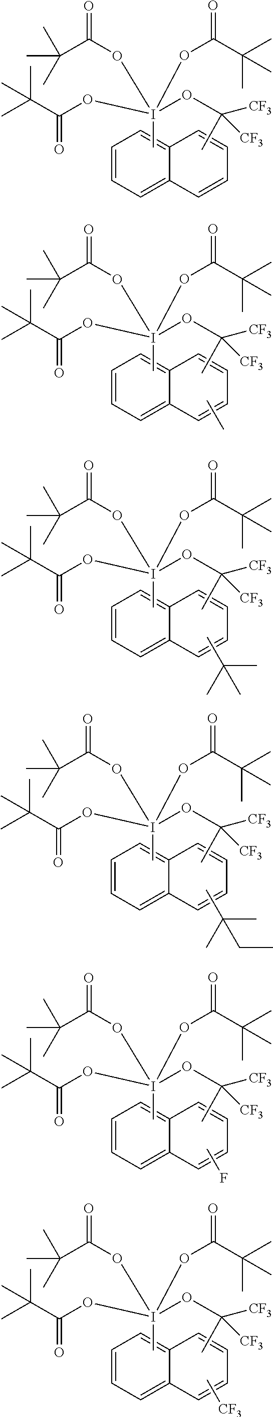

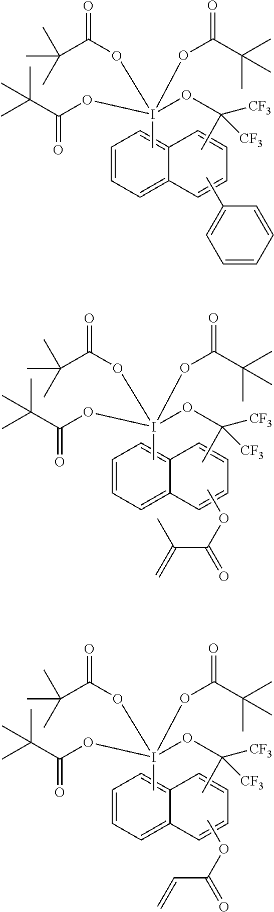

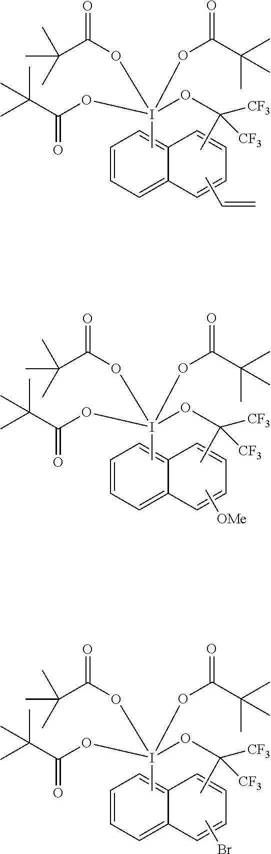

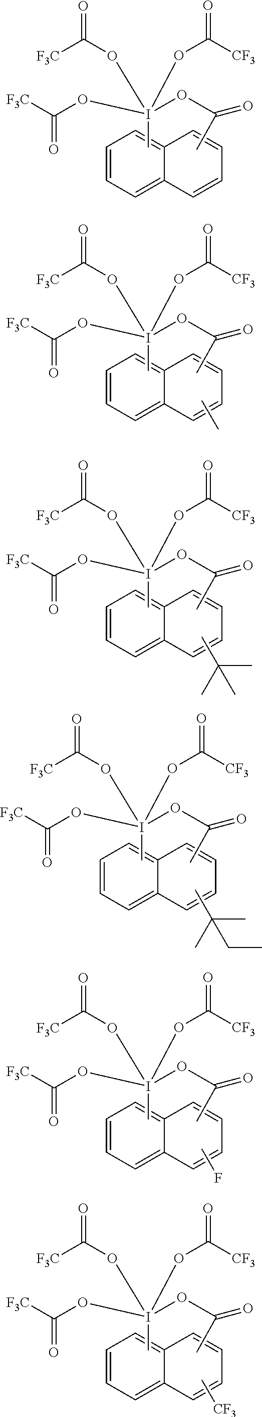

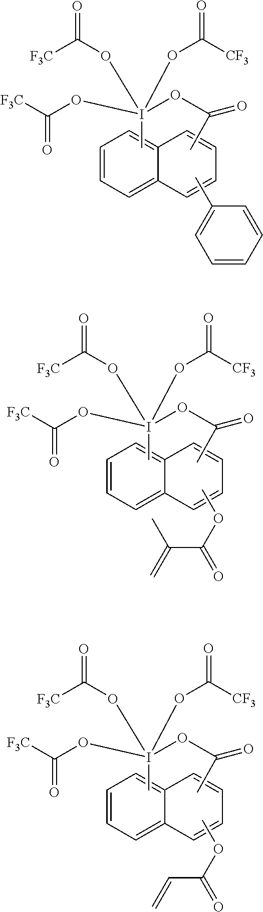

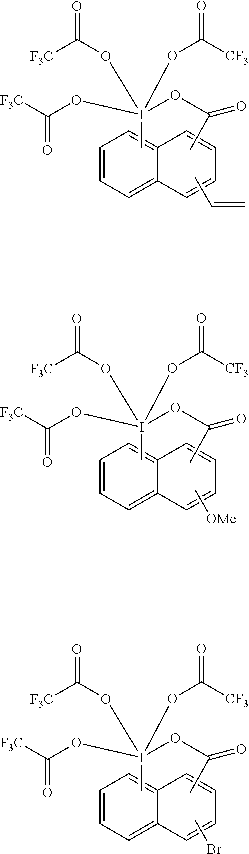

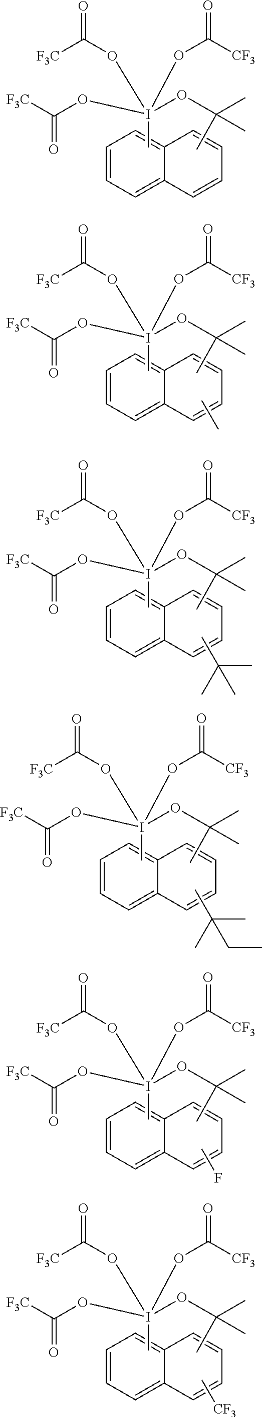

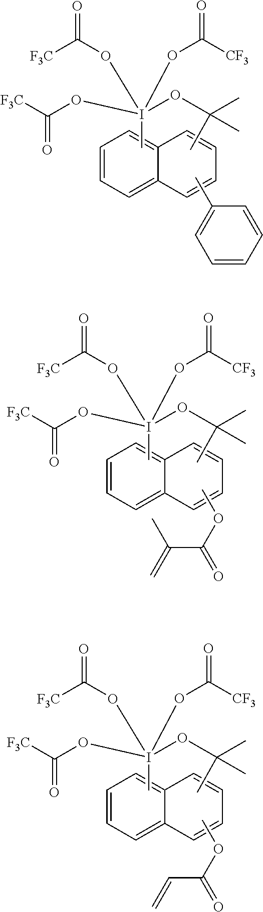

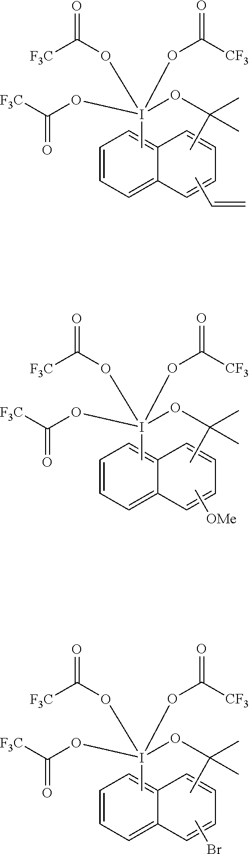

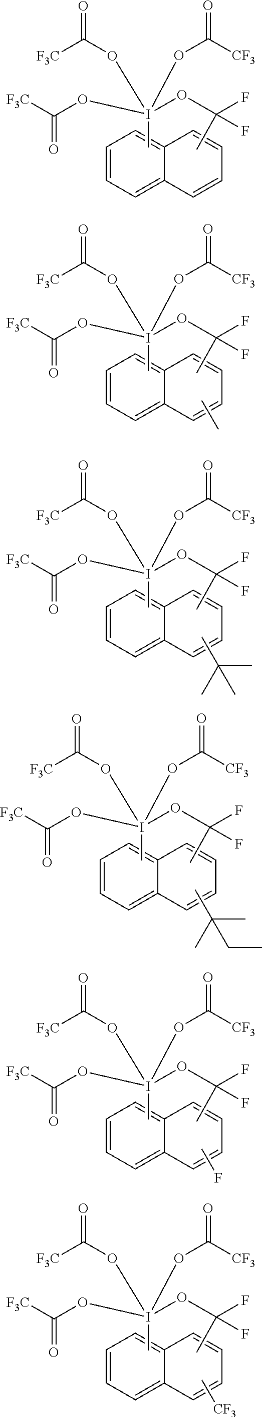

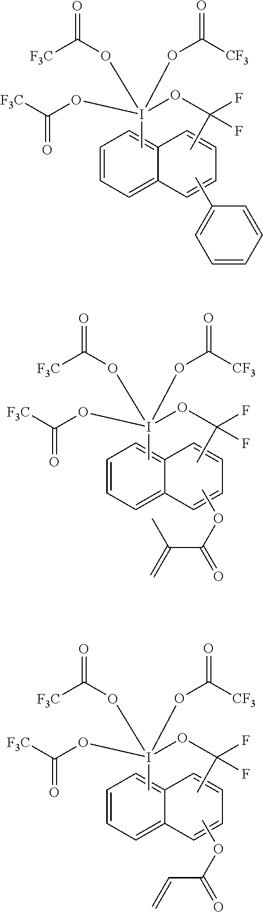

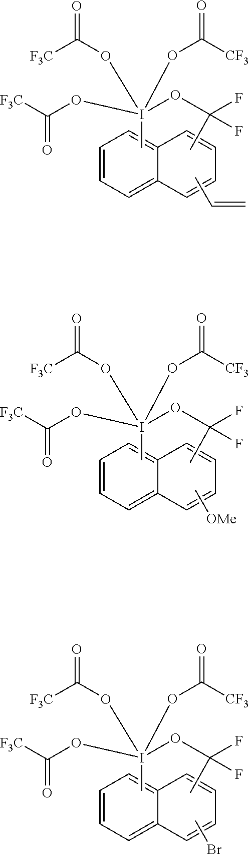

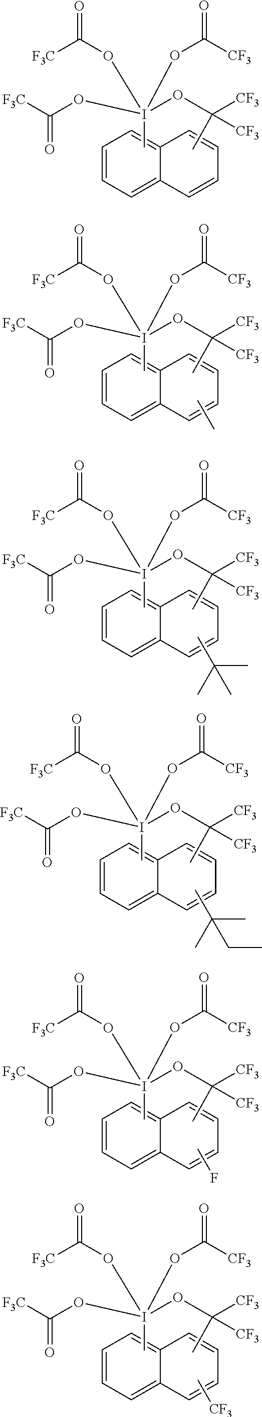

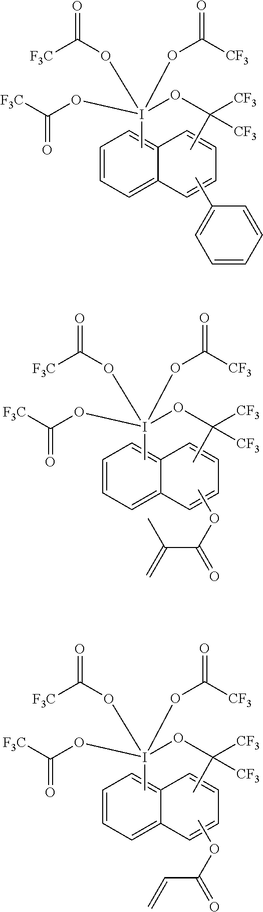

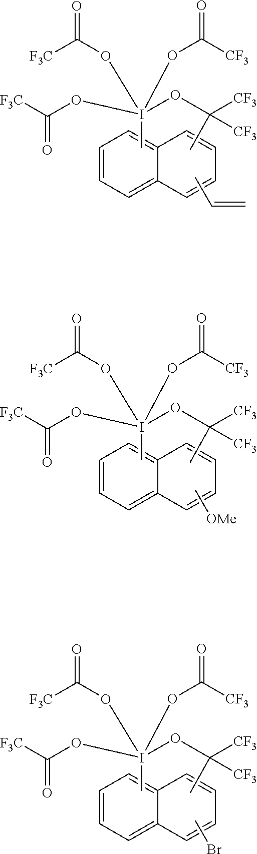

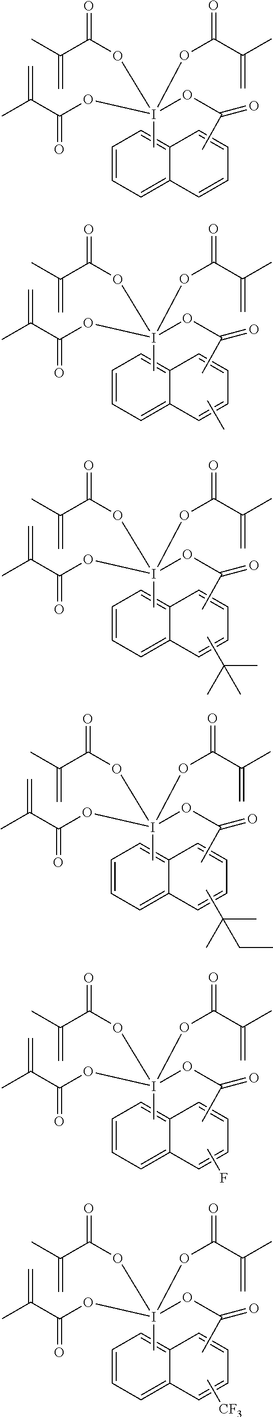

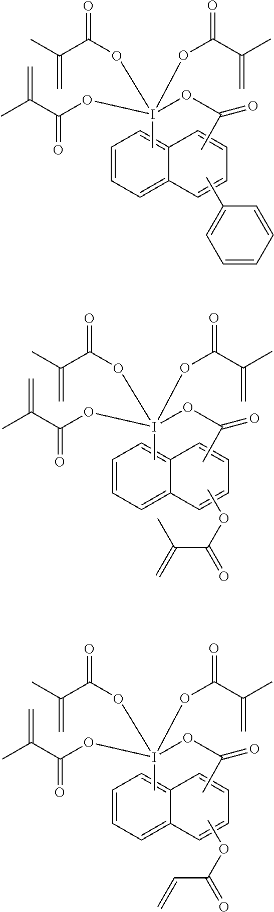

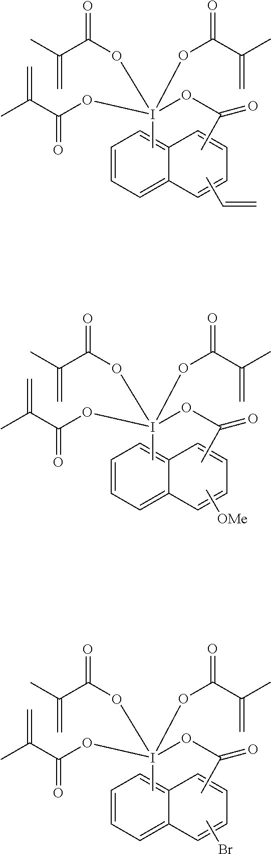

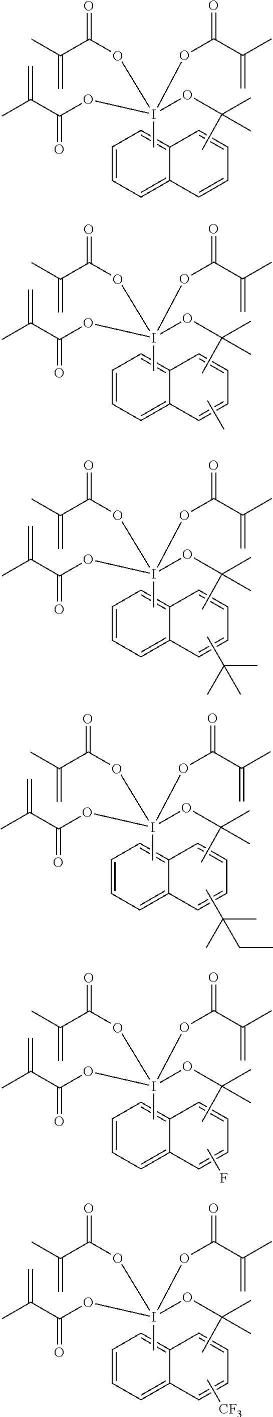

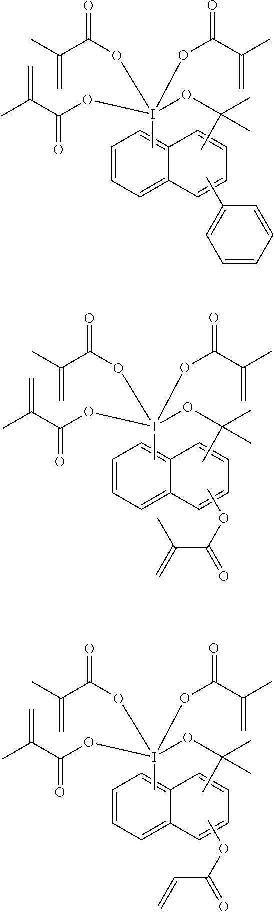

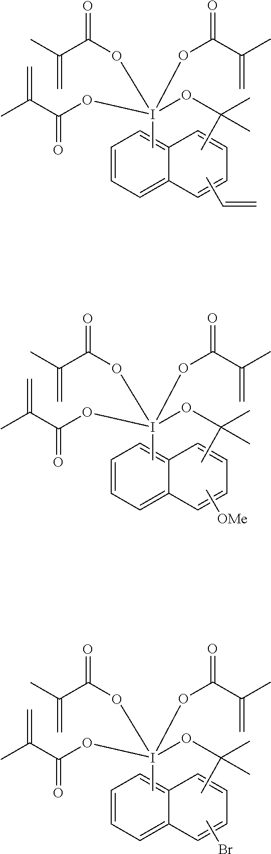

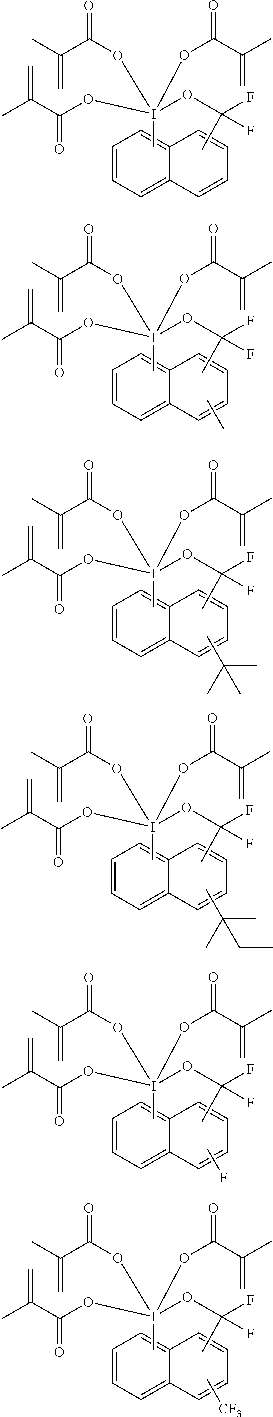

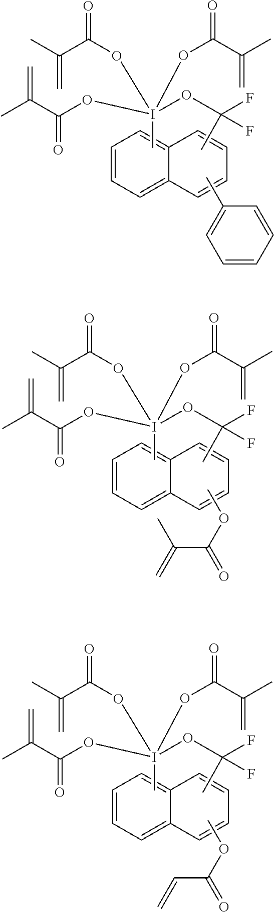

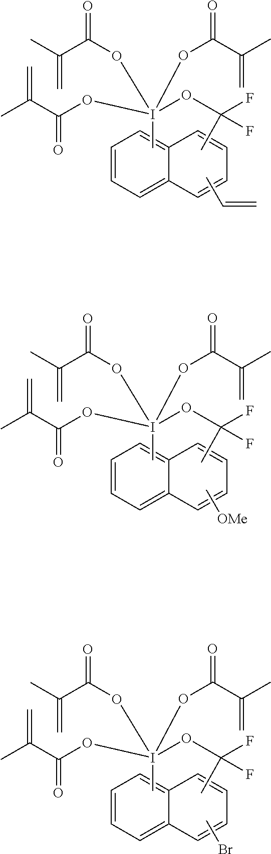

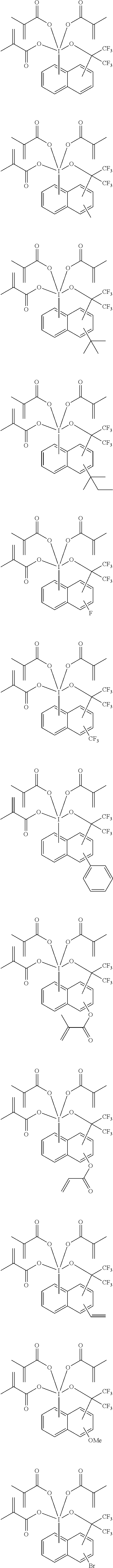

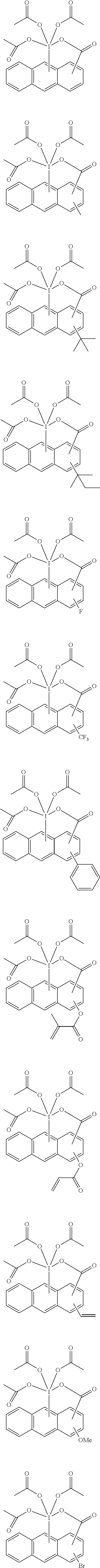

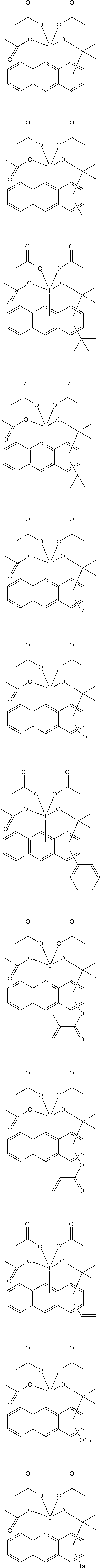

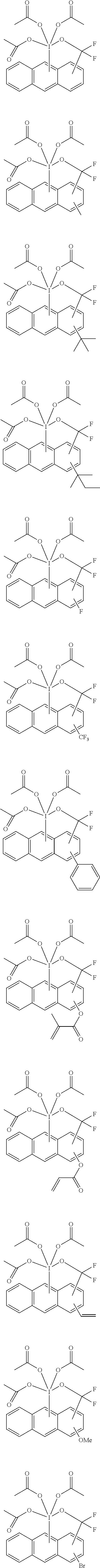

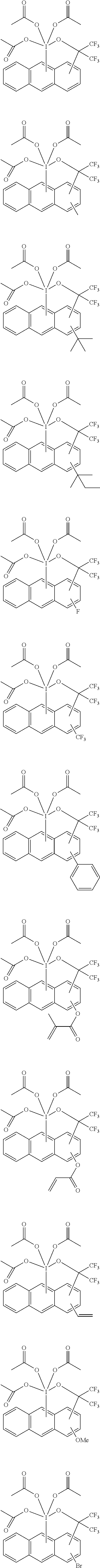

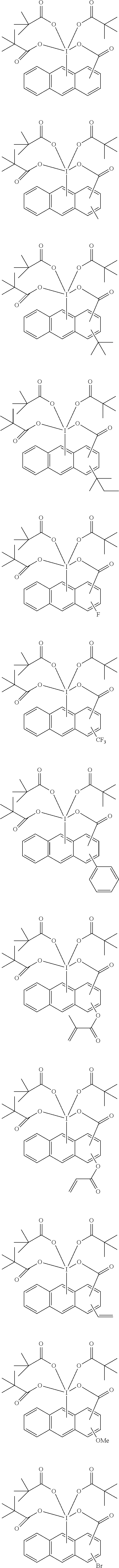

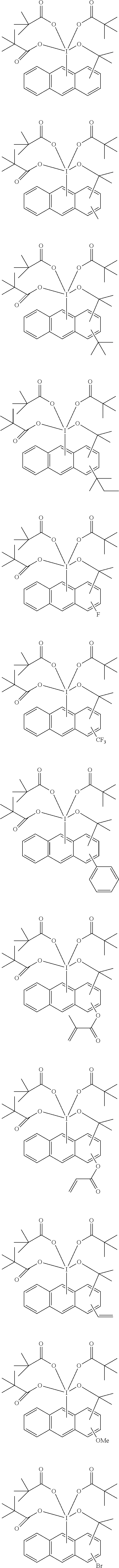

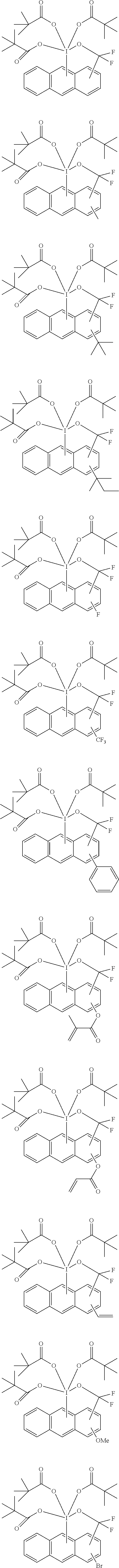

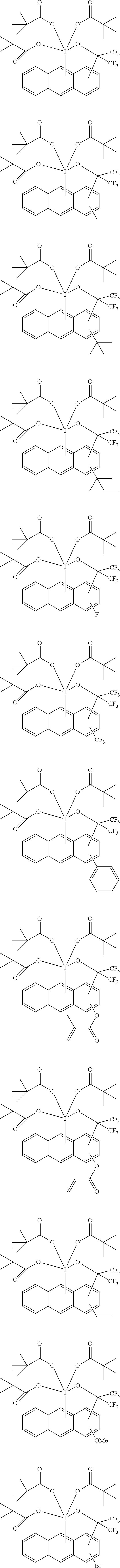

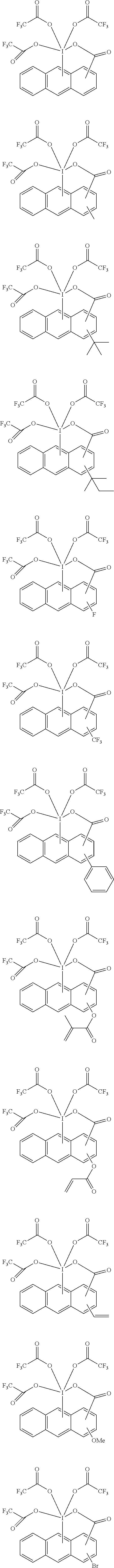

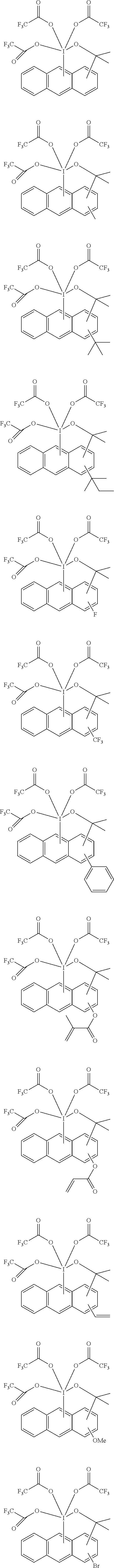

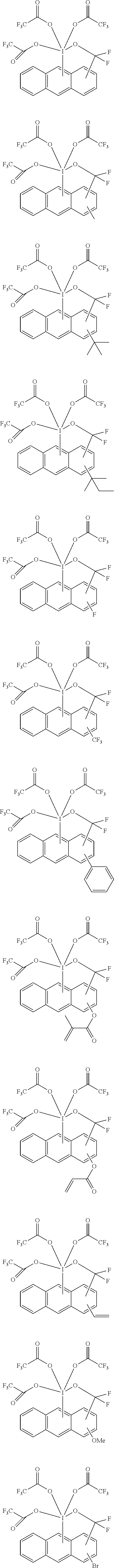

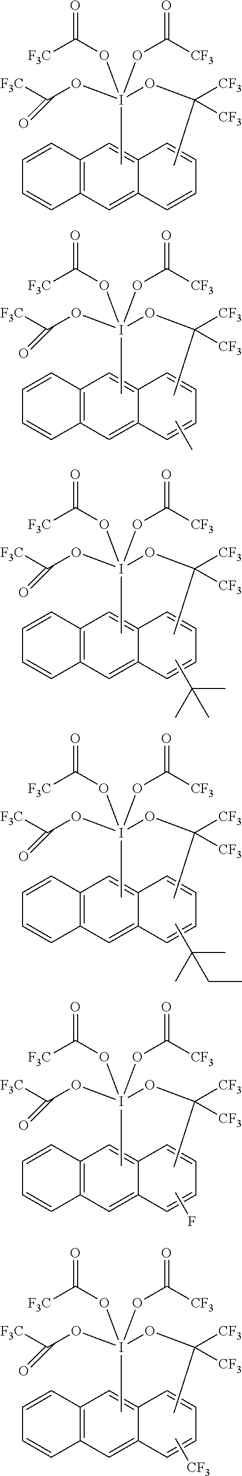

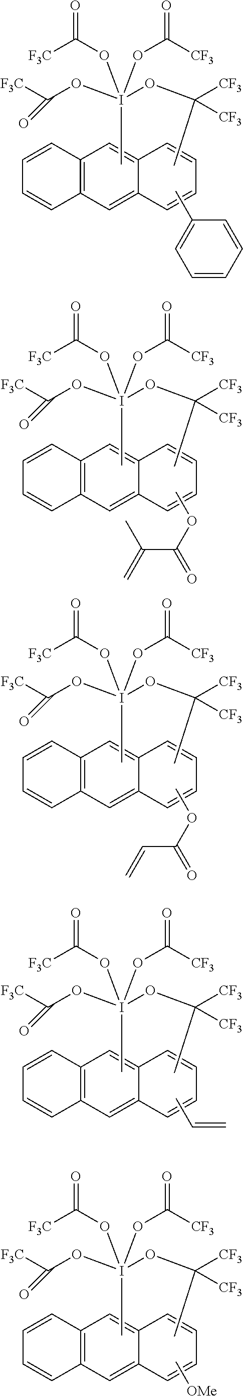

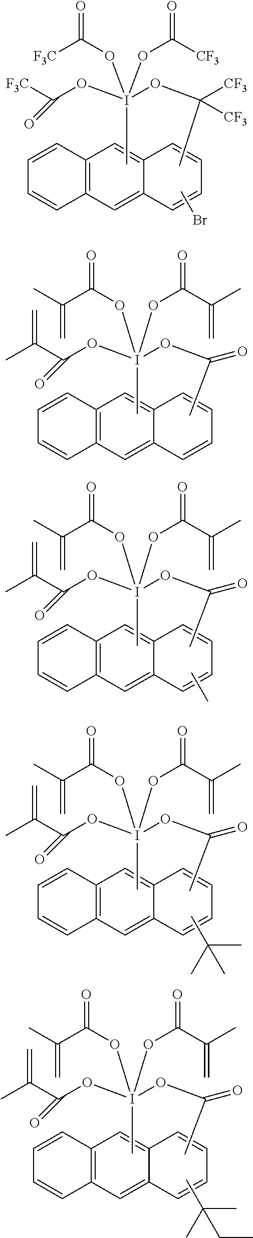

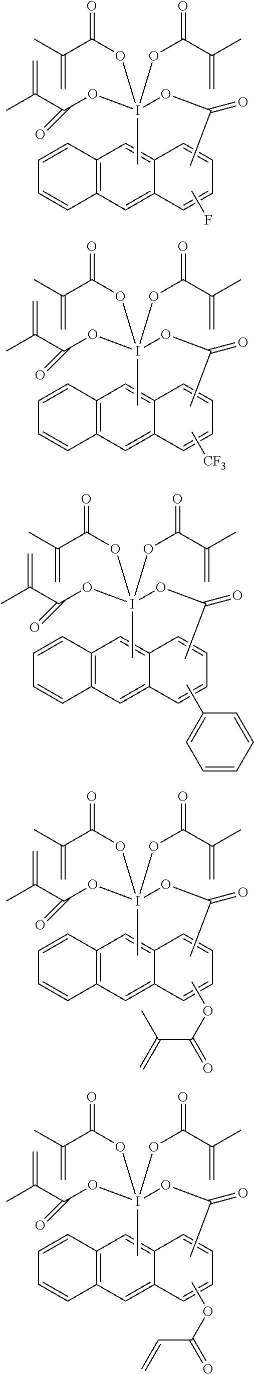

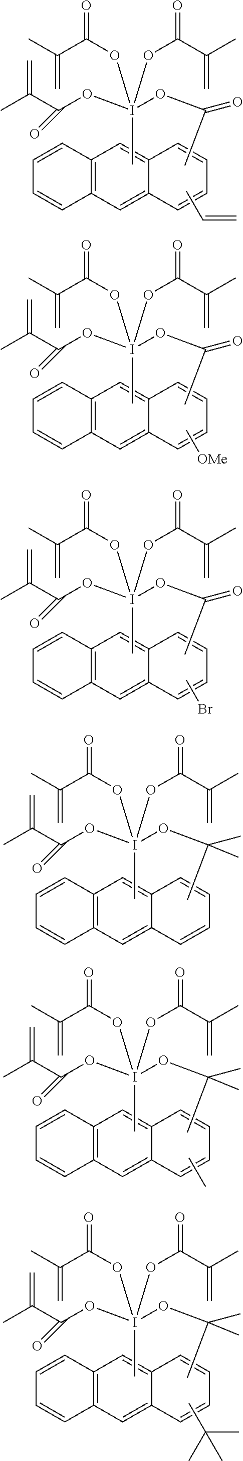

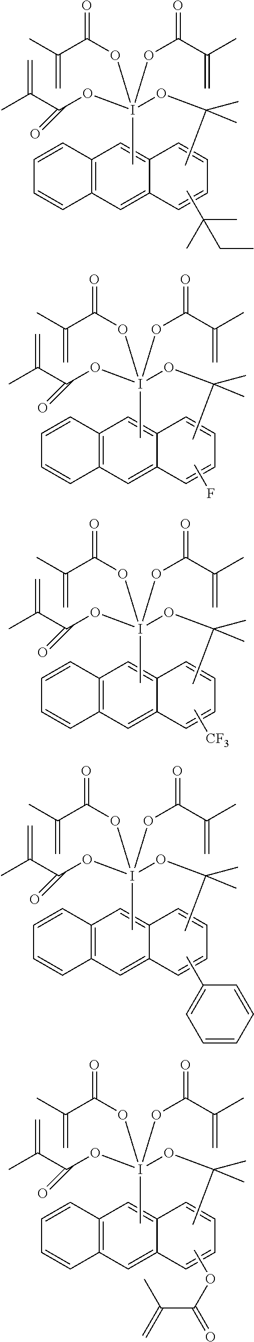

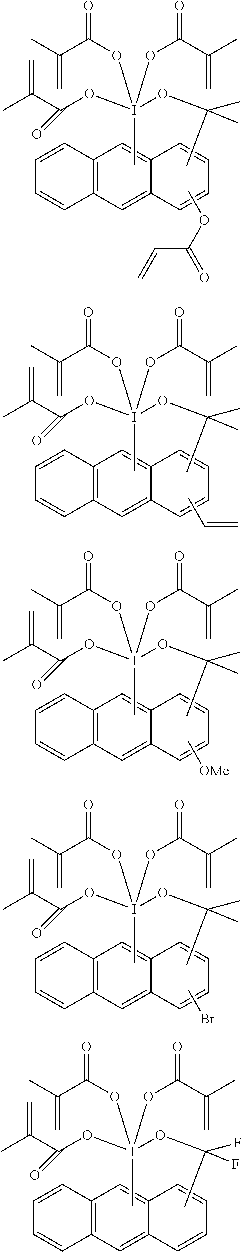

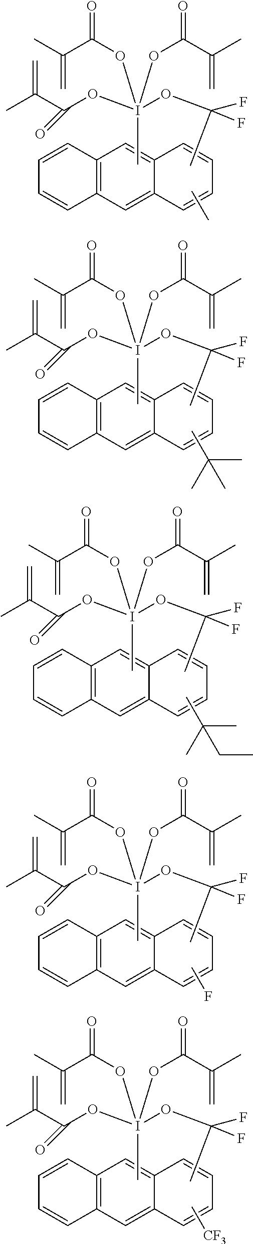

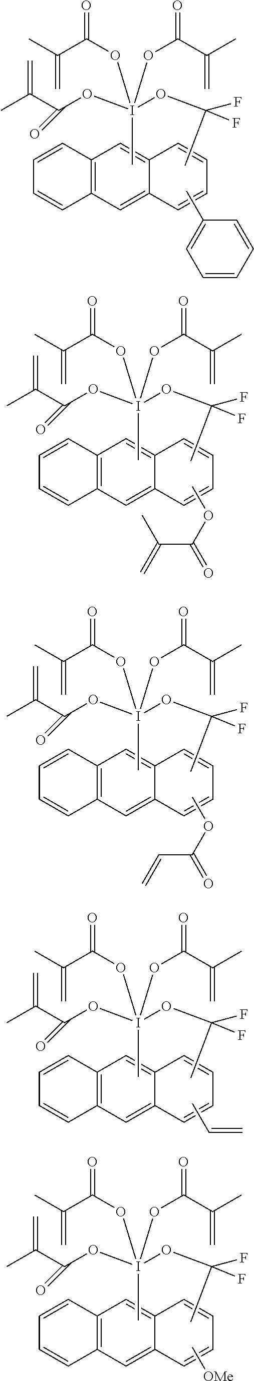

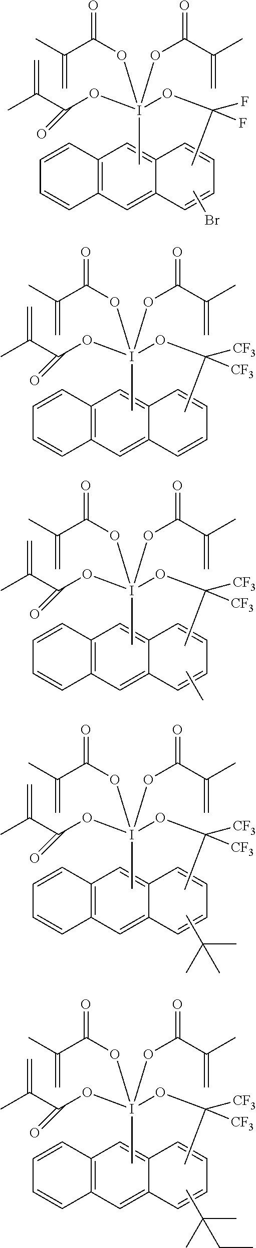

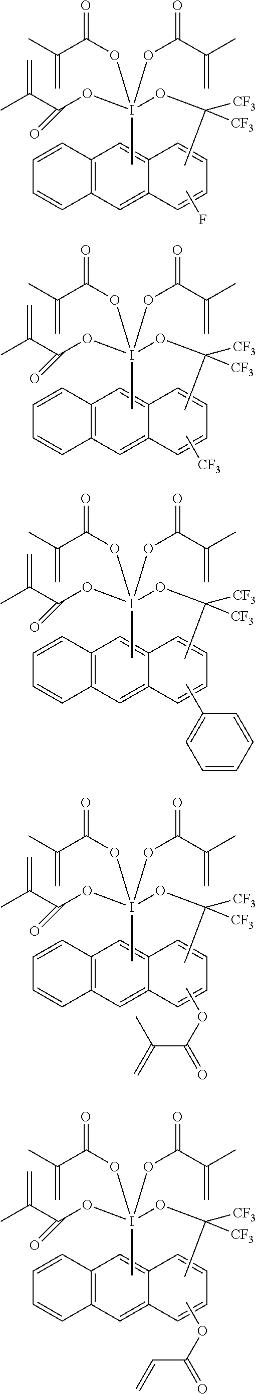

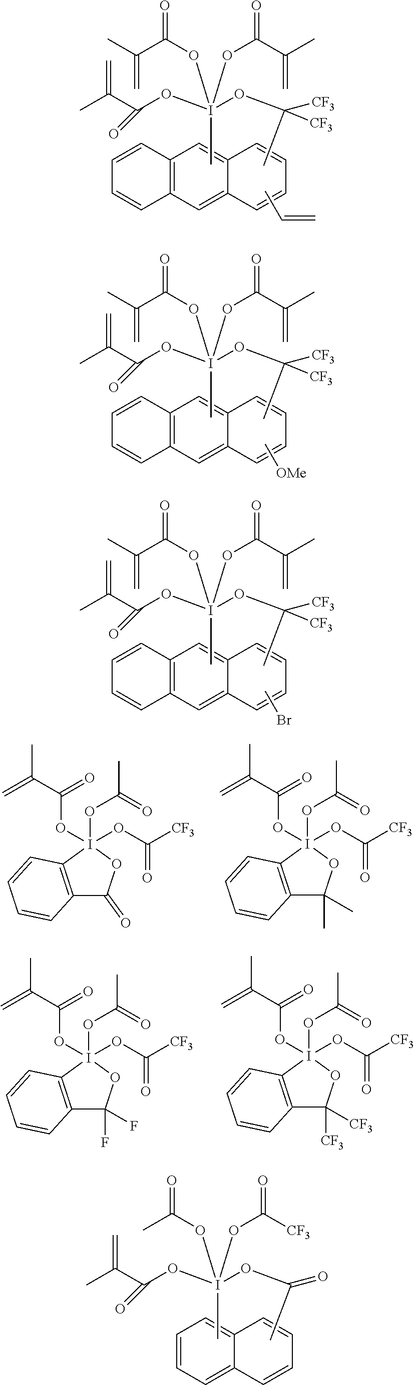

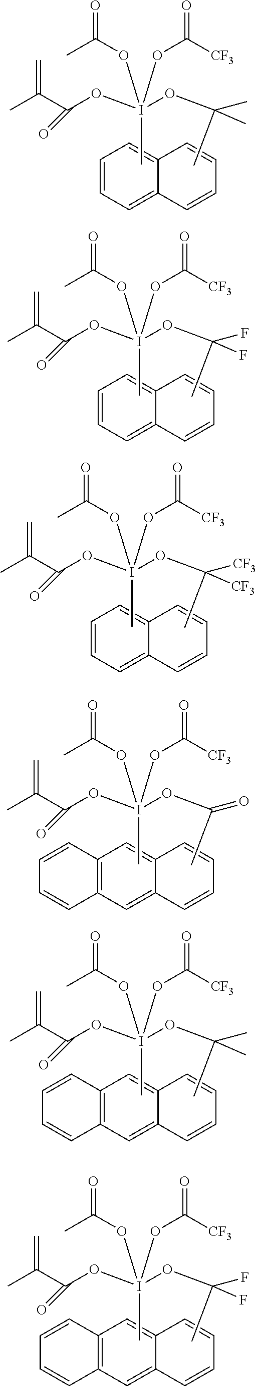

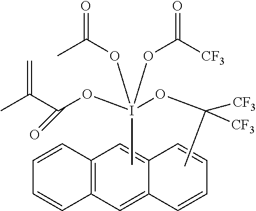

### [Carboxy Group-Containing Compound]

The carboxy group-containing compound is preferably one or both of a polymer having a repeating unit represented by the following formula (2) and a compound represented by the following formula (3).

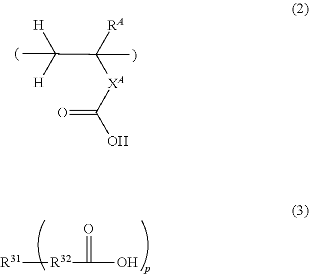

In the formula (2), R^{A} represents a hydrogen atom, a halogen atom, a methyl group, or a trifluoromethyl group. X^{A} represents a single bond, a phenylene group, a naphthylene group, or *—C(═O)—O—X^{A1}—. X^{A1} represents a saturated hydrocarbylene group having 1 to 10 carbon atoms, a phenylene group or a naphthylene group. The saturated hydrocarbylene group may have a hydroxy group, an ether bond, an ester bond, or a lactone ring. “*” represents an attachment point to a carbon atom of the main chain.

In the formula (3), “p” is 1, 2, 3 or 4.

In the formula (3), R³¹ is a p-valent hydrocarbon group having 1 to 40 carbon atoms or a p-valent heterocyclic group having 2 to 40 carbon atoms. When “p” is 2, R³¹ may be an ether bond, a carbonyl group, an azo group, a thioether bond, a carbonate bond, a carbamate bond, a sulfinyl group, or a sulfonyl group. Part or all of the hydrogen atoms of the p-valent hydrocarbon group or p-valent heterocyclic group may be substituted with a group having a heteroatom, and part of the —CH₂— groups of the p-valent hydrocarbon group may be substituted with a group having a heteroatom.

In the formula (3), R³² is a single bond or a hydrocarbylene group having 1 to 20 carbon atoms, and part or all of the hydrogen atoms of the hydrocarbylene group may be substituted with a group having a heteroatom, or part of the —CH₂— groups of the hydrocarbylene group may be substituted with a group having a heteroatom. When “p” is 2, 3, or 4, R³²s may be identical to or different from each other.

The p-valent hydrocarbon group represented by R³¹ may be saturated or unsaturated, and may be linear, branched, or cyclic. The p-valent hydrocarbon group is a group obtained by eliminating p hydrogen atoms from a hydrocarbon. Examples of the hydrocarbon include alkanes having 1 to 40 carbon atoms, alkenes having 2 to 40 carbon atoms, alkynes having 2 to 40 carbon atoms, saturated cyclic hydrocarbons having 3 to 40 carbon atoms, unsaturated cyclic hydrocarbons having 3 to 40 carbon atoms, and aromatic hydrocarbons having 6 to 40 carbon atoms.

Examples of the alkanes having 1 to 40 carbon atoms include methane, ethane, propane, butane, pentane, hexane, heptane, octane, nonane, decane, and structural isomers thereof.

Examples of the alkenes having 2 to 40 carbon atoms include ethylene, propylene, butene, pentene, hexene, heptene, octene, nonene, decene, and structural isomers thereof.

Examples of the alkyne having 2 to 40 carbon atoms include acetylene, propyne, butyne, pentyne, hexyne, heptyne, octyne, nonyne, decyne, and structural isomers thereof.

Examples of the cyclic saturated hydrocarbon having 3 to 40 carbon atoms include cyclopropane, cyclobutane, cyclohexane, cycloheptane, cyclooctane, adamantane, and norbornane.

Examples of the cyclic unsaturated hydrocarbon having 3 to 40 carbon atoms include cyclopropene, cyclobutene, cyclopentene, cyclohexene, cycloheptene, cyclooctene, and norbornene.

Examples of the aromatic hydrocarbons having 6 to 40 carbon atoms include benzene, naphthalene, and biphenyl.

The p-valent heterocyclic group represented by R³¹ is a group obtained by eliminating p hydrogen atoms from a heterocyclic compound. Examples of the heterocyclic compound include furan, pyridine, pyrazole, and thiazolidine.

In the p-valent hydrocarbon group or p-valent heterocyclic group, part or all of its hydrogen atoms may be substituted with a group having a heteroatom, such as an oxygen atom, a sulfur atom, a nitrogen atom, or a halogen atom, and as a result, the p-valent hydrocarbon group or p-valent heterocyclic group may contain a hydroxy group, a cyano group, a fluorine atom, a chlorine atom, a bromine atom, an iodine atom, etc. Furthermore, In the p-valent hydrocarbon group, part of its consisting —CH₂— groups may be substituted with a group having a heteroatom, such as an oxygen atom, a sulfur atom, or a nitrogen atom, and as a result, the p-valent hydrocarbon group may have a carbonyl group, an ether bond, a thioether bond, an ester bond, a sulfonate ester bond, a carbonate bond, a carbamate bond, a lactone ring, a sultone ring, a carboxylic acid anhydride (—C(═O)—O—C(═O)—), etc.

The hydrocarbylene group having 1 to 20 carbon atoms represented by R³² may be saturated or unsaturated, and may be linear, branched, or cyclic. Specific examples thereof include: alkanediyl groups having 1 to 20 carbon atoms, such as a methanediyl group, an ethane-1,1-diyl group, an ethane-1,2-diyl group, propane-1,2-diyl group, a propane-1,3-diyl group, butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, and a dodecane-1,12-diyl group; cyclic saturated hydrocarbylene groups having 3 to 20 carbon atoms, such as a cyclopentanediyl group, a cyclohexanediyl group, a norbornanediyl group, and an adamantanediyl group; unsaturated aliphatic hydrocarbylene groups having 2 to 20 carbon atoms, such as a vinylene group and a propene-1,3-diyl group; arylene groups having 6 to 20 carbon atoms, such as a phenylene group and a naphthylene group; and groups obtained by combining these groups. Furthermore, part or all of the hydrogen atoms of the hydrocarbylene group may be substituted with a group having a heteroatom, such as an oxygen atom, a sulfur atom, a nitrogen atom, or a halogen atom, or part of the —CH₂— groups constituting the hydrocarbylene group may be substituted with a group having a heteroatom, such as an oxygen atom, a sulfur atom, or a nitrogen atom, and as a result, the hydrocarbylene group may contain a hydroxy group, a cyano group, a fluorine atom, a chlorine atom, a bromine atom, an iodine atom, a carbonyl group, an ether bond, a thioether bond, an ester bond, a sulfonate ester bond, a carbonate bond, a carbamate bond, a lactone ring, a sultone ring, a carboxylic acid anhydride, etc.

Among the carboxylic acid compounds (low-molecular compounds) represented by the formula (3), those in which “p” is 2, 3, or 4 are preferable. In these cases, when mixed with a hypervalent iodine compound, a strong resist film with high-molecular-weight is easily formed, which is preferable from the viewpoints of etching resistance and developer resistance.

Specific examples of the carboxy group-containing repeating unit represented by the formula (2) include, but are not limited to, those shown below. In the following formulae, R^{A} is the same as defined above.

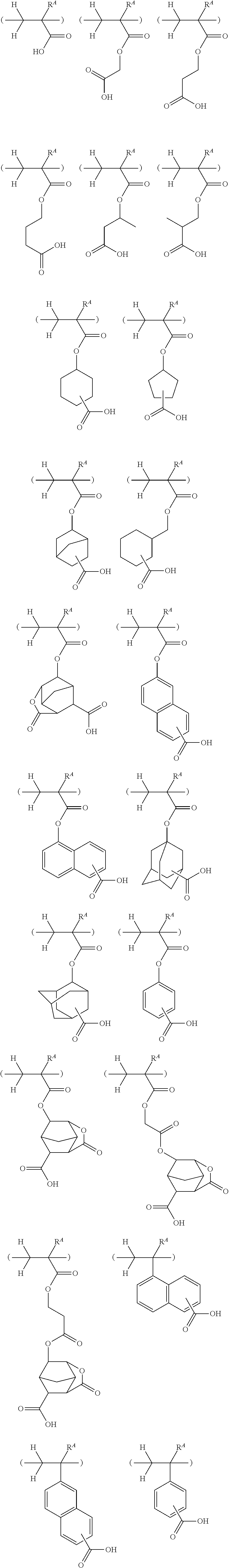

Examples of the carboxylic acid compound represented by the formula (3) include, but are not limited to, the following. The carboxylic acid compound may be a commercially available product or may be synthesized.

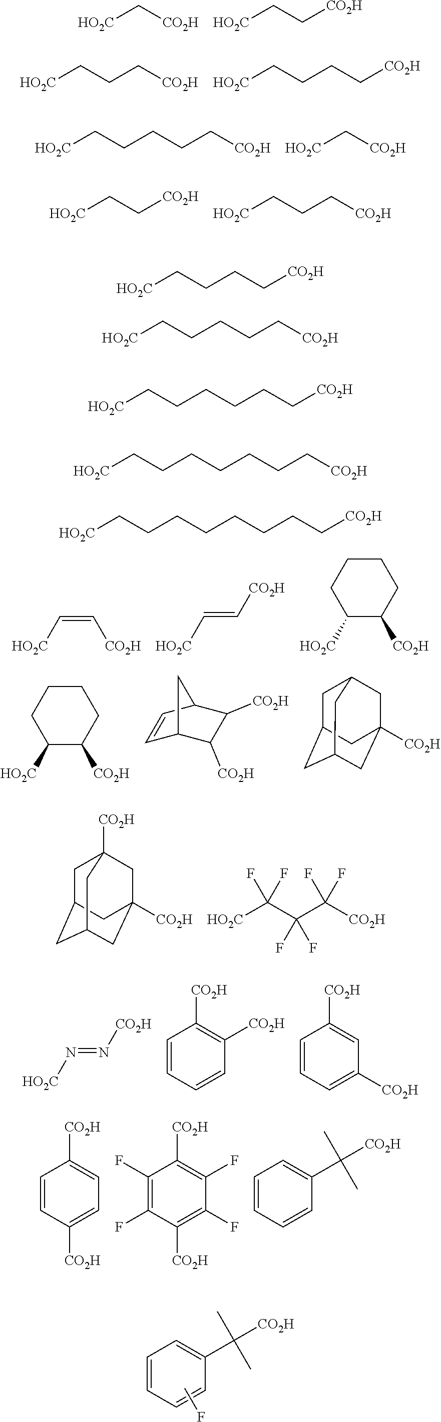

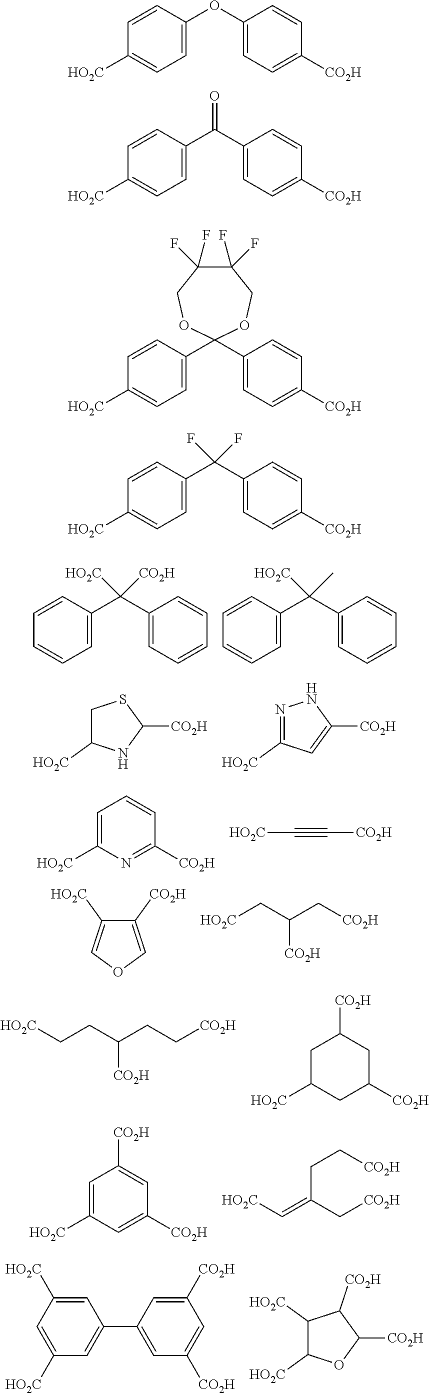

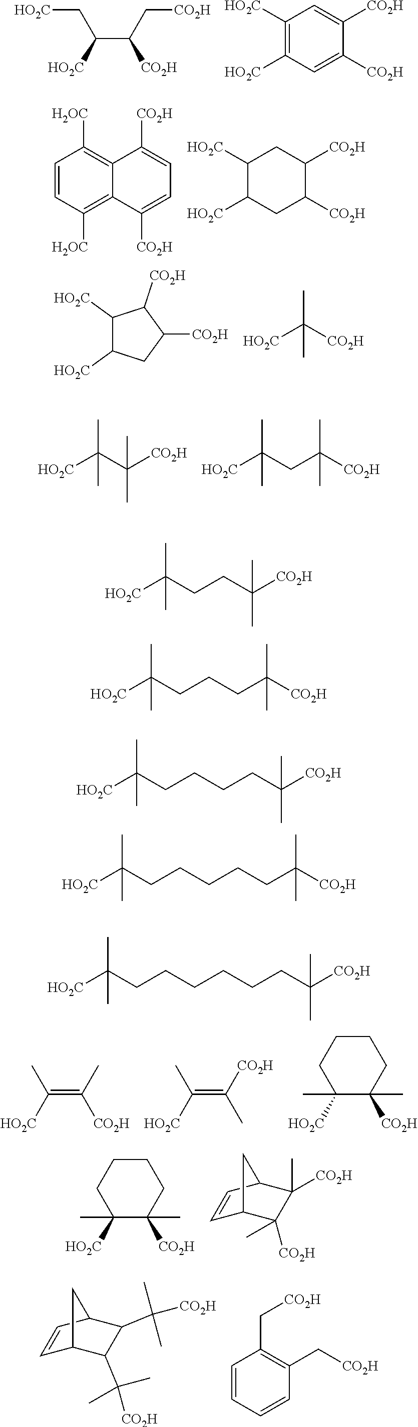

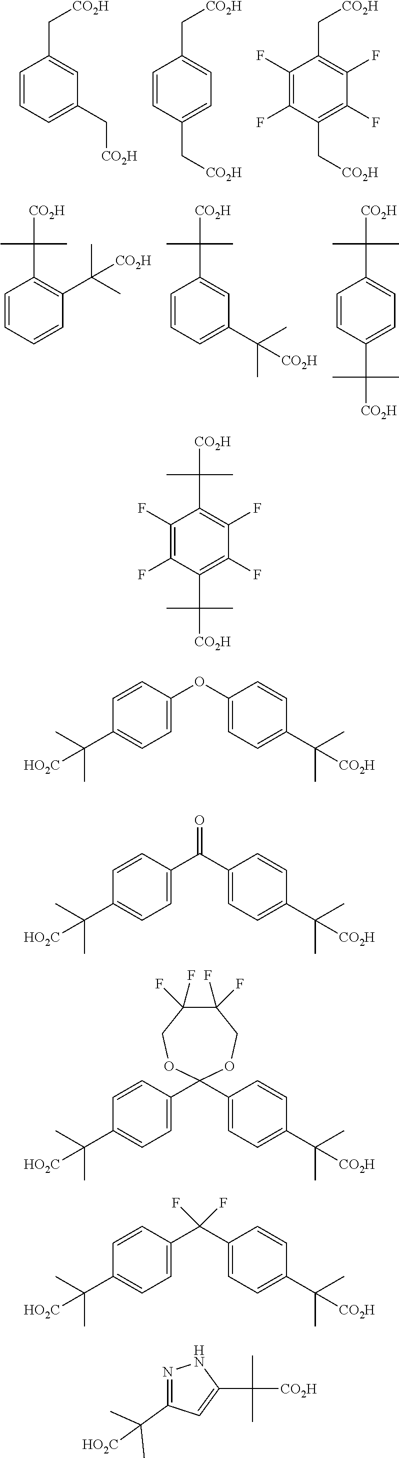

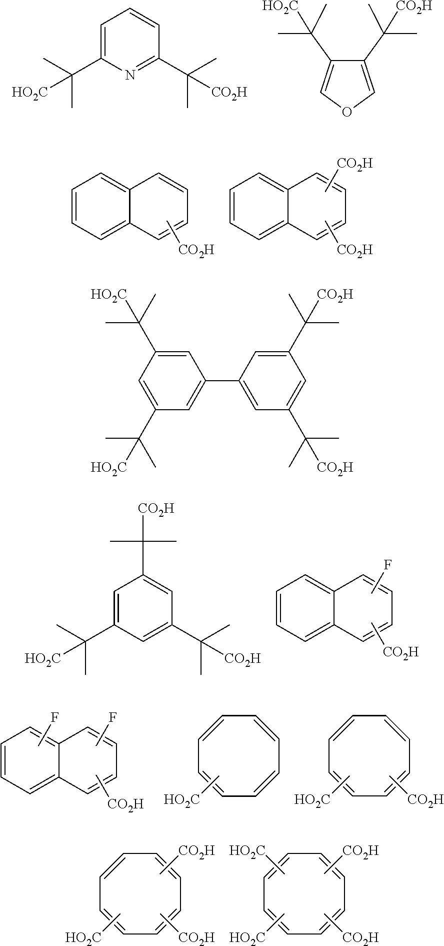

The carboxyl group-containing polymer having the repeating unit represented by the formula (2) may further contain a repeating unit other than the repeating unit represented by the formula (2) (hereinafter also referred to as “other repeating unit”). The other repeating unit is not particularly limited, but is preferably one that can improve the solubility in a solvent of a polymer that is poorly soluble in the solvent in the case that the polymer contains only a repeating unit having a carboxyl group. As the other repeating units, repeating units with a rigid skeleton having a cyclic structure that is expected to have high etching resistance, and repeating units having a styrene skeleton are preferable.

Specific examples of the other repeating units include, but are not limited to, those shown below. In the following formulae, R^{A} is the same as defined above, and X^{B} is each independently —CH₂— or —O—.

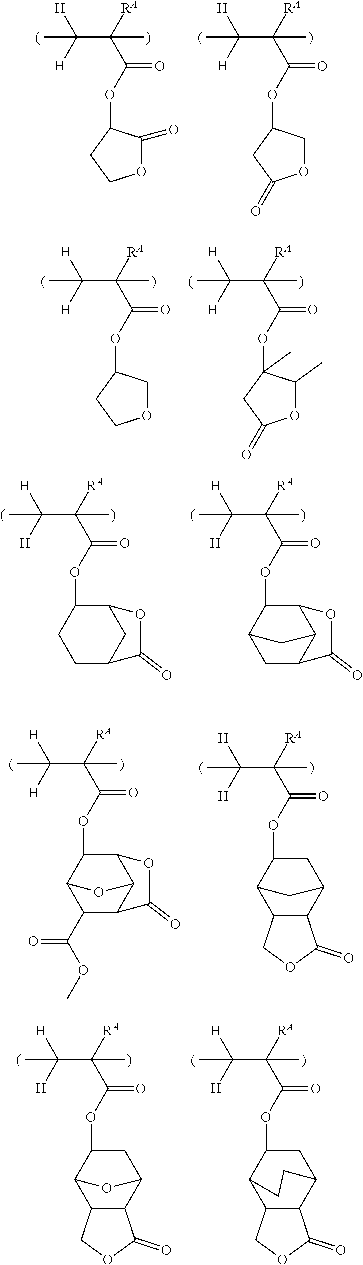

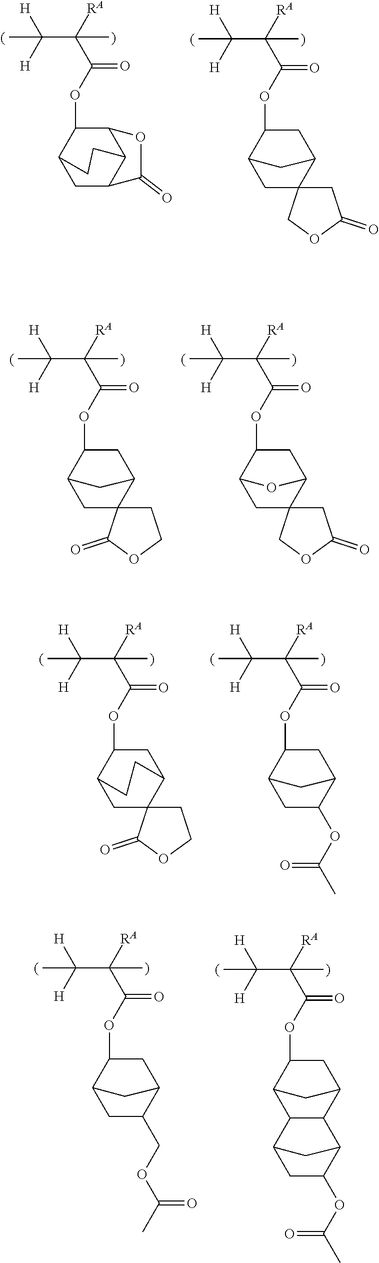

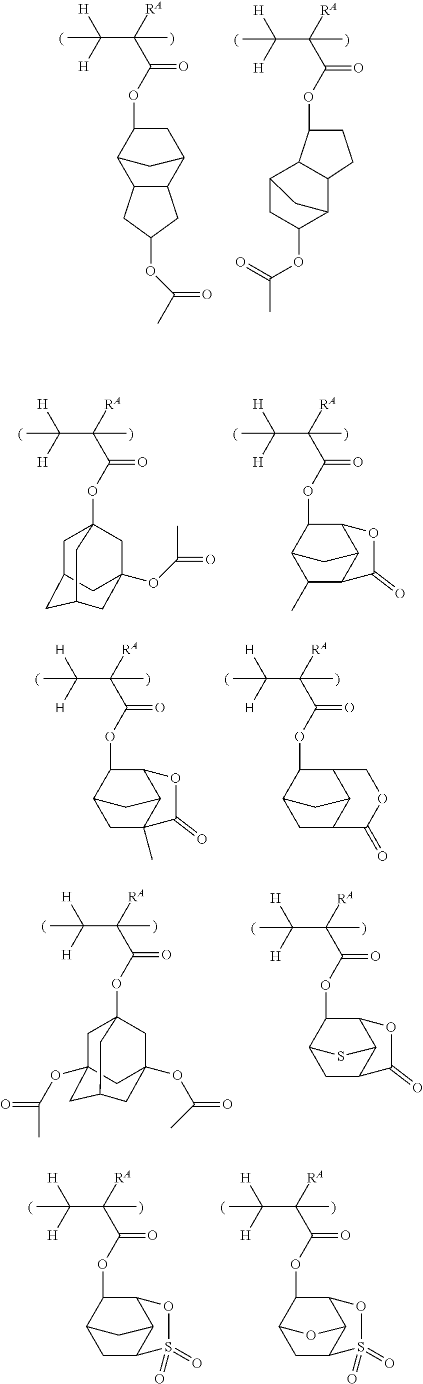

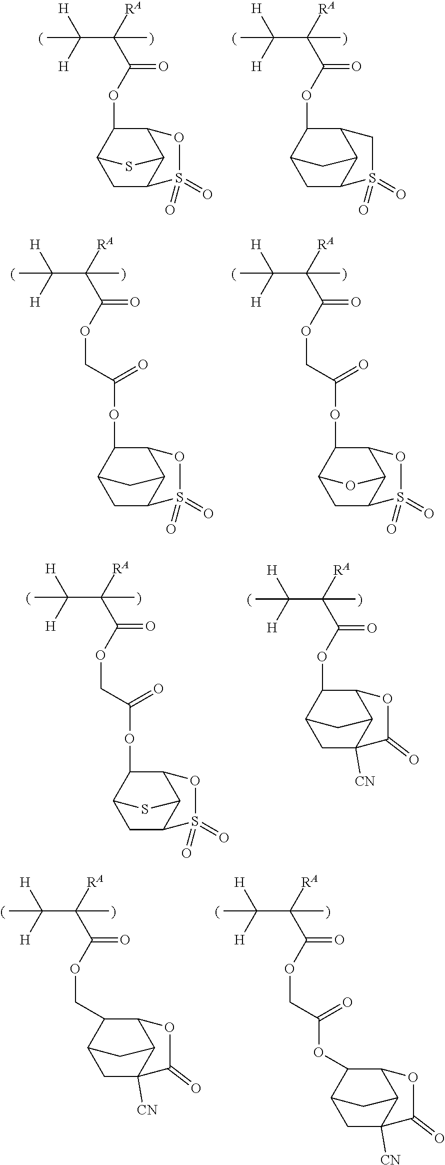

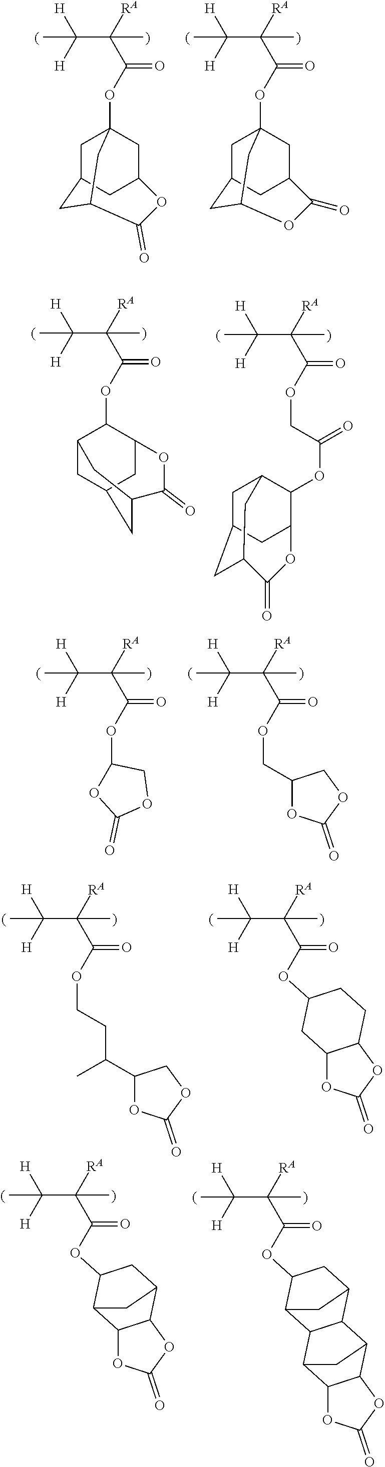

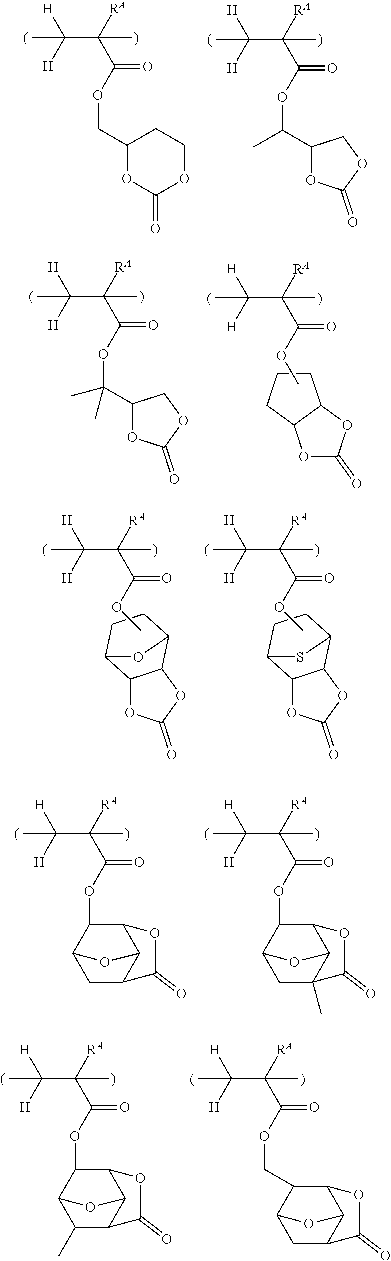

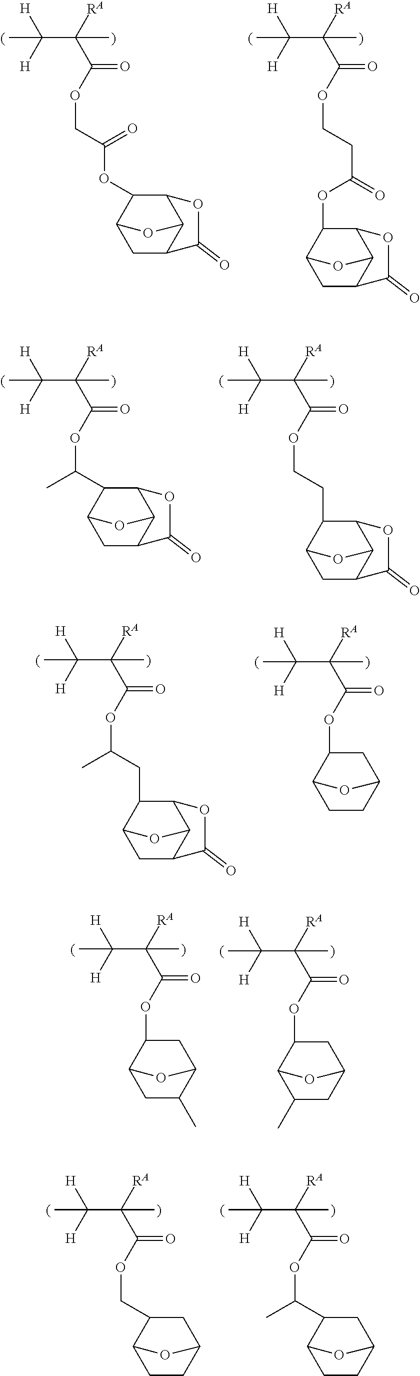

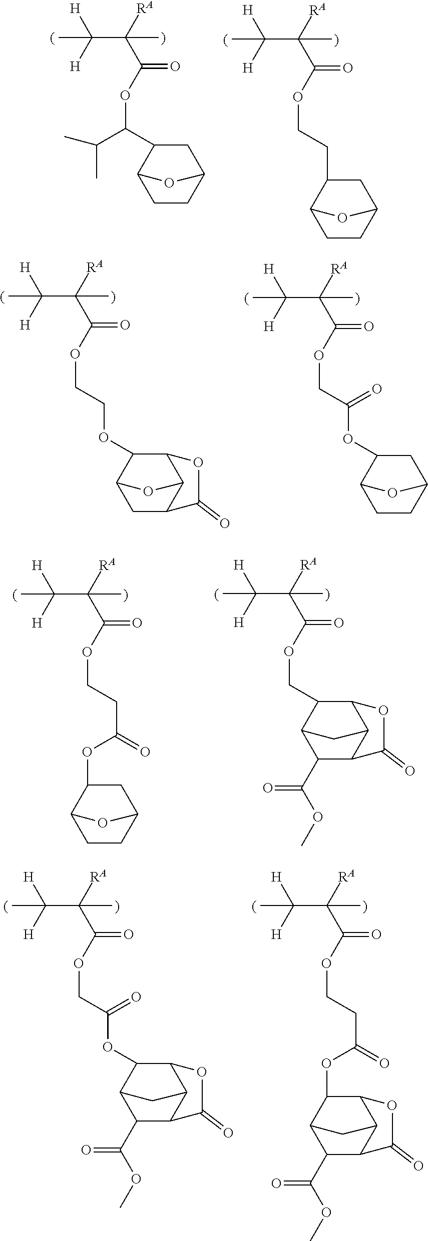

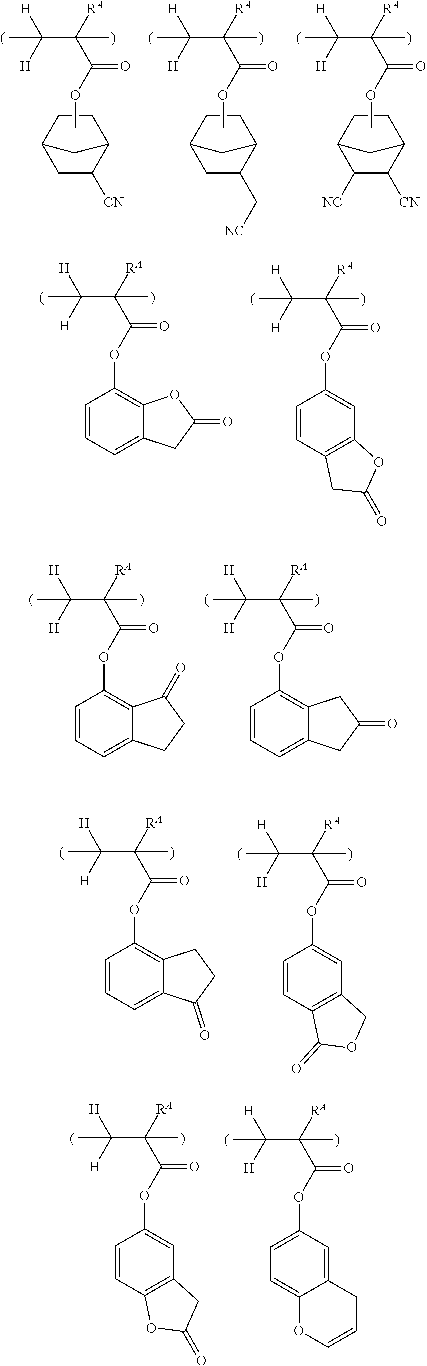

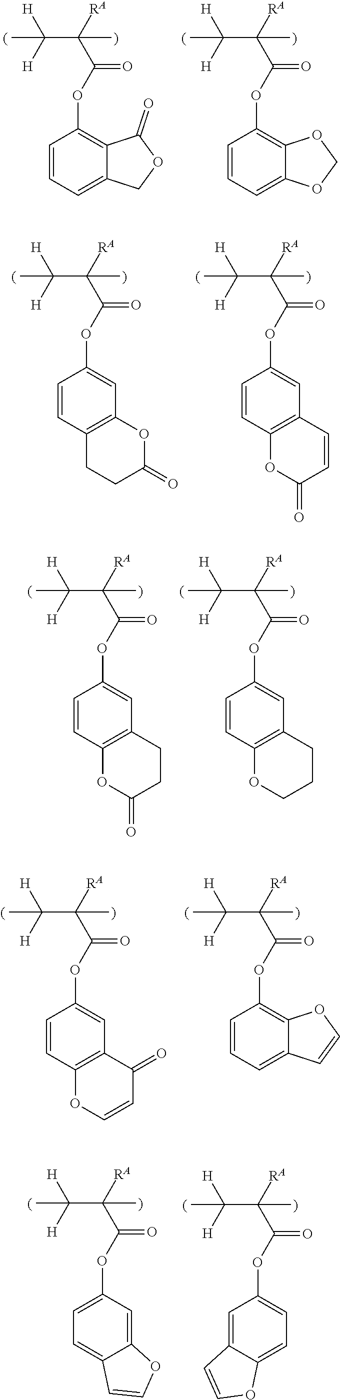

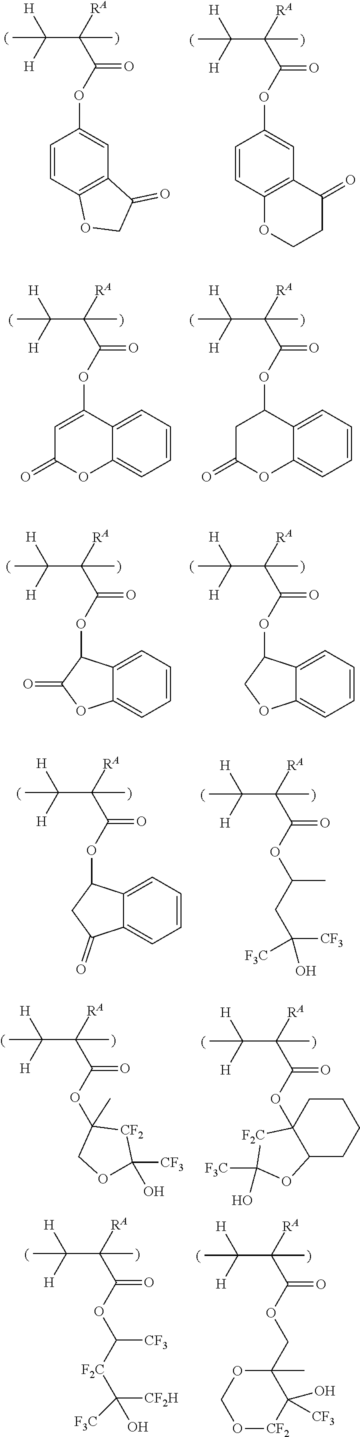

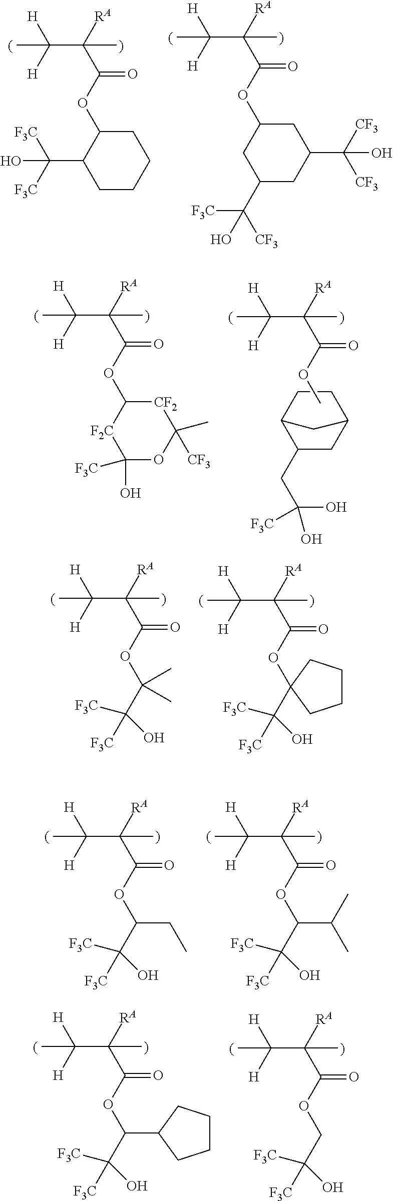

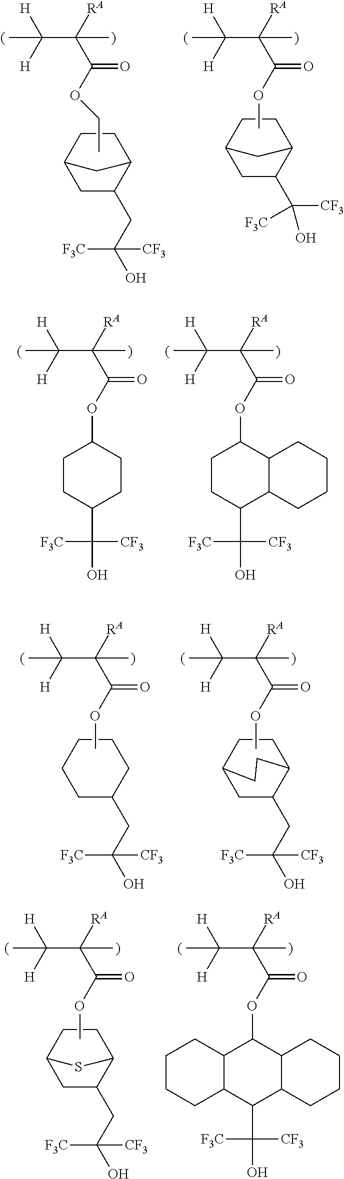

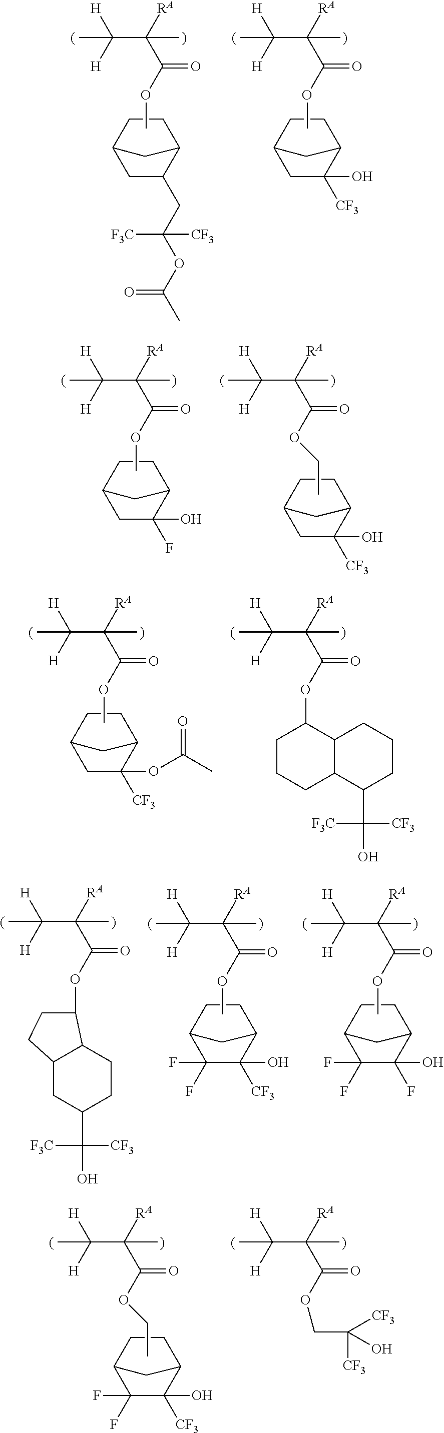

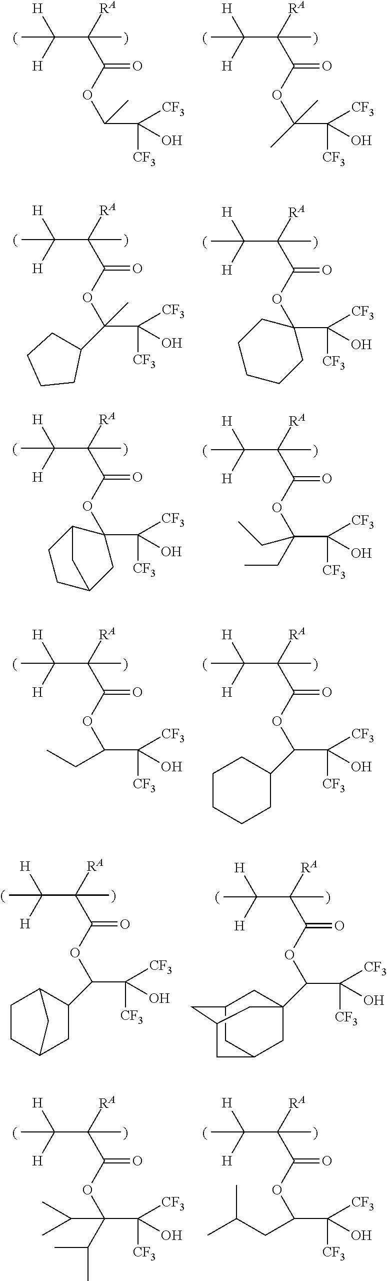

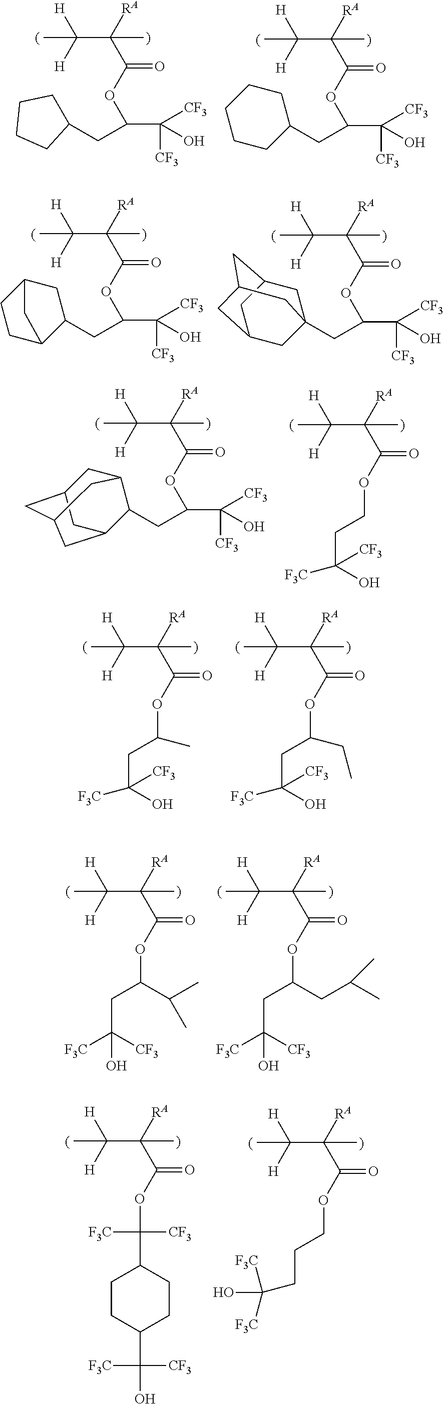

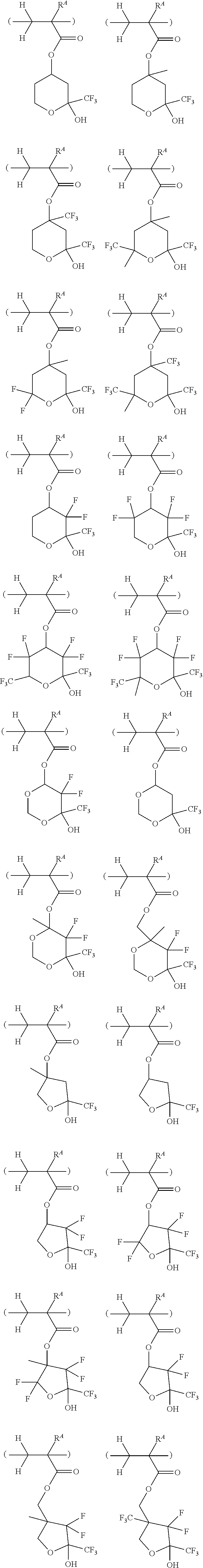

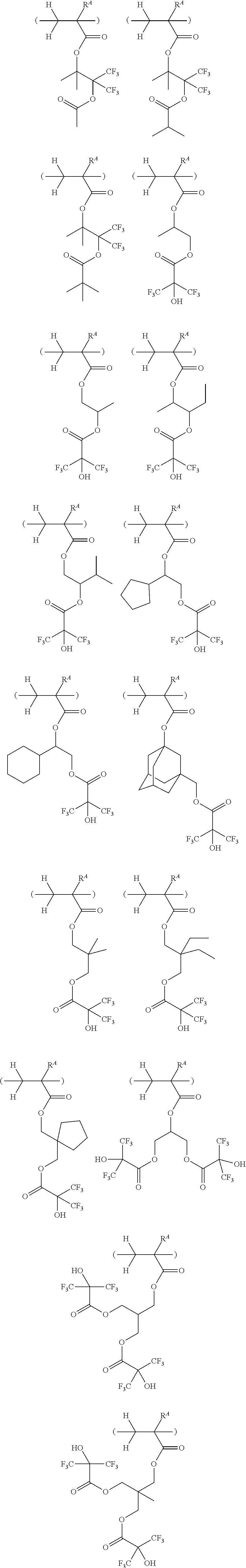

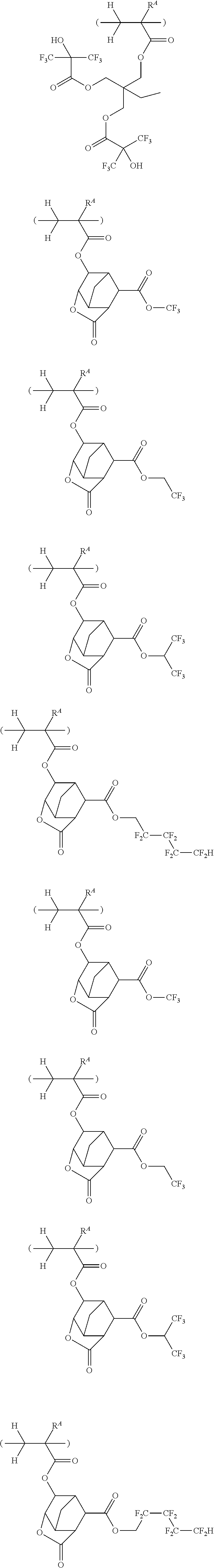

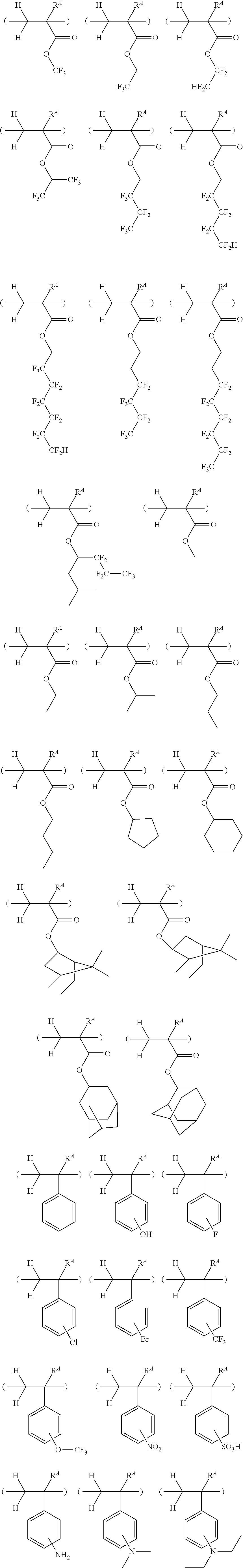

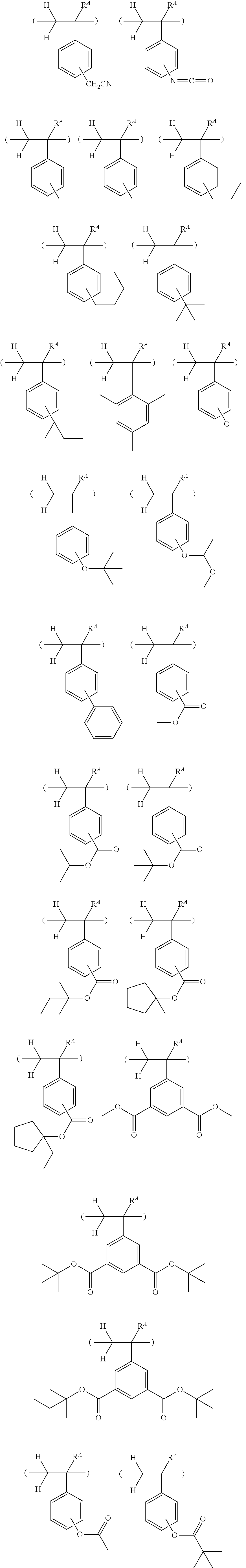

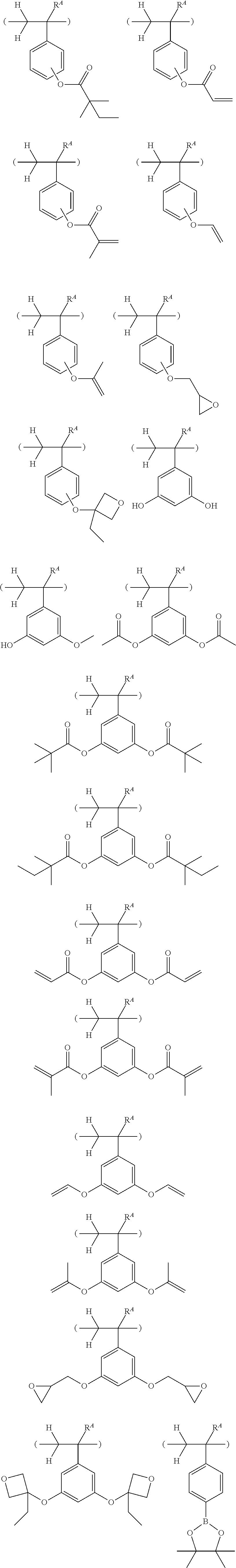

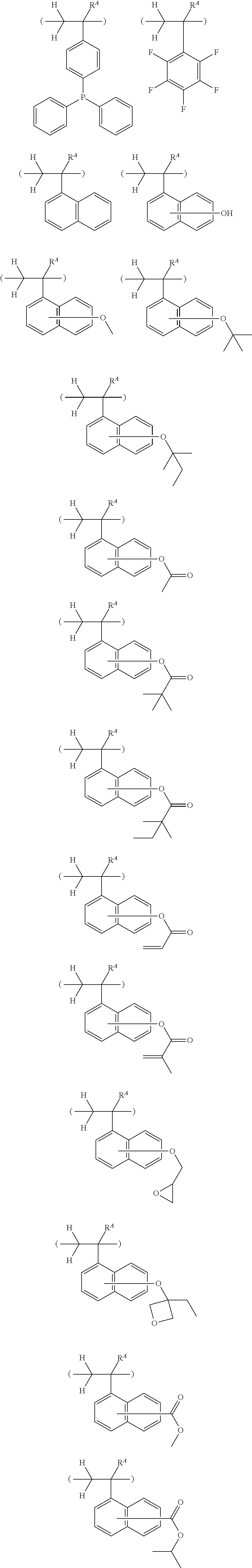

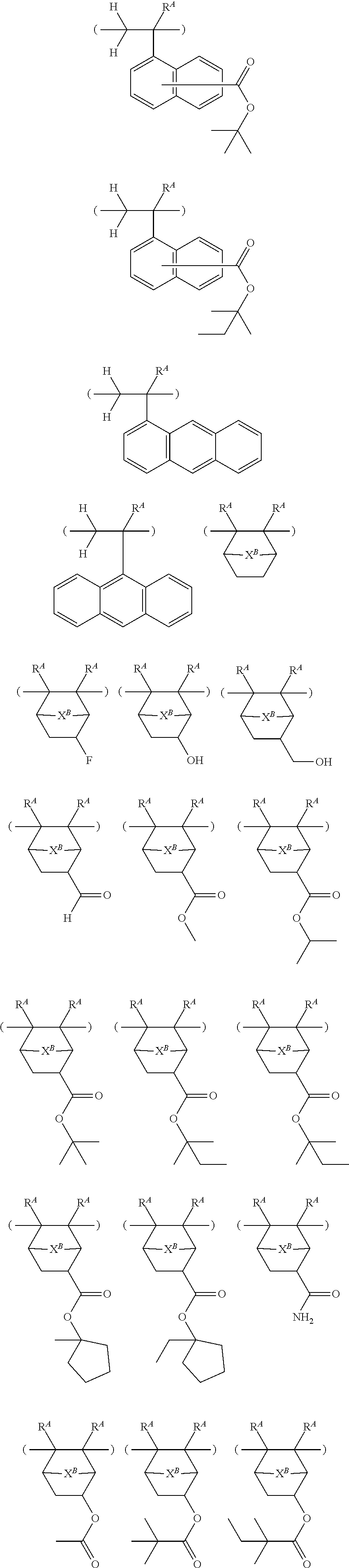

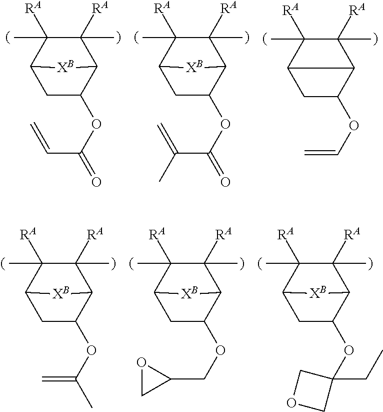

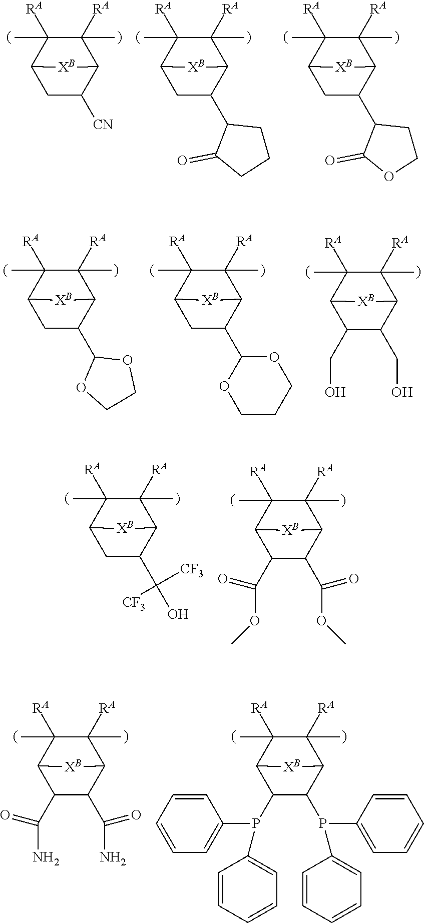

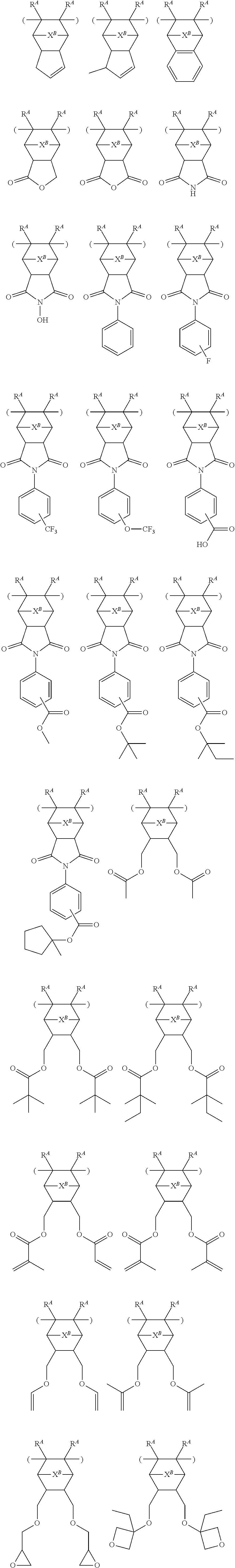

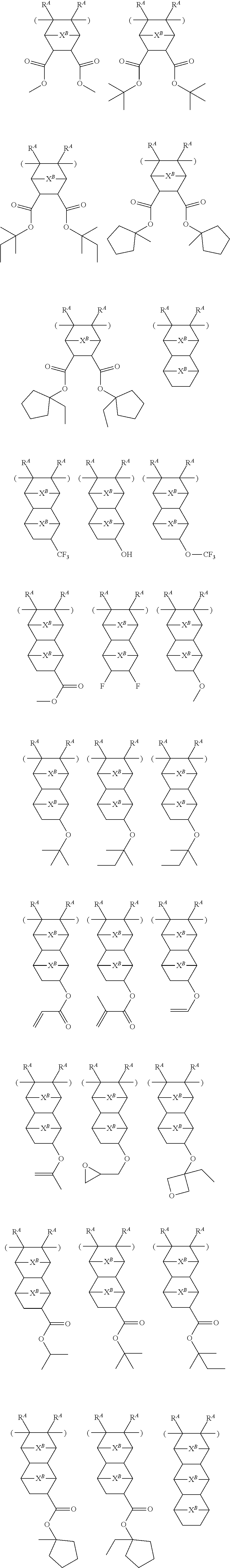

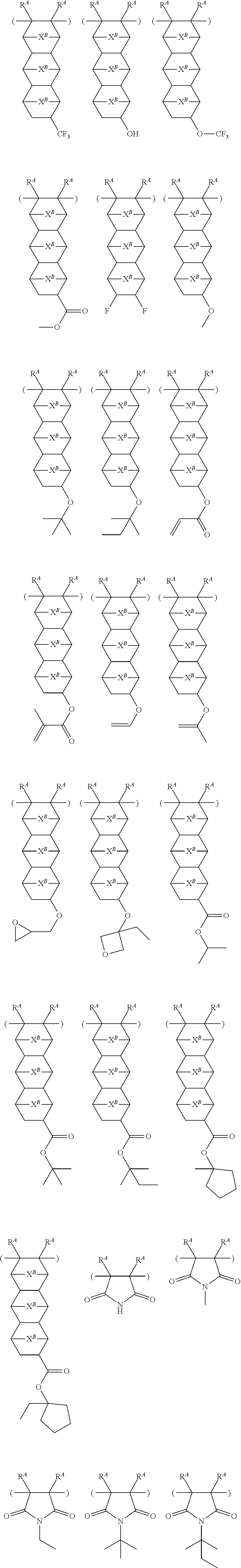

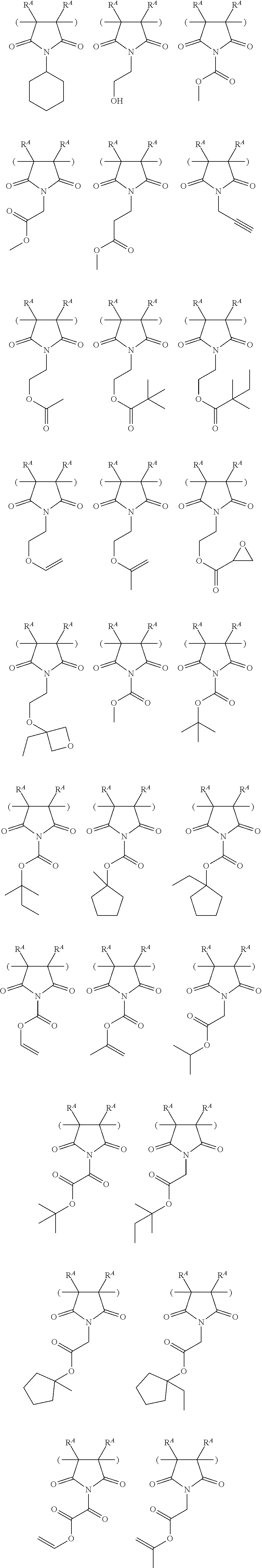

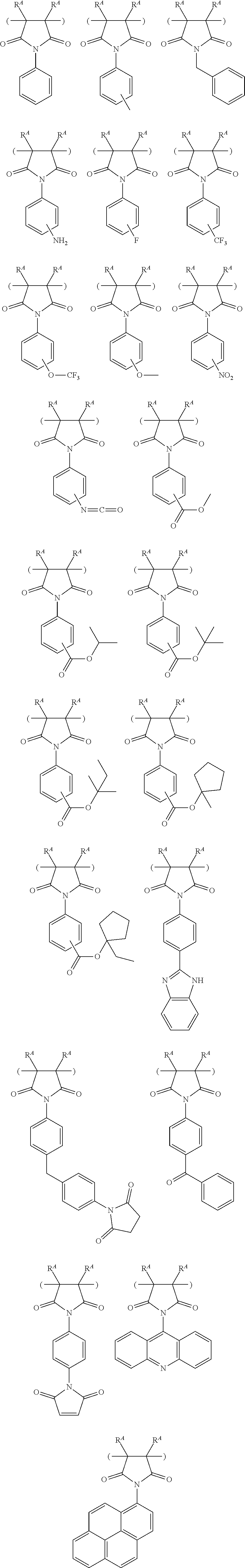

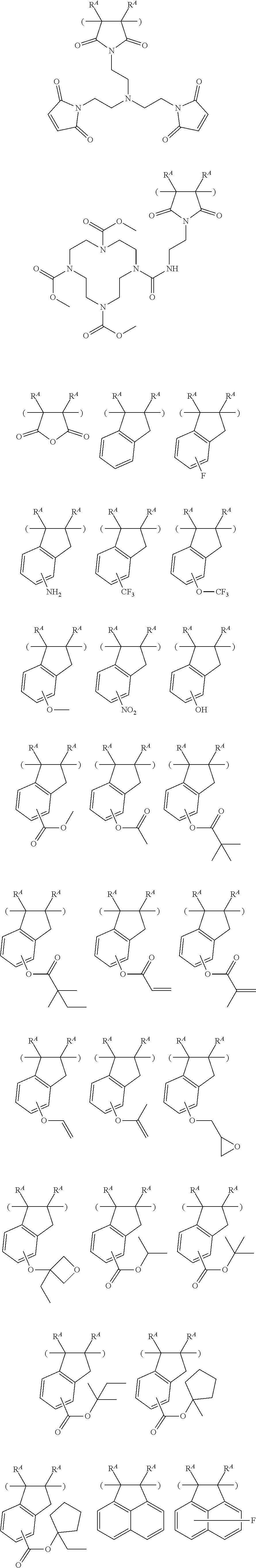

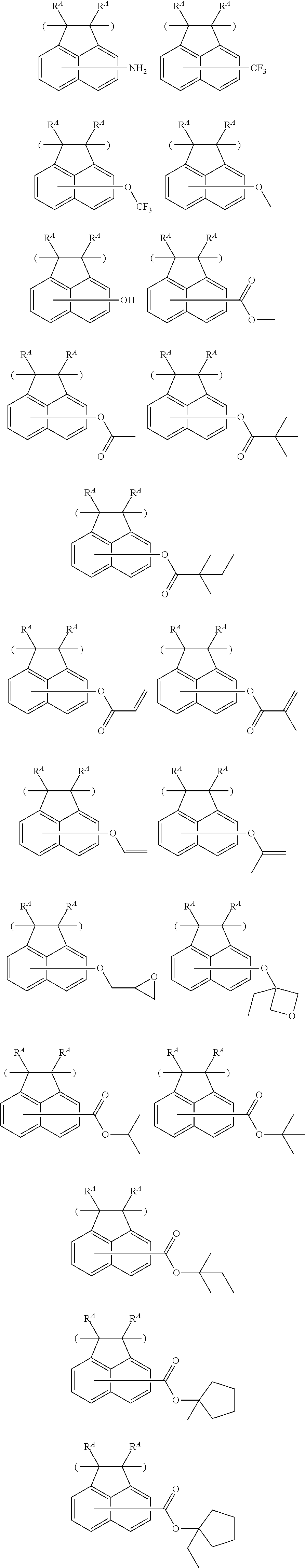

In the resist composition, the content ratio of the hypervalent iodine compound relative to the carboxy group-containing compound (a polymer having a repeating unit represented by the formula (2) and/or a compound represented by the formula (3)) (when the carboxy group-containing compound is a carboxy group-containing polymer, this is the content ratio of the hypervalent iodine compound (moles) to the carboxylic acid-containing repeating units (moles) in the polymer; and when the carboxy group-containing compound is a low-molecular compound represented by the formula (3), this is the content ratio of the hypervalent iodine compound (moles) to the low-molecular compound (moles)) is preferably 1:99 to 99:1, more preferably 10:90 to 90:10, and further preferably 20:80 to 80:20, in terms of a mole ratio. One kind of the hypervalent iodine compound may be used or two or more kinds thereof may be used in combination. One kind of the carboxyl group-containing polymer may be used or two or more kinds thereof having different composition ratios, weight average molecular weights (Mw), and/or molecular weight distributions (Mw/Mn) may be used in combination. One kind of the low-molecular compound may be used or two or more kinds thereof may be used in combination. Either of the carboxyl group-containing polymer or the low-molecular compound may be used, or both of them may be used in combination.

In the carboxy group-containing polymer, the content ratio (molar ratio) of the carboxy group-having repeating unit and the other repeating unit is preferably 10:90 to 90:10, more preferably 15:85 to 85:15, and further preferably 20:80 to 80:20.

The weight average molecular weight (Mw) of the carboxy group-containing polymer is preferably 1,000 to 500,000, and more preferably 3,000 to 100,000. In the present invention, Mw and number average molecular weight Mn are values measured in terms of standard polystyrene by gel permeation chromatography (GPC) using tetrahydrofuran (THF) as a solvent.

Furthermore, when the carboxyl group-containing polymer has a broad molecular weight distribution (Mw/Mn), due to the presence of low-molecular-weight polymers and high-molecular-weight polymers, there is a risk of appearance of foreign matters on a pattern after exposure, or degradation of a pattern shape. Therefore, since the influence of Mw and Mw/Mn tends to become greater as patterning rules become finer, it is preferable that the carboxyl group-containing polymer has a narrow Mw/Mn distribution of 1.0 to 2.0, in order to obtain a resist composition that can be used suitably for fine pattern dimensions.

Examples of methods for synthesizing he carboxyl group-containing polymer include heating monomers that can provide a repeating unit mentioned above after adding a radical polymerization initiator in an organic solvent to polymerize the monomers.

Specific examples of the organic solvent used for the polymerization reaction include toluene, benzene, THF, diethyl ether, dioxane, cyclohexane, cyclopentane, cyclopentanone, cyclohexanone, methyl ethyl ketone (MEK), propylene glycol monomethyl ether (PGME), propylene glycol monomethyl ether acetate (PGMEA), and γ-butyrolactone (GBL). Specific examples of the polymerization initiator include 2,2′-azobisisobutyronitrile (AIBN), 2,2′-azobis(2,4-dimethylvaleronitrile), dimethyl-2,2-azobis(2-methylpropionate), 1,1′-azobis(1-acetoxy-1-phenylethane), benzoyl peroxide, and lauroyl peroxide. The adding amount of the polymerization initiator is preferably 0.01 to 25 mol % based on the total amount of monomers to be polymerized. The reaction temperature is preferably 50 to 150° C., more preferably 60 to 100° C. The reaction time is preferably 2 to 24 hours, and more preferably 2 to 12 hours. from the viewpoint of production efficiency.

The polymerization initiator may be added to the monomer solution mentioned above and then supplied to the reaction vessel, or an initiator solution may be prepared separately from the monomer solution mentioned above and then the solutions each may be supplied to the reaction vessel independently. From the viewpoint of quality control, it is preferable to prepare the monomer solution and the initiator solution independently and then add them dropwise, since the polymerization reaction may proceed due to radicals generated from the initiator during the waiting time, resulting in the formation of an ultra-high molecular weight polymer. In order to adjust the molecular weight, publicly known chain transfer agents such as dodecyl mercaptan and 2-mercaptoethanol may be used in combination. In this case, the adding amount of the chain transfer agent is preferably 0.01 to 20 mol % based on the total amount of the monomers to be polymerized.

The amount of each monomer in the monomer solution, for example, may be appropriately set so as to achieve the desired content ratio of the repeating units described above.

### [Other Hypervalent Iodine Compounds]

The inventive resist composition may further contain at least one hypervalent iodine compound represented by the following formula (4) or (5) (hereinafter also referred to as “other hypervalent iodine compounds”). By adding the other hypervalent iodine compound (I(III) compound), it is possible to control reactivity to light and adjust sensitivity.

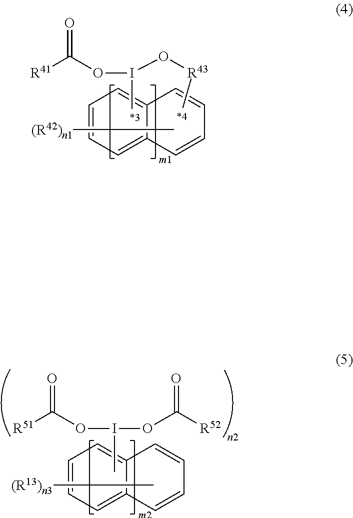

In the formulae, m1 and m2 represent integers from 0 to 2; n1 represents an integer from 0 to 4 when m1 is 0, an integer from 0 to 6 when m1 is 1, and an integer from 0 to 8 when m1 is 2; when m2 is 0, n2 represents an integer from 1 to 3, n3 represents an integer from 0 to 5, and 1≤(n2+n3)≤6 is satisfied, when m2 is 1, n2 represents an integer from 1 to 3, and n3 represents an integer from 0 to 7, and 1≤(n2+n3)≤8 is satisfied, and when m2 is 2, n2 represents an integer from 1 to 3, and n3 represents an integer from 0 to 9, and 1≤(n2+n3)≤10 is satisfied; R⁴¹ represents a halogen atom or a hydrocarbyl group having 1 to 10 carbon atoms and optionally having a heteroatom; R⁴² represents a halogen atom or a hydrocarbyl group having 1 to 40 carbon atoms and optionally having a heteroatom, R⁴²s may be identical to or different from each other when n1 is 2 to 6, and a plurality of R⁴²s may be bonded to each other to form a ring together with the carbon atoms of the aromatic ring bonded thereto; R⁴³ is a carbonyl group or a hydrocarbylene group having 1 to 10 carbon atoms and optionally having a heteroatom; *3 and *4 represent an attachment point to a carbon atom of the aromatic ring in the formula, and *3 and *4 must be bonded to adjacent carbon atoms of the aromatic ring; R⁵¹ and R⁵² represent each independently a halogen atom or a hydrocarbyl group having 1 to 10 carbon atoms and optionally having a heteroatom, R⁵¹ and R⁵² may be bonded to each other to form a ring together with the carbon atoms bonded thereto and with an atom between the carbon atoms, and when n2 is 2 to 3, R⁵¹ and R⁵² may be identical to or different from each other; and R⁵³ represents a halogen atom or a hydrocarbyl group having 1 to 40 carbon atoms and optionally having a heteroatom, R⁵³s may be identical to or different from each other when n3 is 2 to 9, and a plurality of R⁵³s may be bonded to each other to form a ring together with the carbon atoms of the aromatic ring bonded thereto.

In the above general formula (4), m1 is an integer of 0 to 2. n1 is an integer of 0 to 4 when m1 is 0, an integer of 0 to 6 when m1 is 1, and an integer of 0 to 8 when m1 is 2. n1 is preferably 0, 1, 2, 3, or 4, more preferably 0, 1, 2, or 3, further preferably 0, 1, or 2, and most preferably 0 or 1.

In the general formula (4), R⁴¹ is a halogen atom or a hydrocarbyl group having 1 to 10 carbon atoms and optionally having a heteroatom. Specific examples of the halogen atom include a fluorine atom, a chlorine atom, a bromine atom, and an iodine atom. The hydrocarbyl group having 1 to 10 carbon atoms may be saturated or unsaturated, and may be linear, branched, or cyclic. Specific examples thereof include: alkyl groups having 1 to 10 carbon atoms, such as a methyl group, a ethyl group, a n-propyl group, a isopropyl group, a n-butyl group, a isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 10 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, and an adamantyl group; alkenyl groups having 2 to 10 carbon atoms, such as a vinyl group and an allyl group; aryl groups having 6 to 10 carbon atoms, such as a phenyl group and a naphthyl group; and groups obtained by combining these groups. Furthermore, part or all of the hydrogen atoms of the hydrocarbyl group may be substituted with a group having a heteroatom, such as an oxygen atom, a sulfur atom, a nitrogen atom, or a halogen atom, or part of the —CH₂— groups of the hydrocarbyl group may be substituted with a group having a heteroatom, such as an oxygen atom, a sulfur atom, or a nitrogen atom, and as a result, the hydrocarbyl group may contain a hydroxy group, a cyano group, a halogen atom, a carbonyl group, an ether bond, a thioether bond, an ester bond, a sulfonate ester bond, a carbonate bond, a carbamate bond, a lactone ring, a sultone ring, a carboxylic acid anhydride (—C(═O)—O—C(═O)—), and the like. R⁴¹ is preferably a hydrocarbyl group having 1 to 4 carbon atoms or a fluorinated hydrocarbyl group having 1 to 4 carbon atoms, more preferably a hydrocarbyl group having 1 to 4 carbon atoms.

In the general formula (4), R⁴² represents a halogen atom or a hydrocarbyl group having 1 to 40 carbon atoms and optionally having a heteroatom. Specific examples of the halogen atom include a fluorine atom, a chlorine atom, a bromine atom, and an iodine atom. The hydrocarbyl group having 1 to 40 carbon atoms may be saturated or unsaturated, and may be linear, branched, or cyclic. Specific examples thereof include: alkyl groups having 1 to 40 carbon atoms, such as a methyl group, an ethyl group, an n-propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl, cyclohexylbutyl group, a norbornyl group, a tricyclo[5.2.1.0^{2,6}]decanyl group, an adamantyl group, and an adamantylmethyl group; and aryl groups having 6 to 40 carbon atoms, such as a phenyl group, a naphthyl group, and an anthracenyl group. Furthermore, part or all of the hydrogen atoms of the hydrocarbyl group may be substituted with a group having a heteroatom, such as an oxygen atom, a sulfur atom, a nitrogen atom, or a halogen atom, or part of the —CH₂— groups of the hydrocarbyl group may be substituted with a group having a heteroatom, such as an oxygen atom, a sulfur atom, or a nitrogen atom, and as a result, the hydrocarbyl group may contain a hydroxy group, a cyano group, a halogen atom, a carbonyl group, an ether bond, a thioether bond, an ester bond, a sulfonate ester bond, a carbonate bond, a carbamate bond, a lactone ring, a sultone ring, a carboxylic acid anhydride (—C(═O)—O—C(═O)—), etc. When n1 is 2 to 8, each R⁴²s may be identical to or different from each other, or a plurality R⁴²s may be bonded to each other to form a ring together with the carbon atoms of the aromatic ring bonded thereto.

In the general formula (4), R⁴³ is a carbonyl group or a hydrocarbylene group having 1 to 10 carbon atoms and optionally having a heteroatom. The hydrocarbylene group having 1 to 10 carbon atoms may be saturated or unsaturated, and may be linear, branched, or cyclic. Specific examples thereof include: alkylene groups having 1 to 10 carbon atoms, such as a methanediyl group, an ethane-1,1-diyl group, an ethane-1,2-diyl group, a propane-1,1-diyl group, a propane-1,2-diyl group, a propane-1,3-diyl group, a propane-2,2-diyl group, a butane-2,3-diyl group, a butane-1,4-diyl group, a 2-methylpropane-1,2-diyl group, a pentane-1,5-diyl group, a hexane-1,6-diyl group, a heptane-1,7-diyl group, an octane-1,8-diyl group, a nonane-1,9-diyl group, and a decane-1,10-diyl group; cyclic saturated hydrocarbylene groups having 3 to 10 carbon atoms, such as a cyclopentanediyl group, a cyclohexanediyl group, a norbornanediyl group, an adamantanediyl group, and a tricyclo[5.2.1.0^{2,6}]decanediyl group; alkenylene groups having 2 to 10 carbon atoms, such as a vinylene group and a propynylene group; arylene groups having 6 to 10 carbon atoms, such as a phenylene group, a methylphenylene group, an ethylphenylene group, an n-propylphenylene group, an isopropylphenylene group, an n-butylphenylene group, and a naphthylene group; and groups obtained by combining these. In addition, part or all of the hydrogen atoms of the hydrocarbylene group may be substituted with a group having a heteroatom, such as an oxygen atom, a sulfur atom, a nitrogen atom, or a halogen atom, and part of the —CH₂— groups of the hydrocarbylene group may be substituted with a group having a heteroatom, such as an oxygen atom, a sulfur atom, or a nitrogen atom, as a result, the hydrocarbylene group may have a hydroxy group, a cyano group, a halogenated alkyl group, a halogen atom, a carbonyl group, an ether bond, a thioether bond, an ester bond, a sulfonate ester bond, a carbonate bond, a carbamate bond, a lactone ring, a sultone ring, a carboxylic acid anhydride (—C(═O)—O—C(═O)—), etc. R⁴³ is preferably a carbonyl group, a hydrocarbylene group having 1 to 4 carbon atoms, or a fluorinated hydrocarbylene group having 1 to 4 carbon atoms.

In the general formula (4), *3 and *4 represent an attachment point to the carbon atoms of the aromatic ring in the formula, and *3 and *4 are bonded to adjacent carbon atoms of the aromatic ring. There are seven possible combinations of *3, *4, and m1, as shown below.

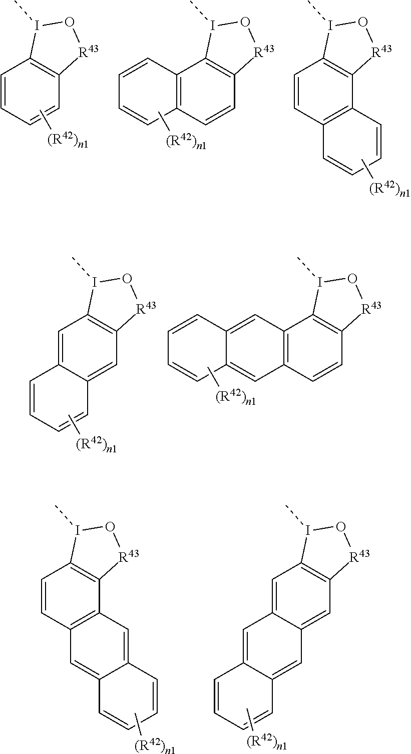

In the formulae, n1, R⁴², and R⁴³ are the same as defined above. The dotted line represents a bond to R⁴¹—C(═O)—O—.

Specific examples of the hypervalent iodine compound represented by the general formula (4) include, but are not limited to, the following. In the following formulae, Me represents a methyl group.

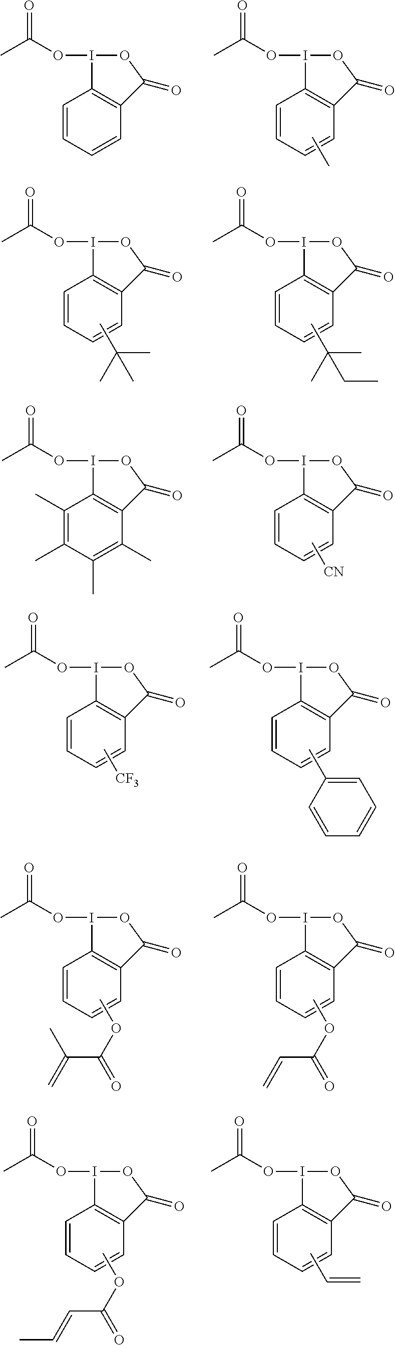

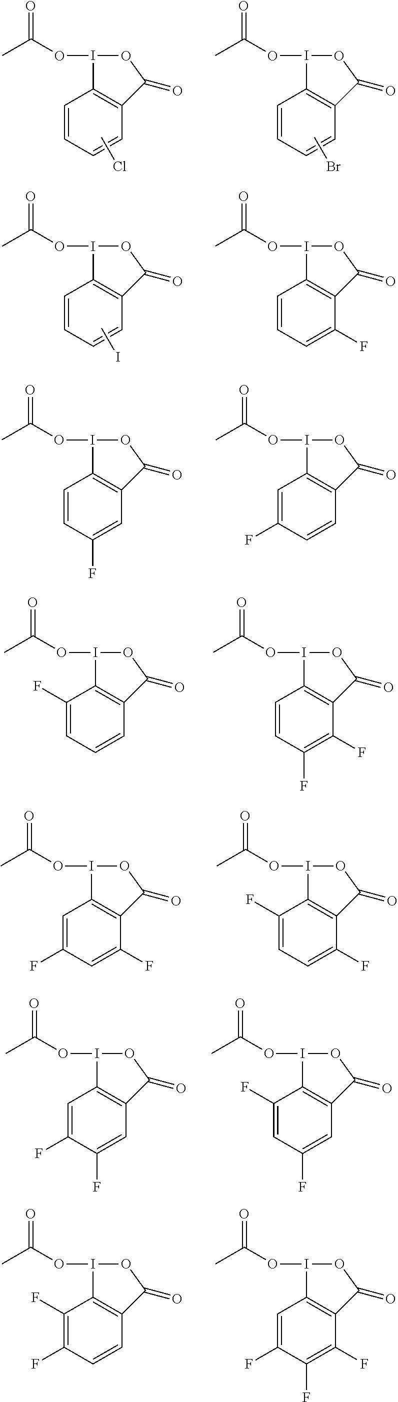

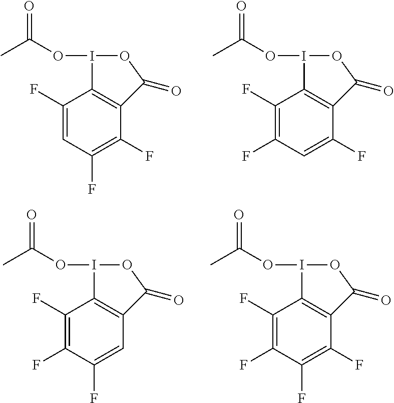

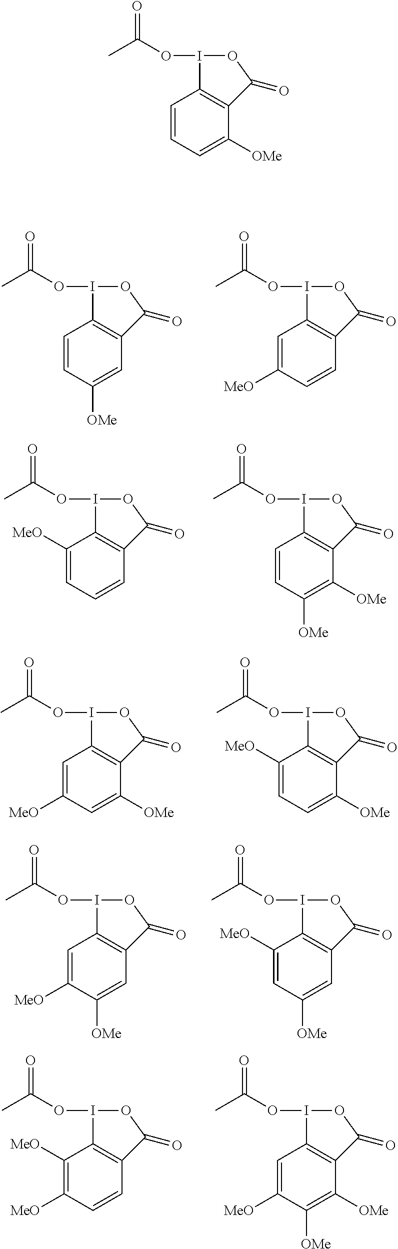

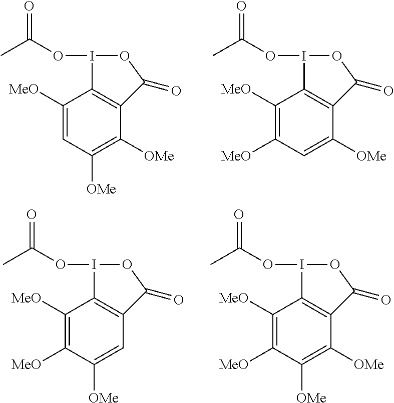

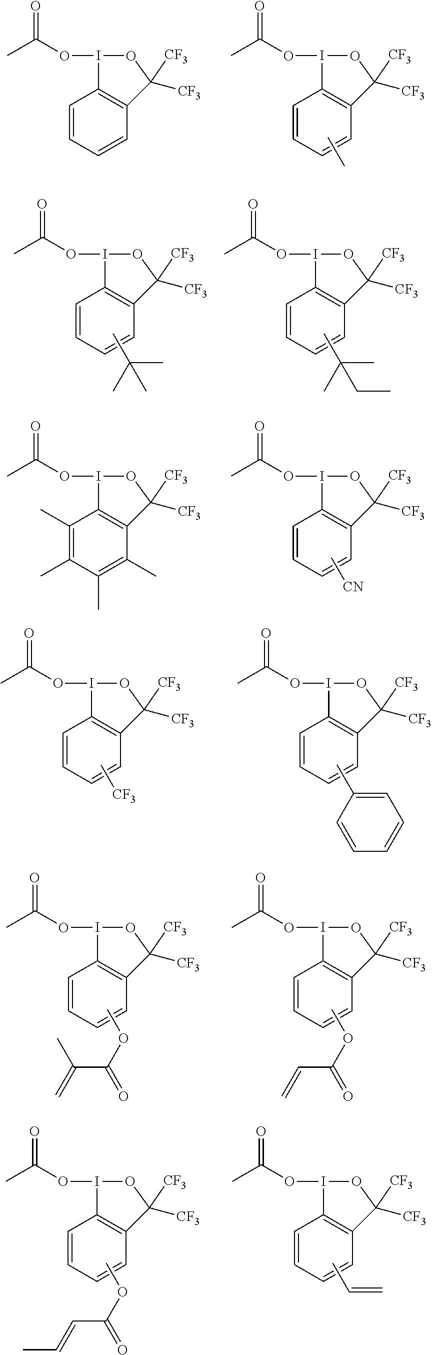

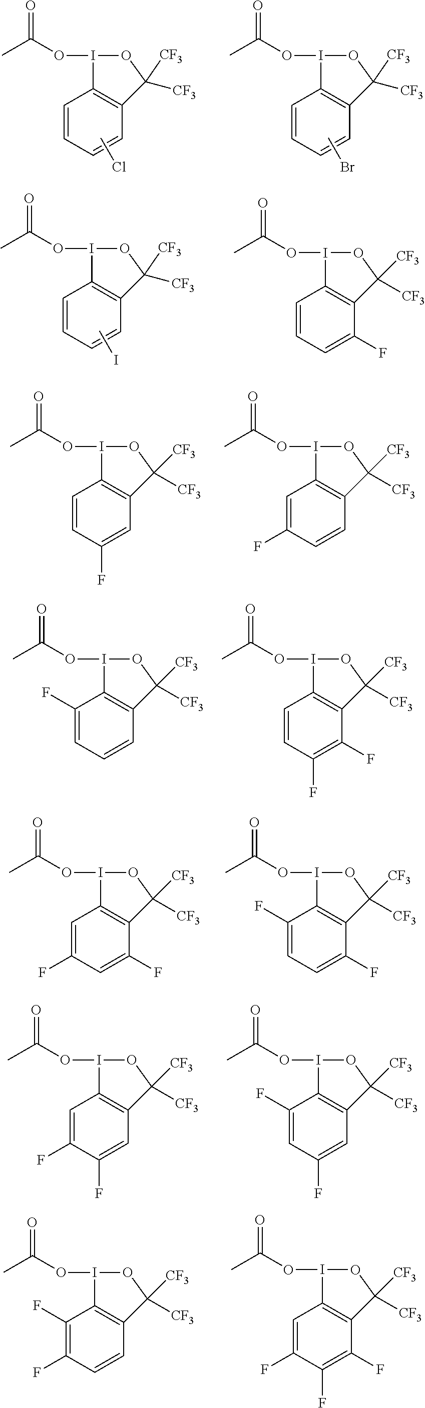

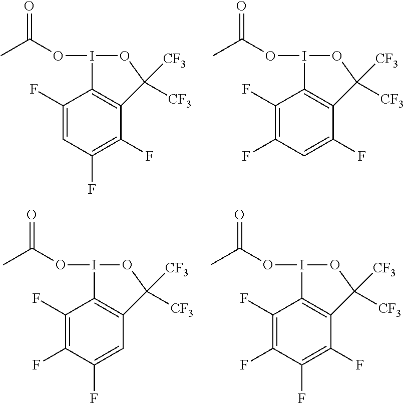

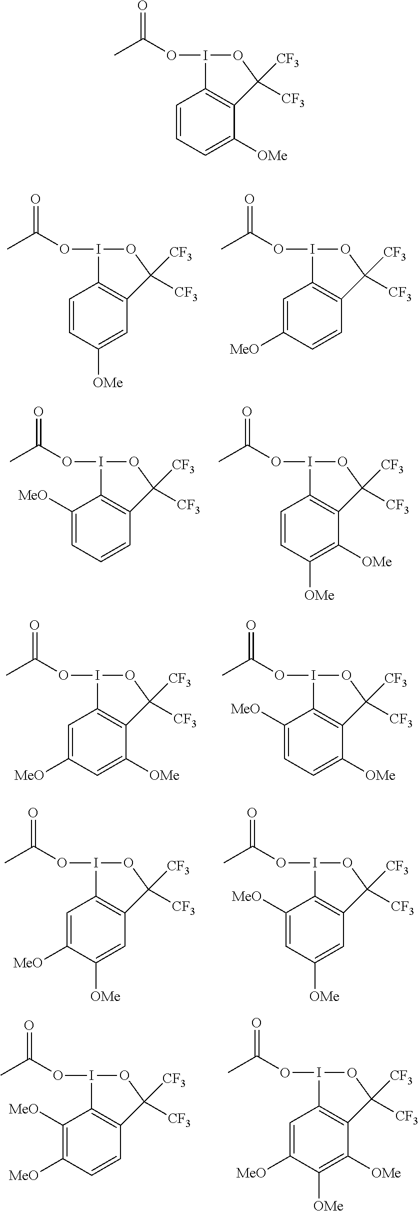

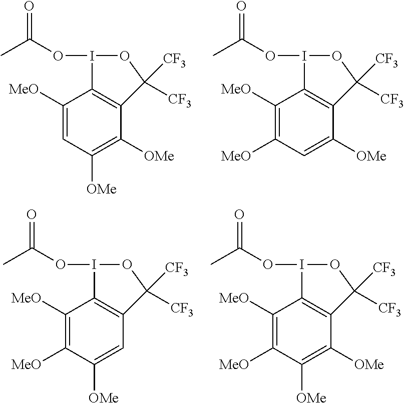

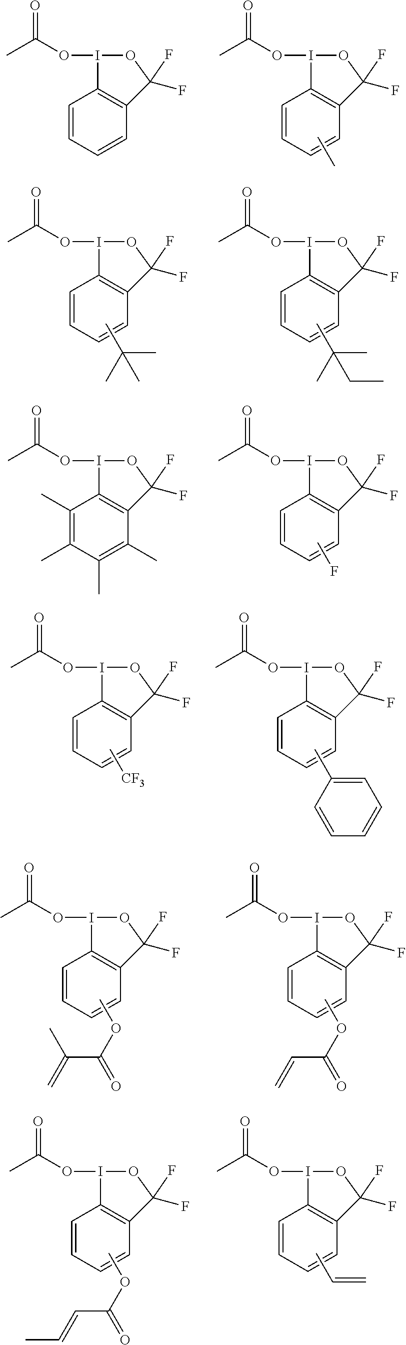

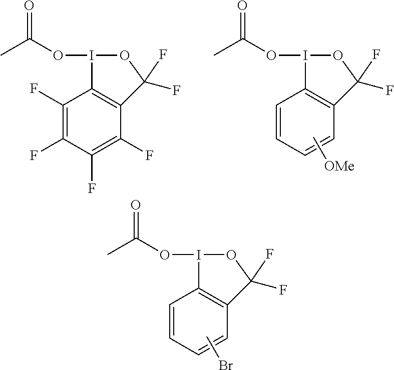

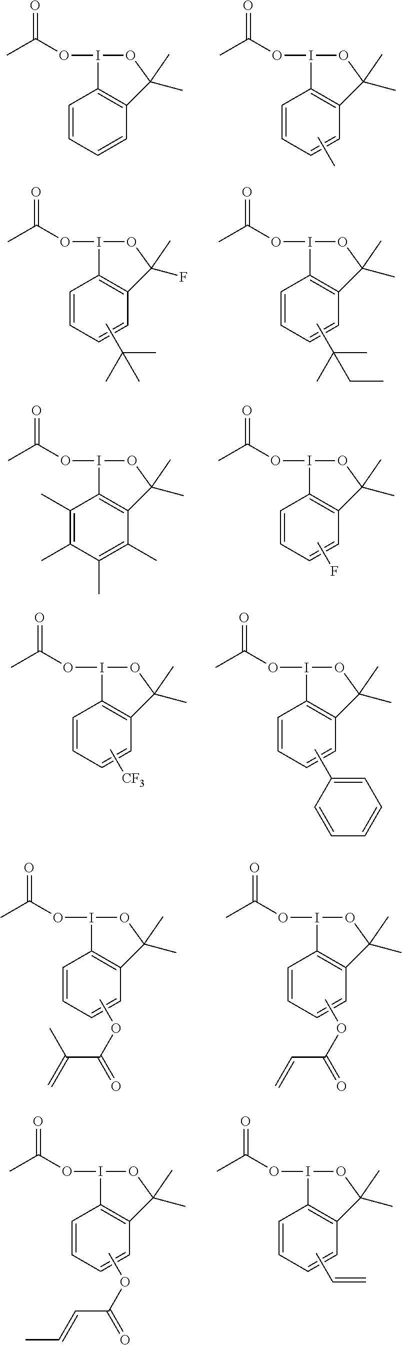

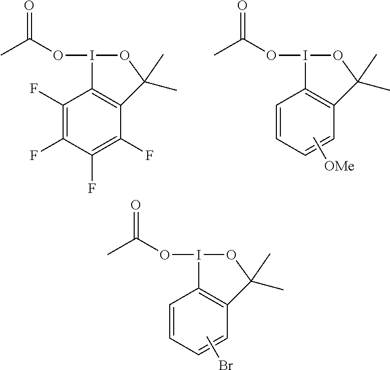

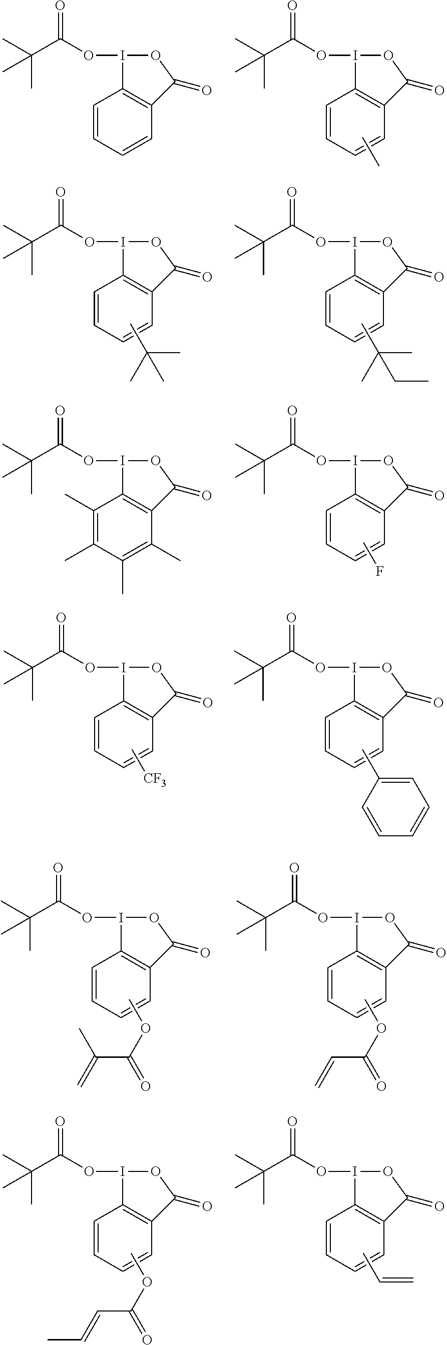

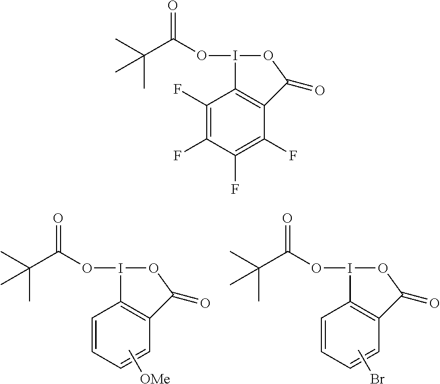

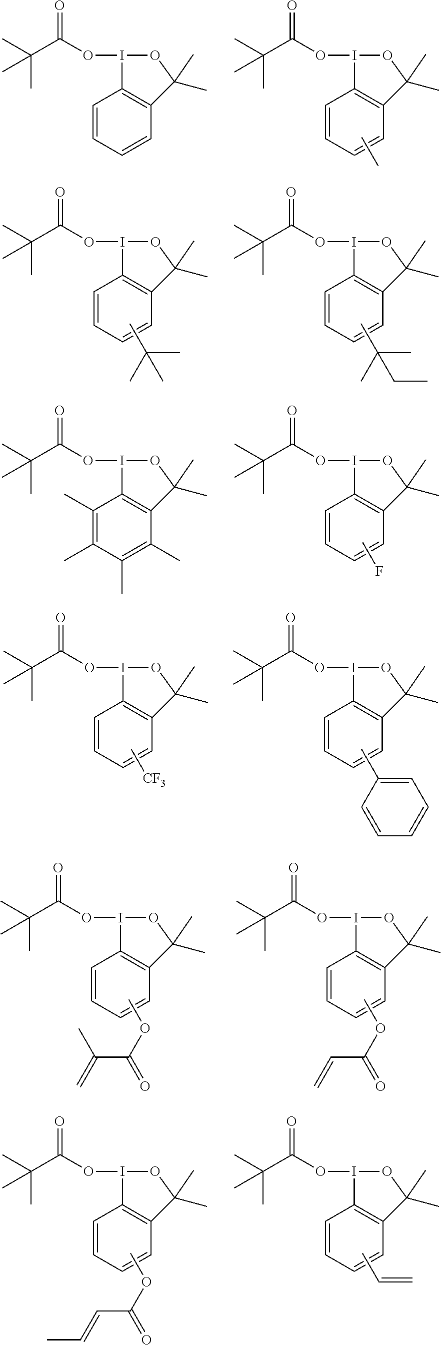

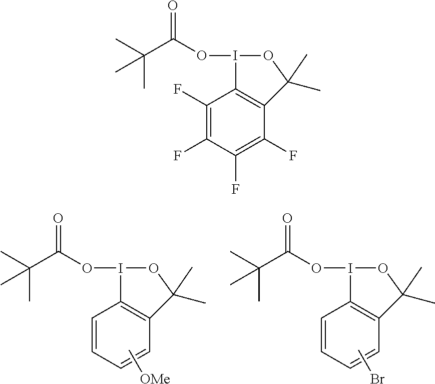

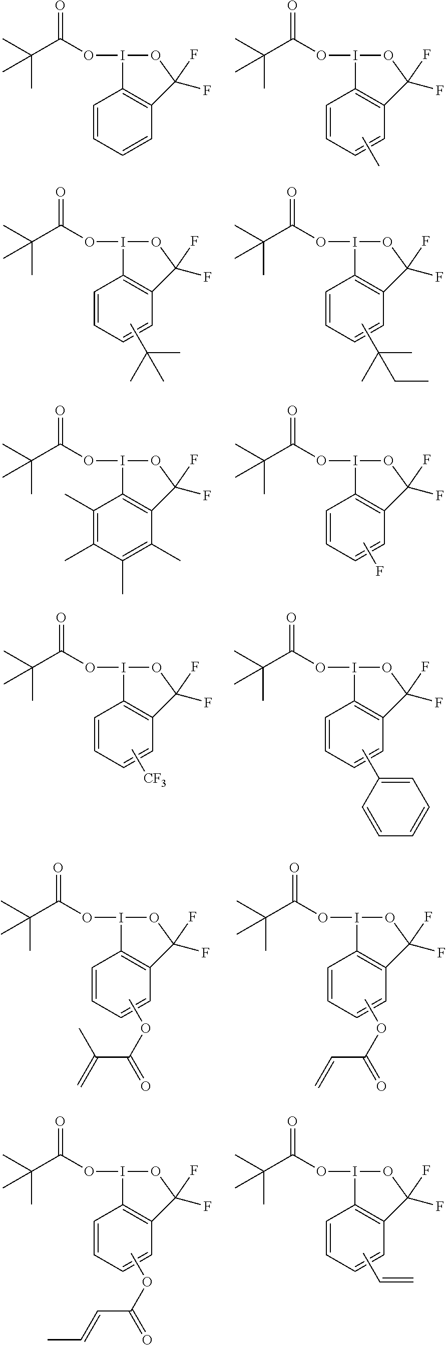

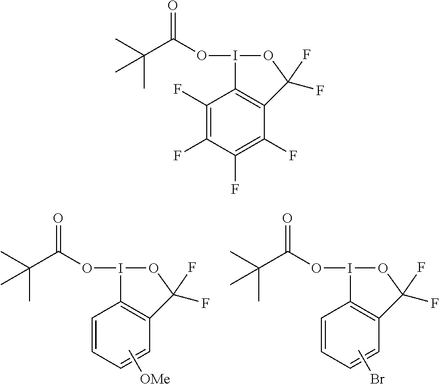

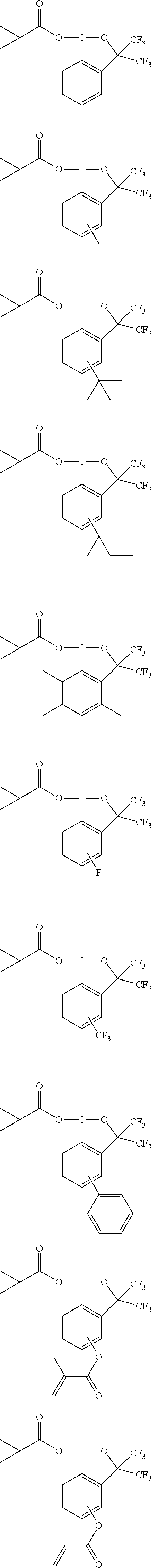

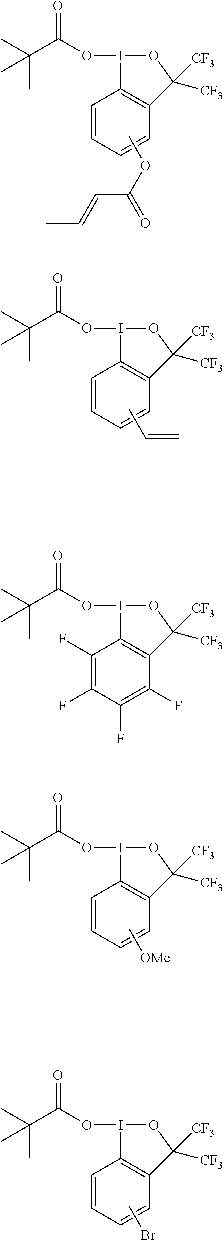

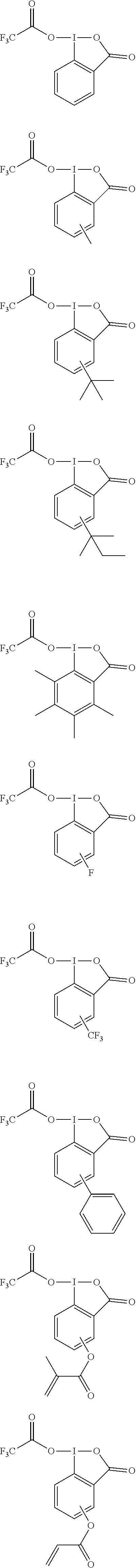

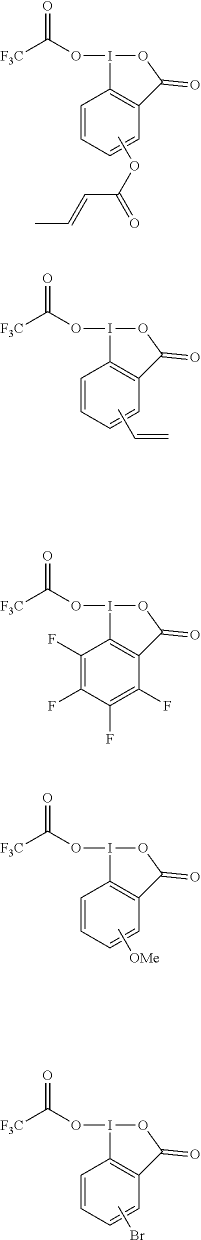

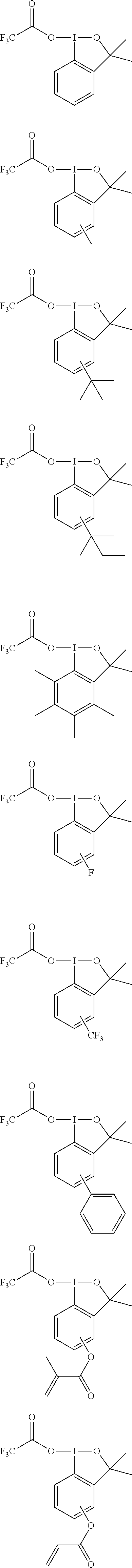

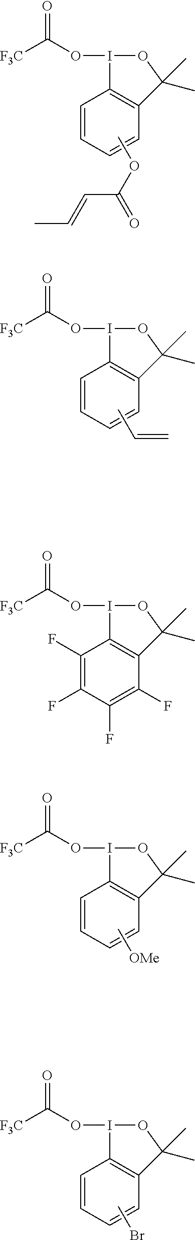

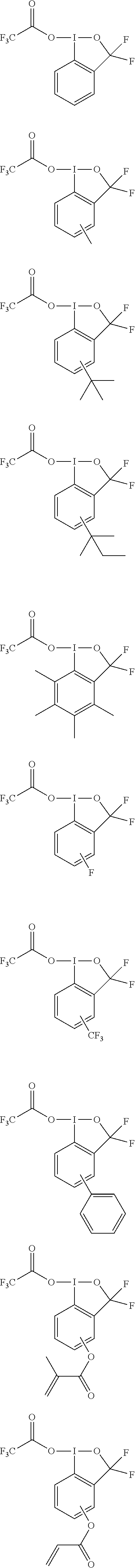

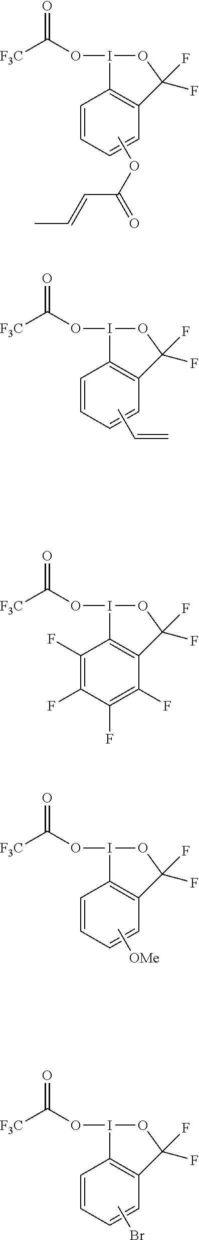

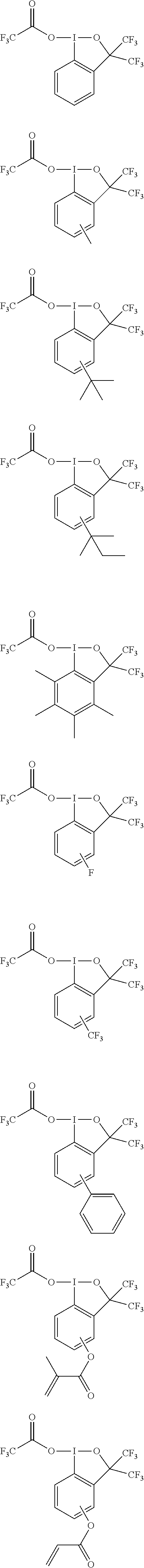

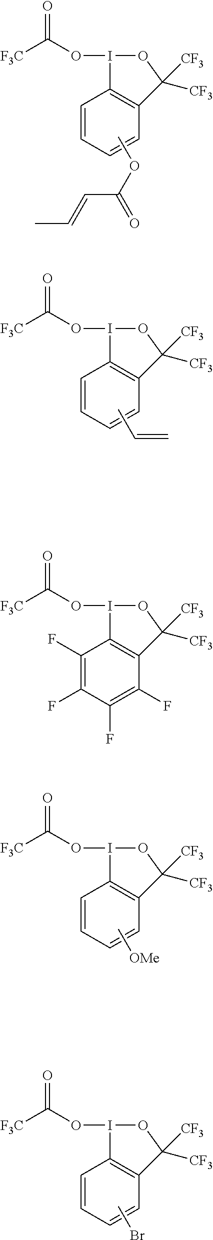

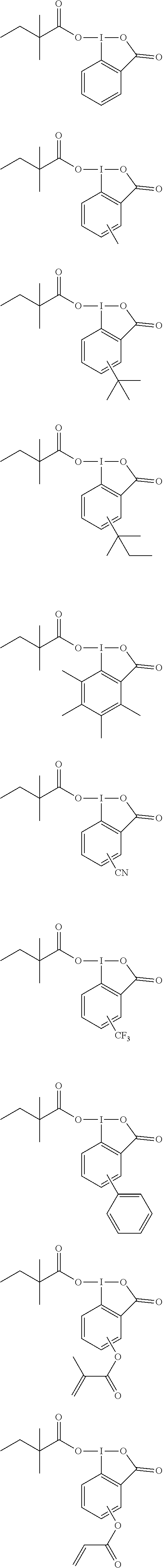

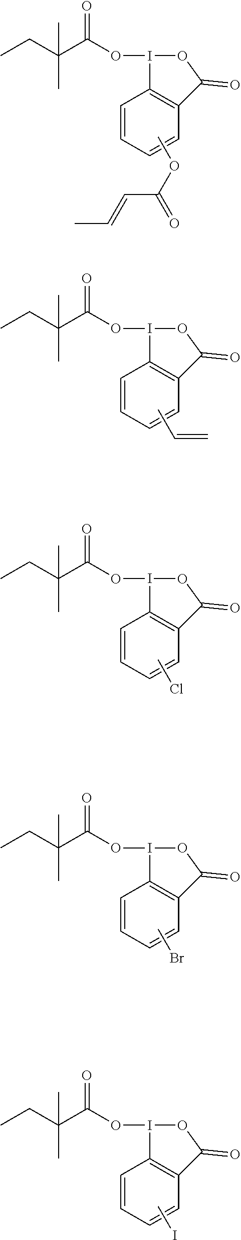

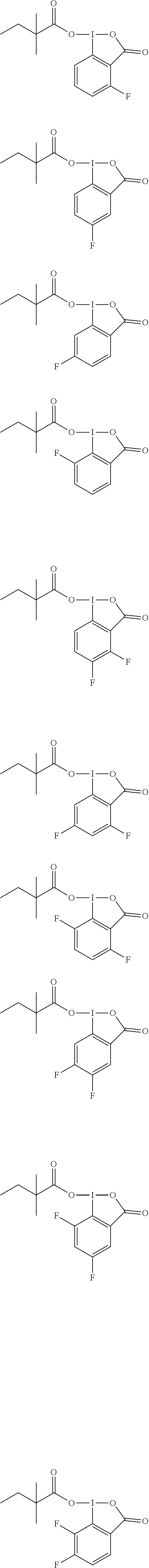

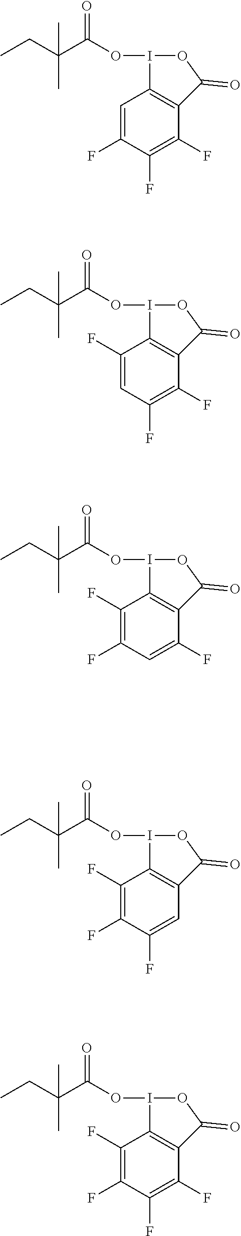

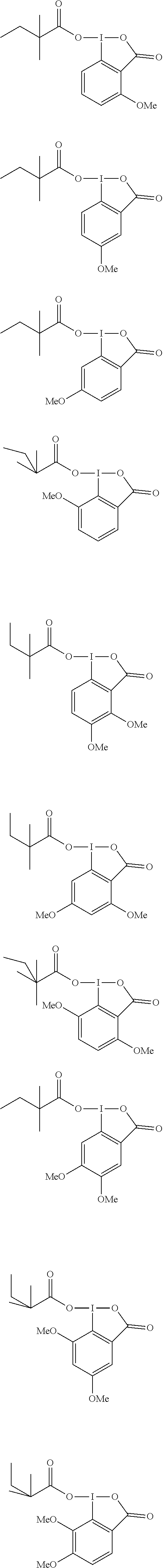

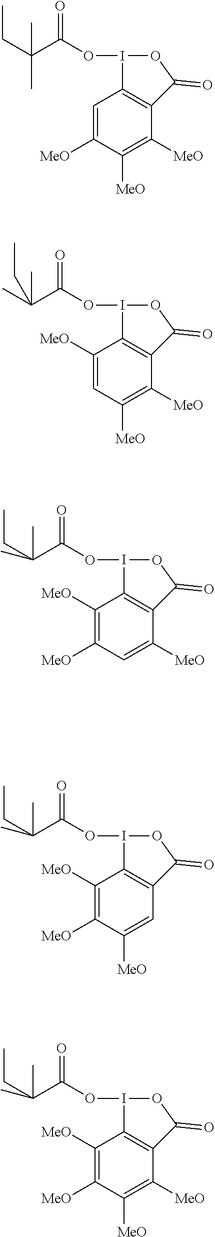

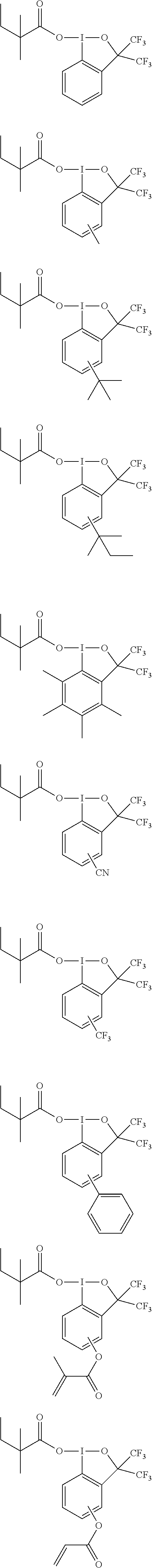

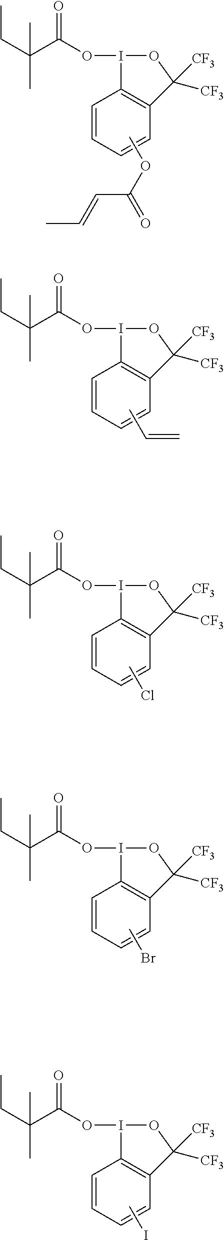

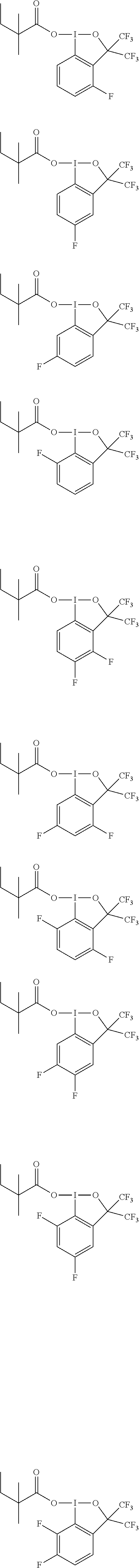

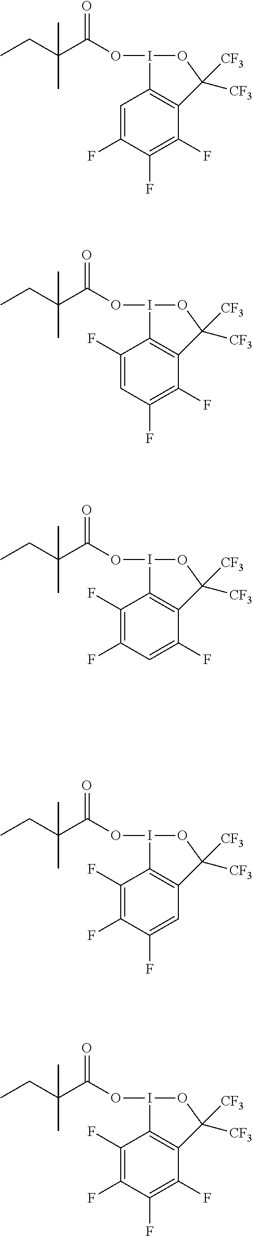

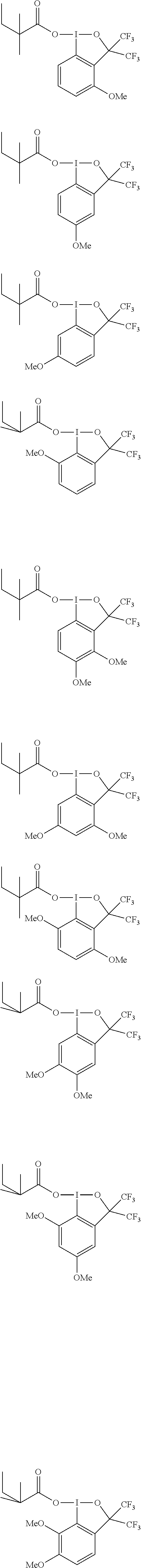

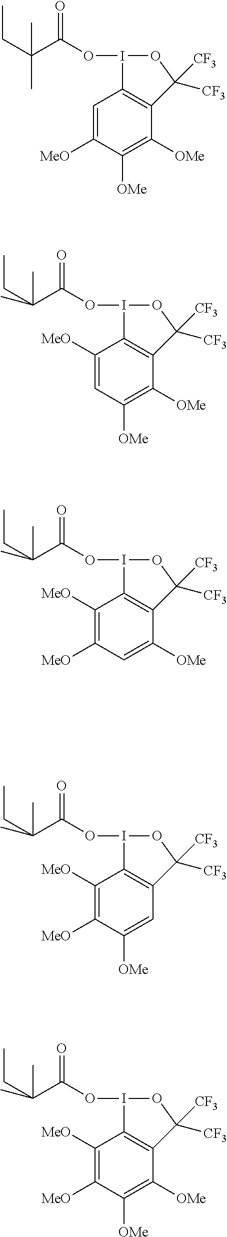

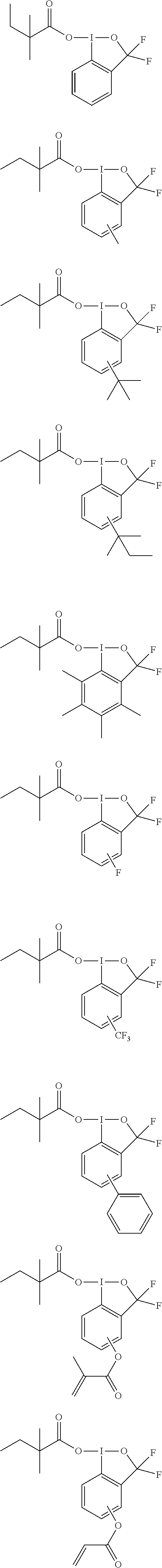

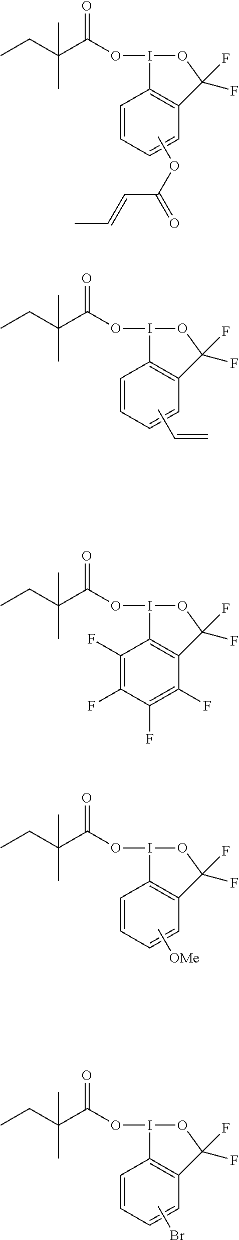

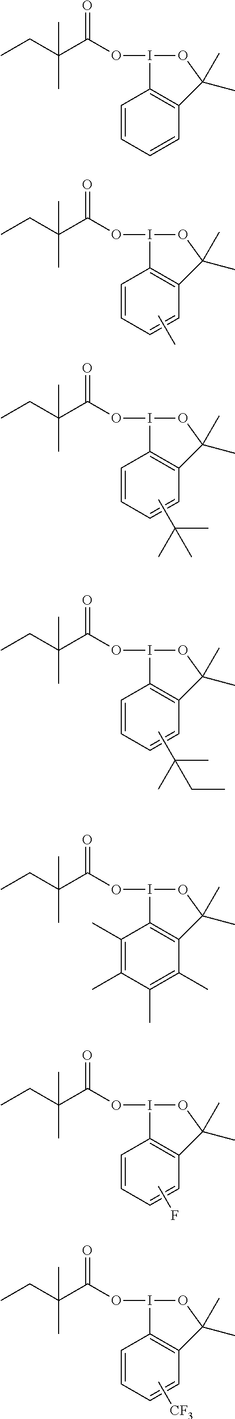

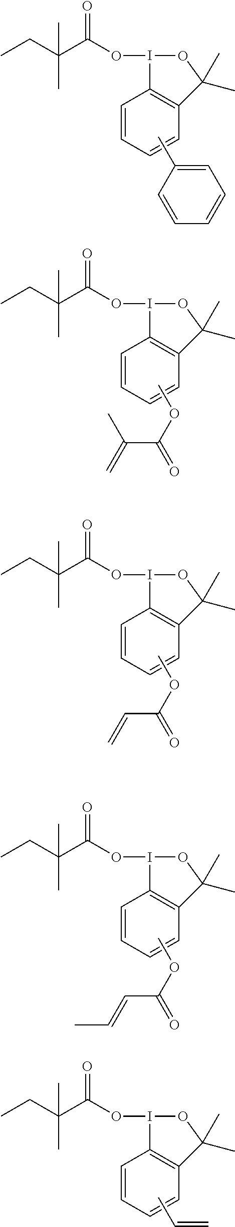

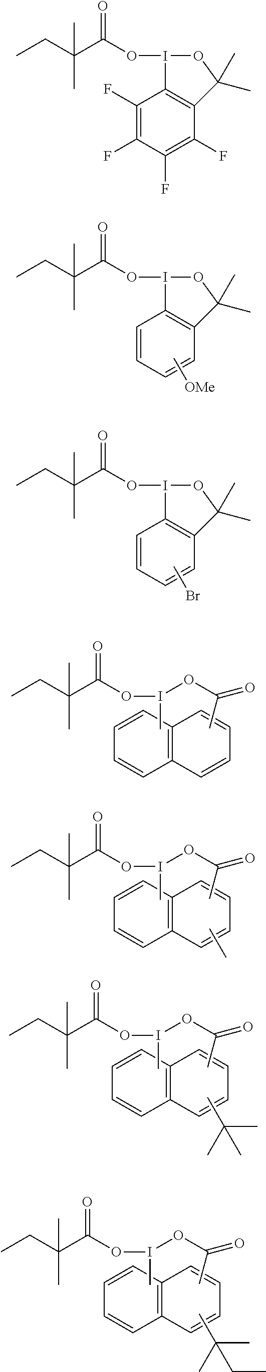

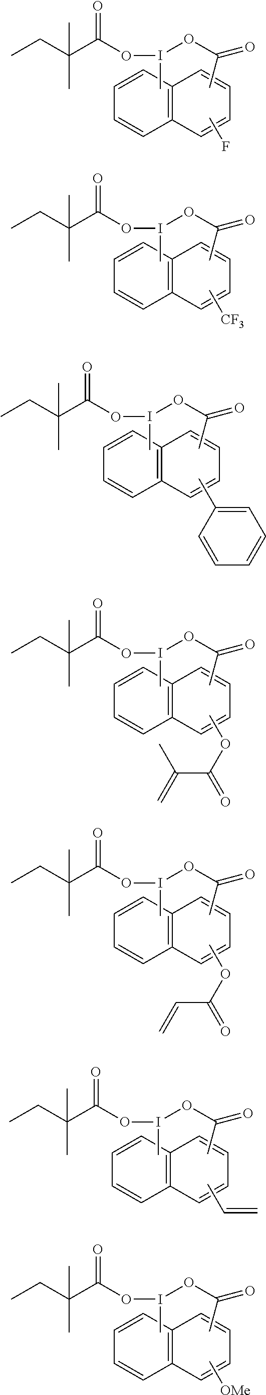

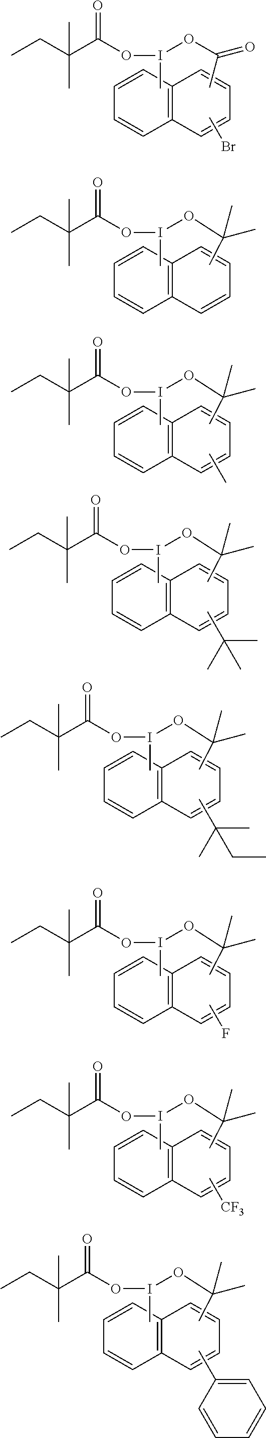

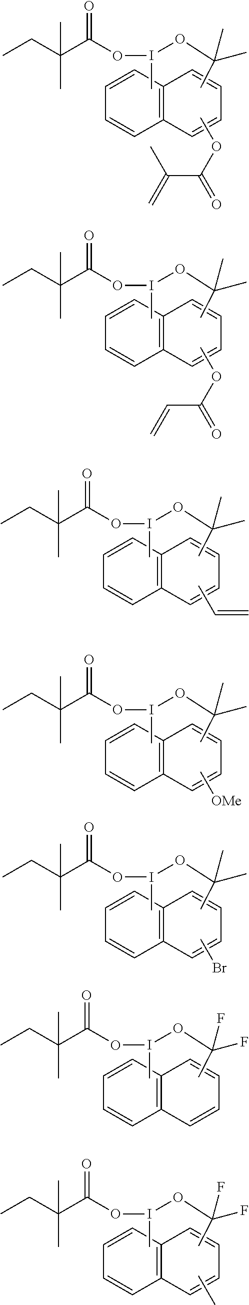

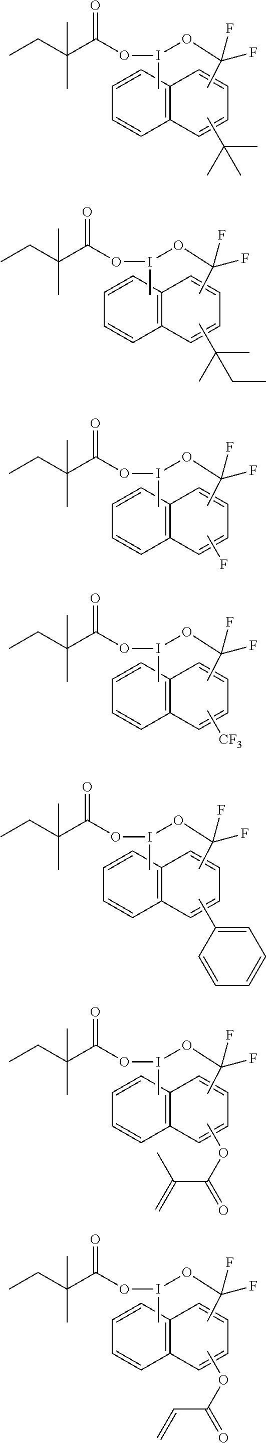

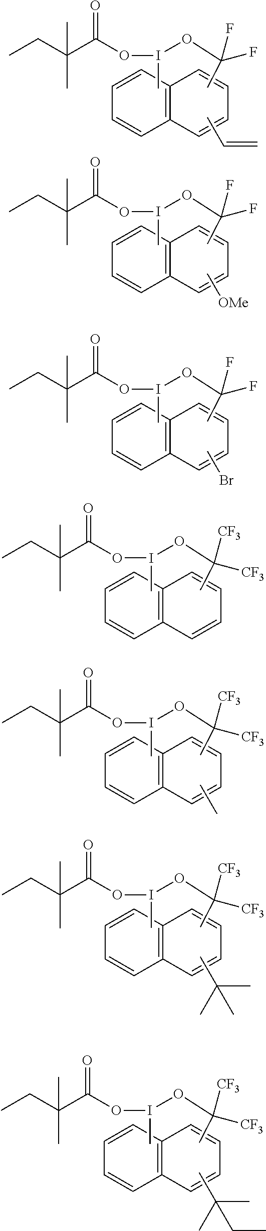

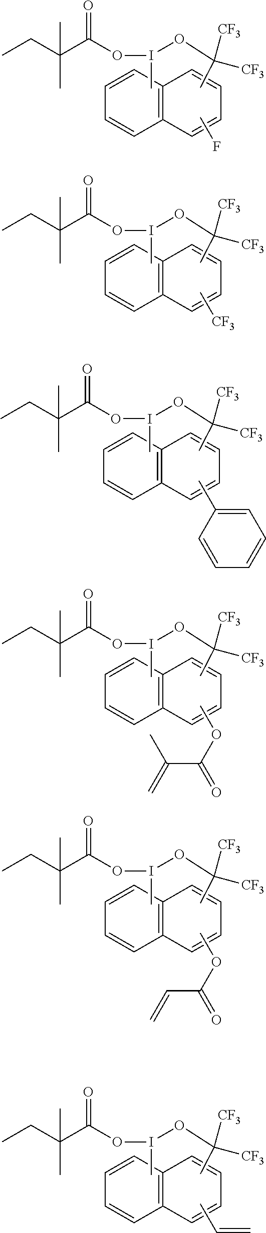

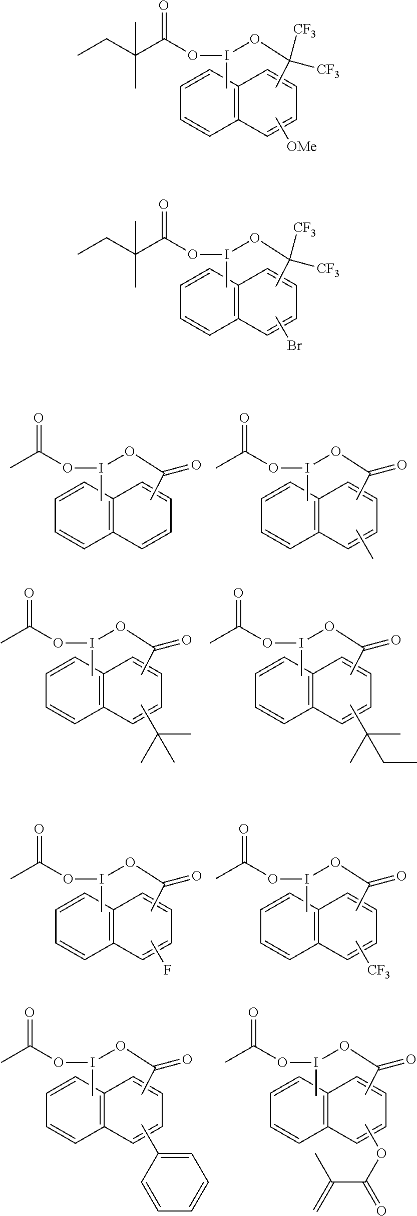

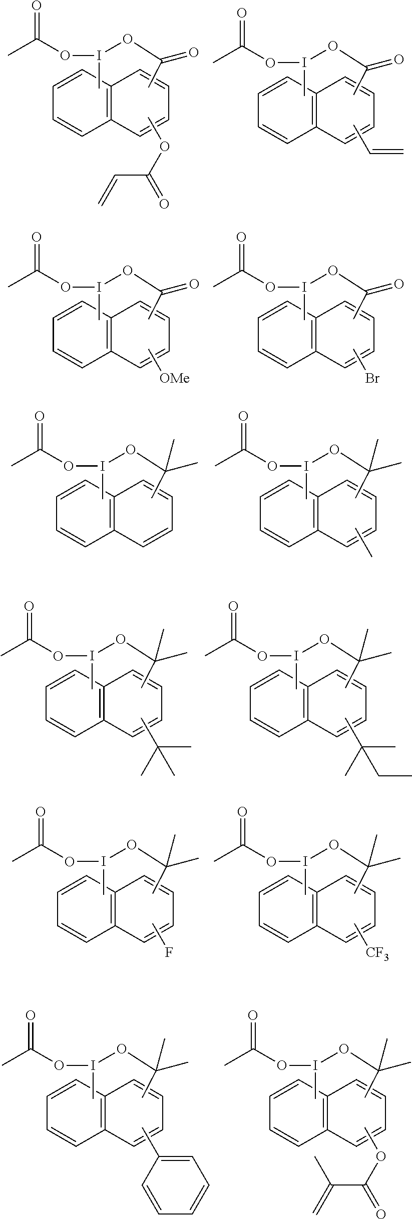

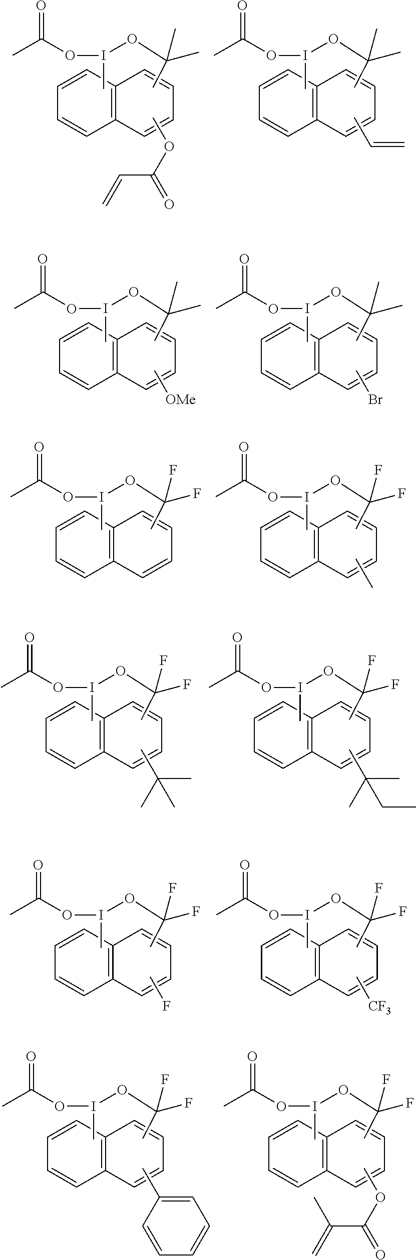

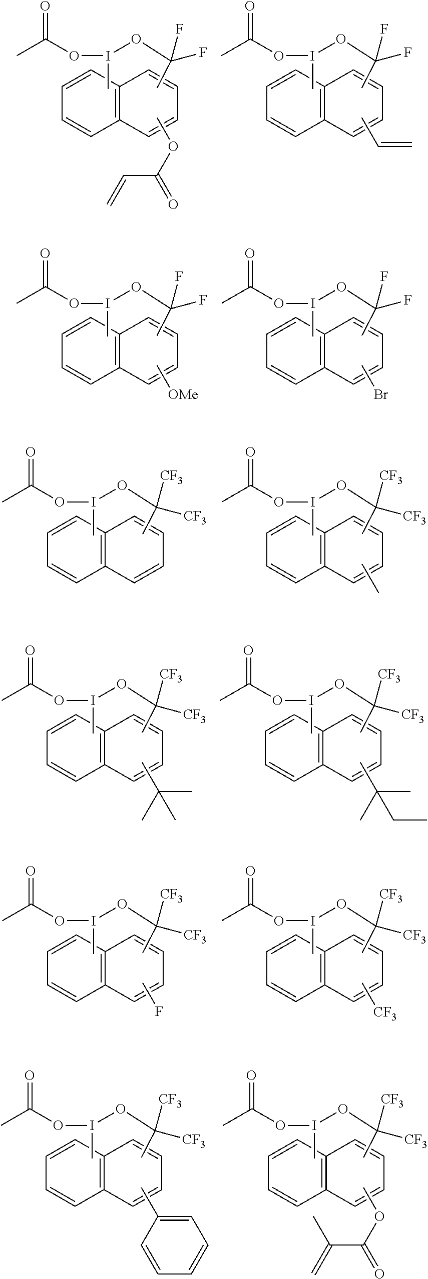

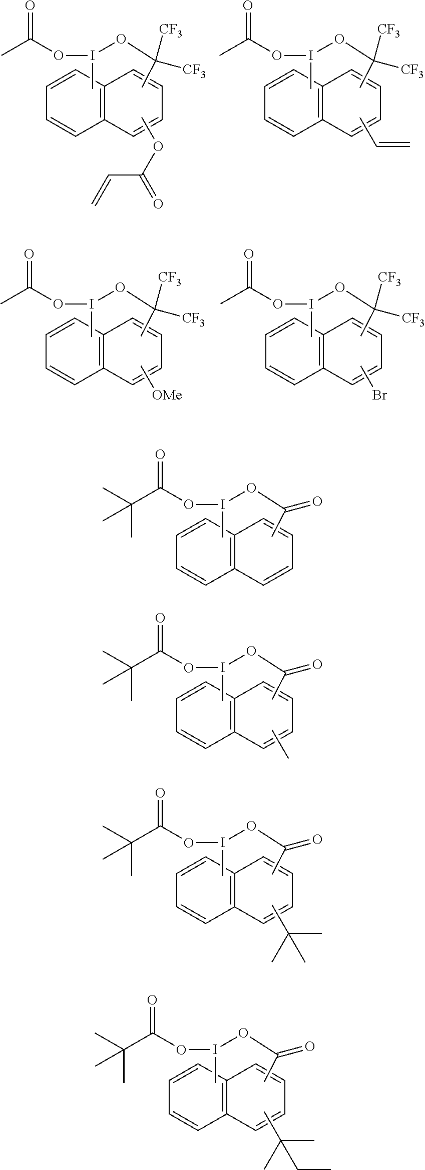

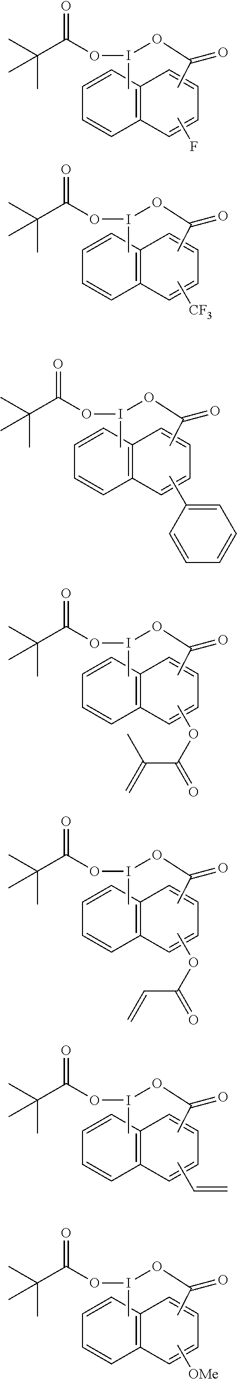

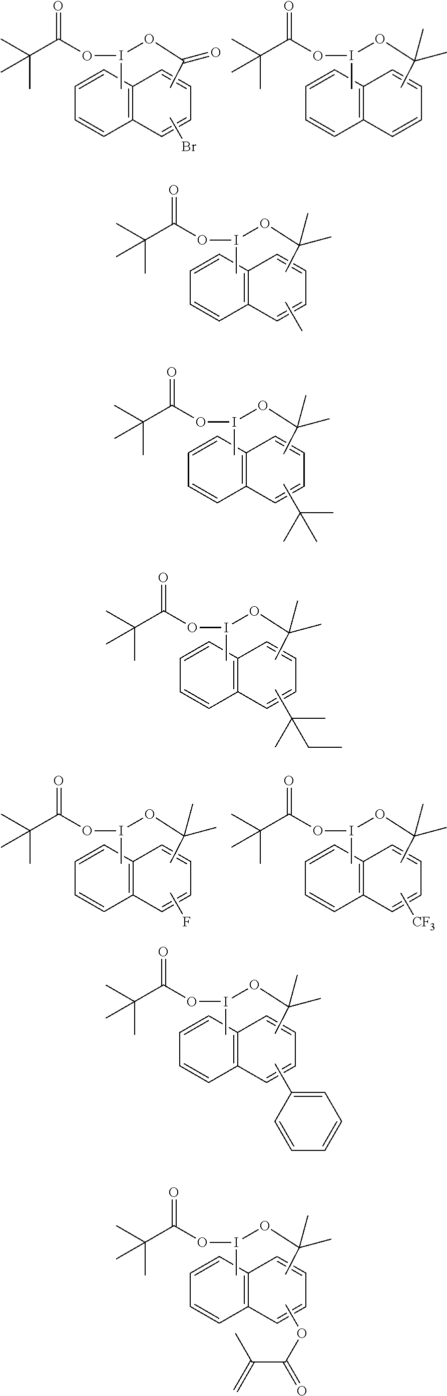

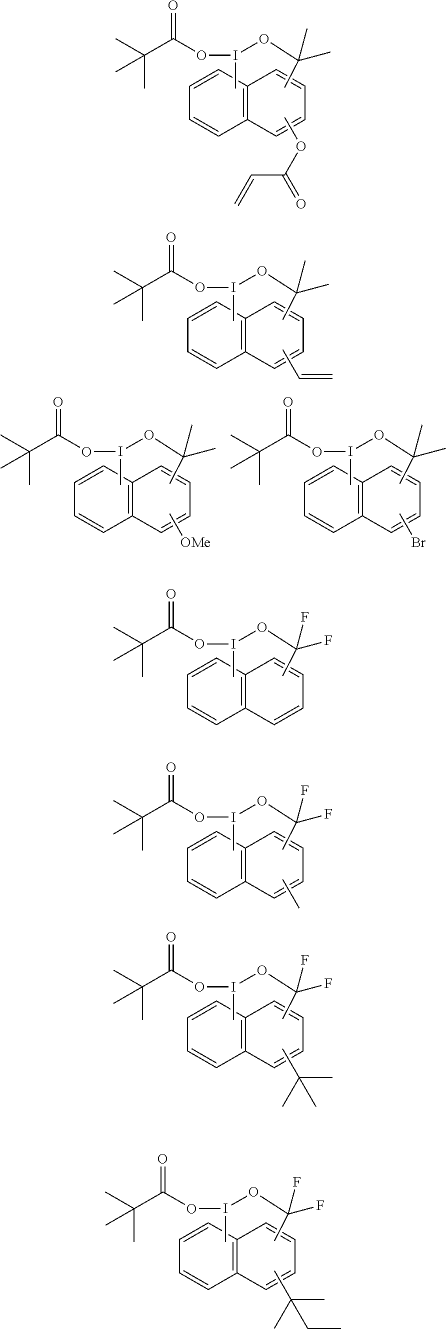

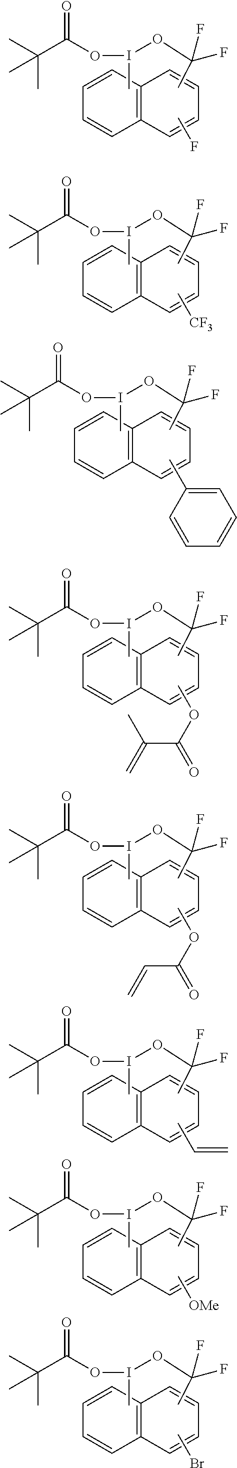

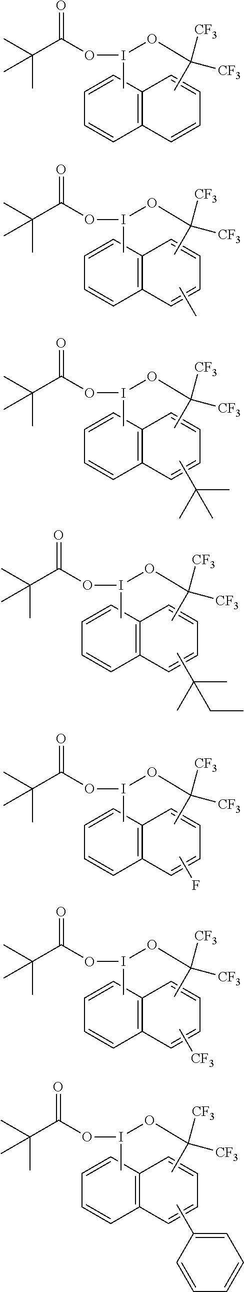

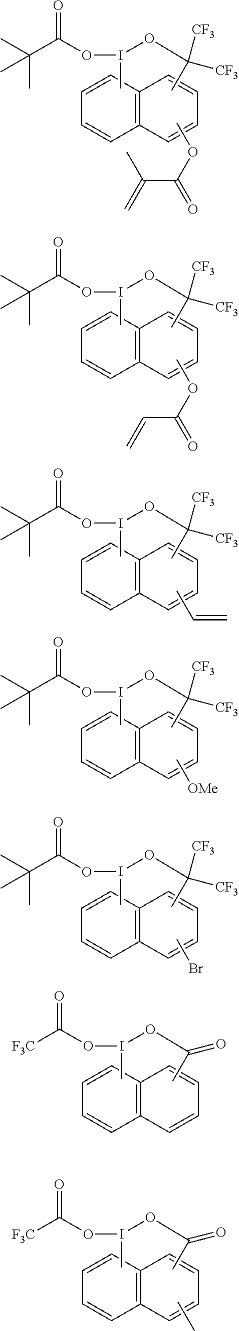

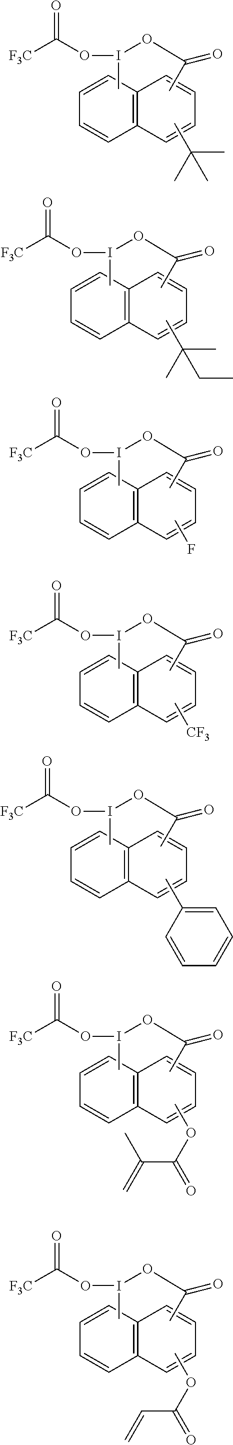

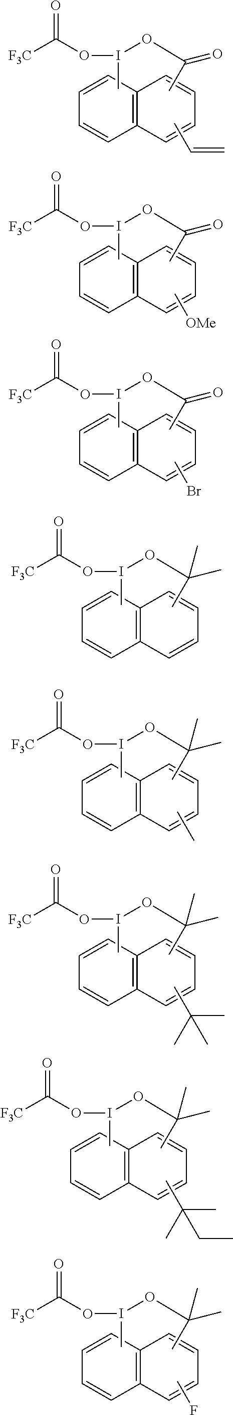

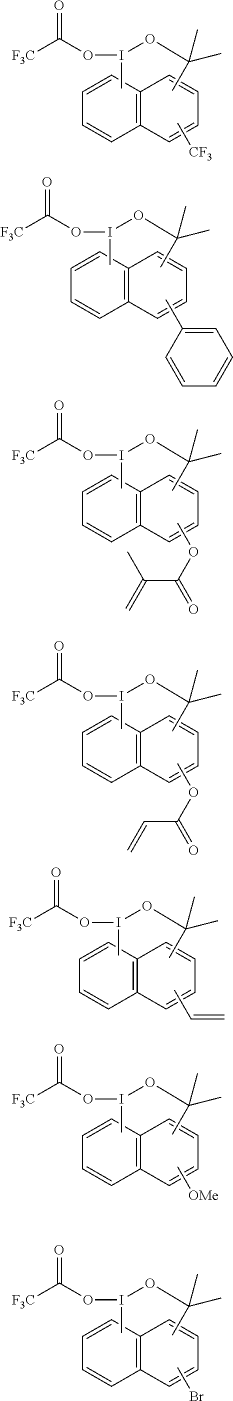

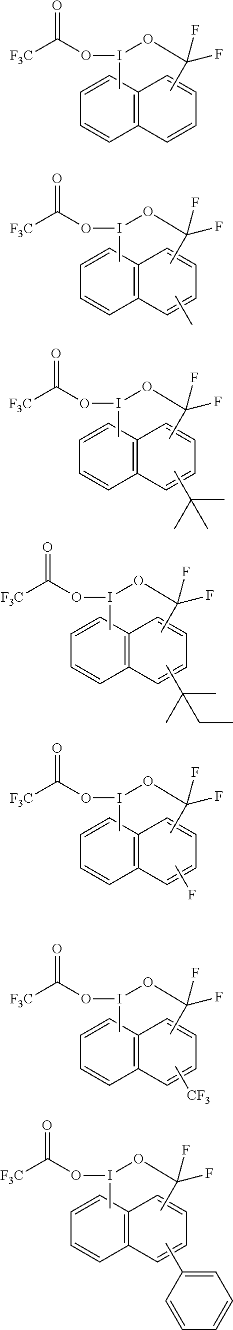

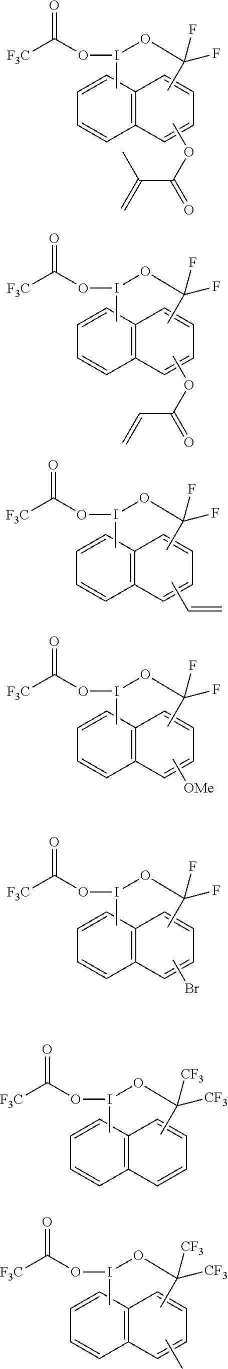

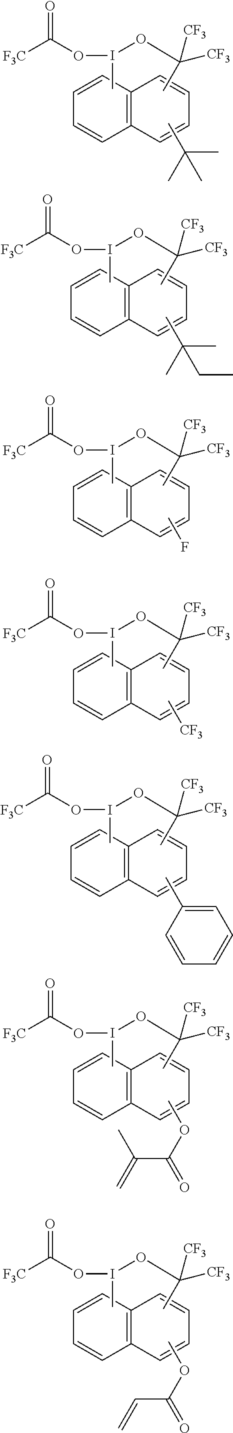

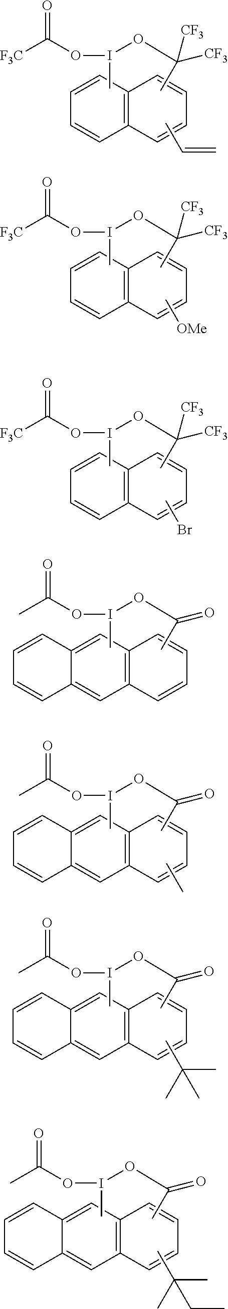

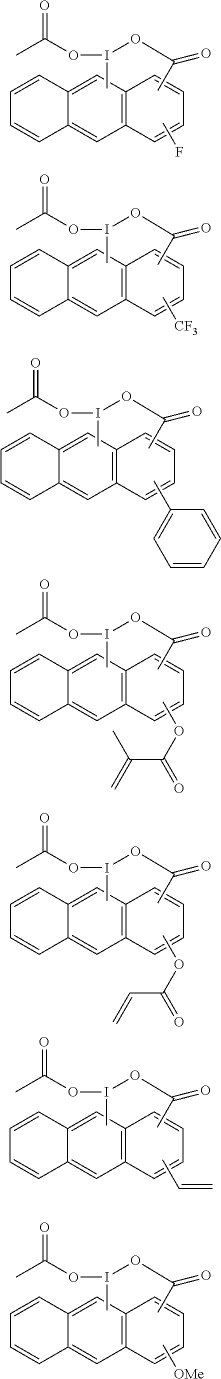

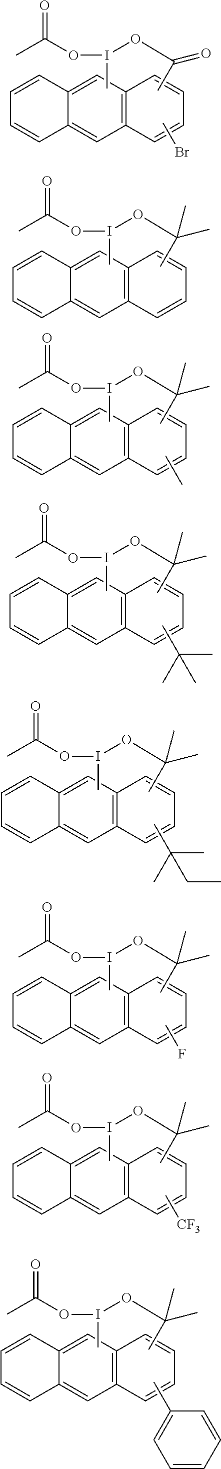

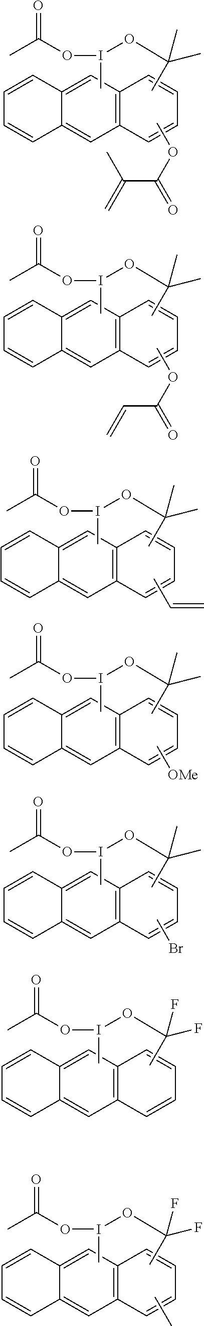

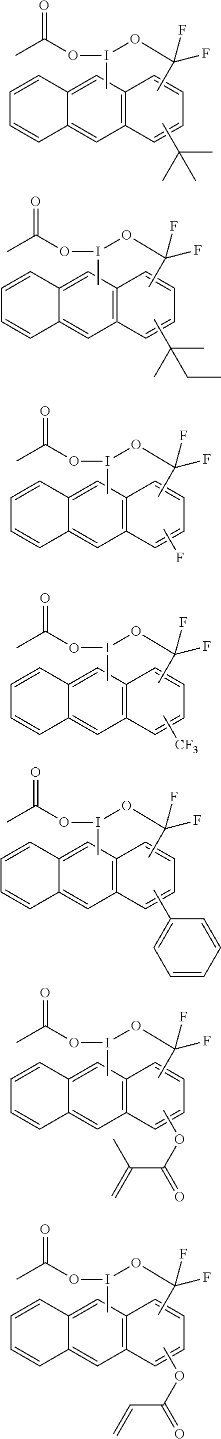

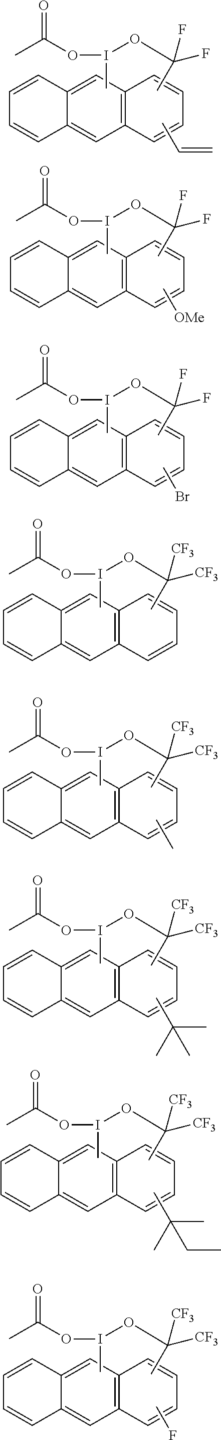

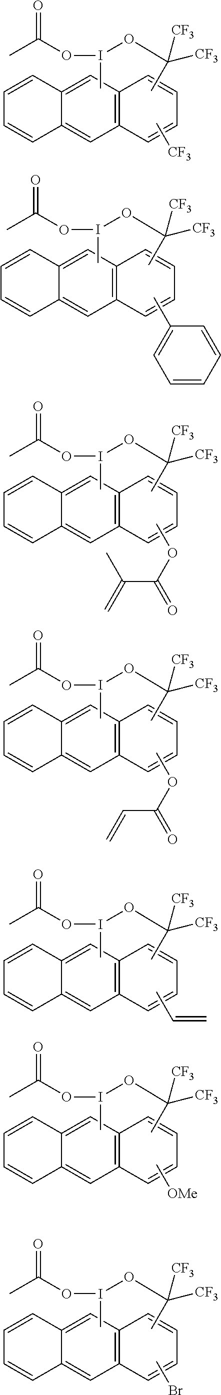

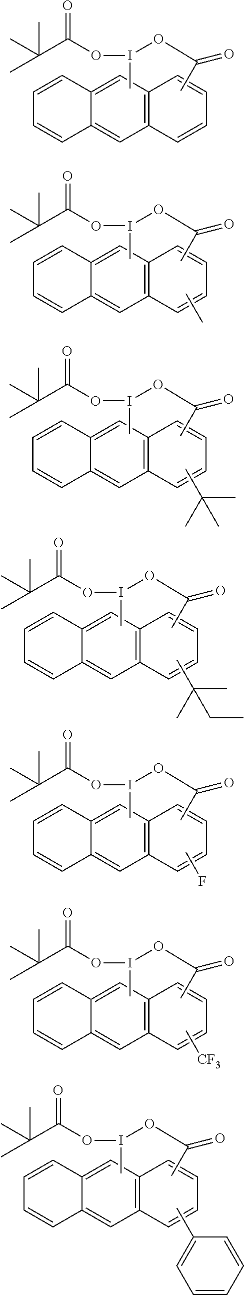

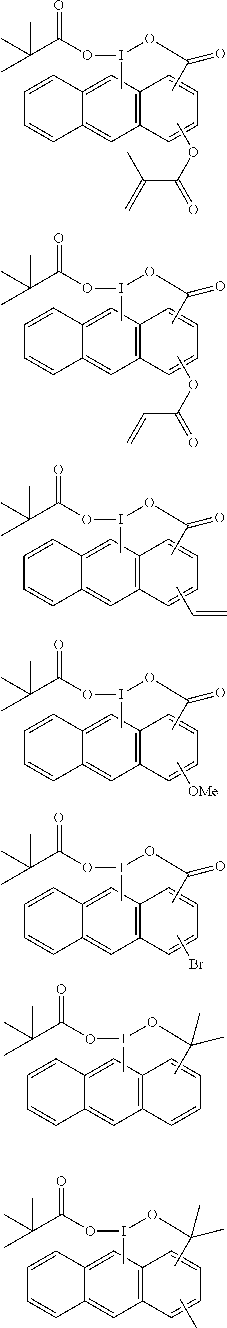

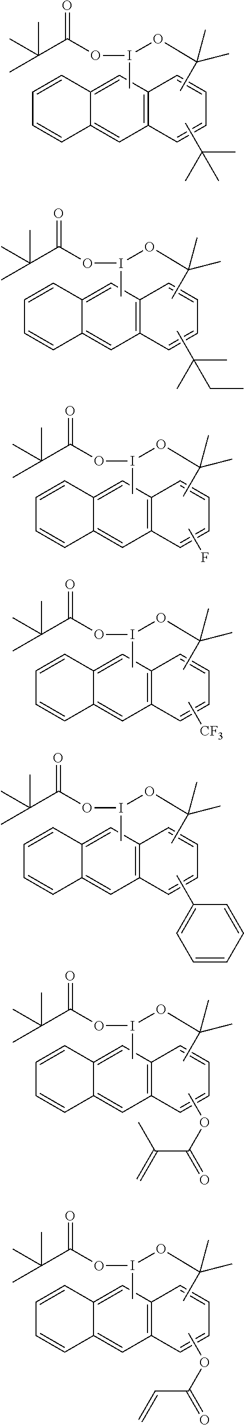

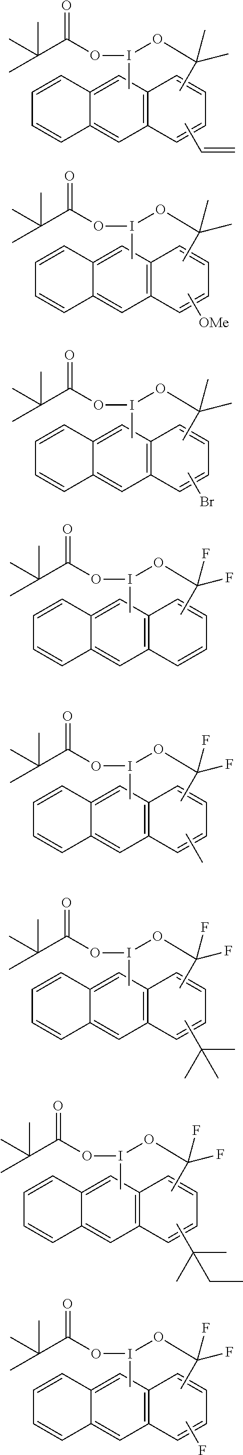

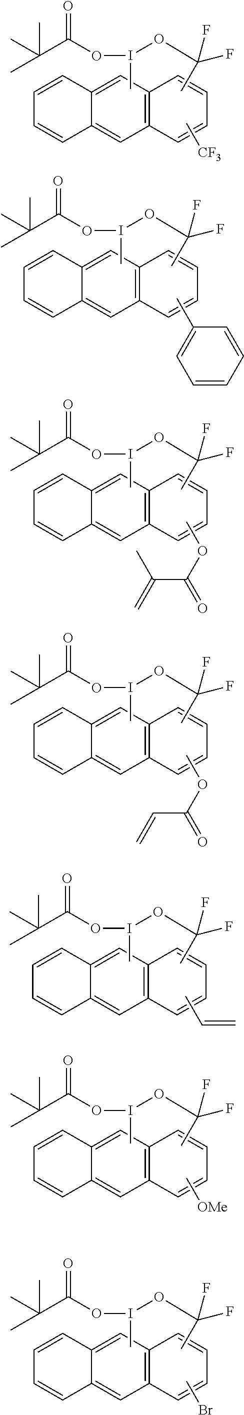

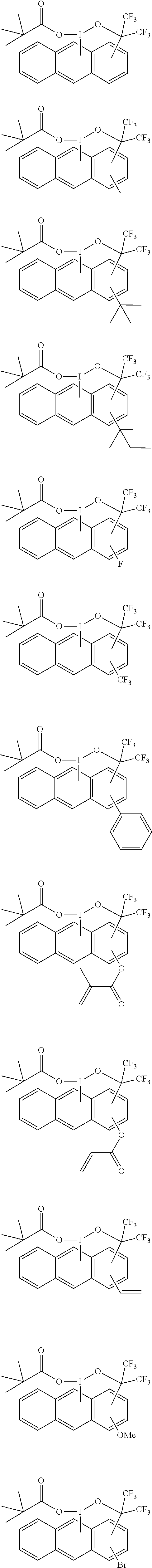

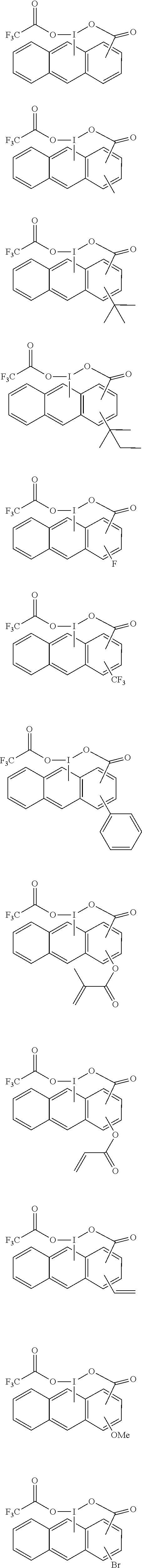

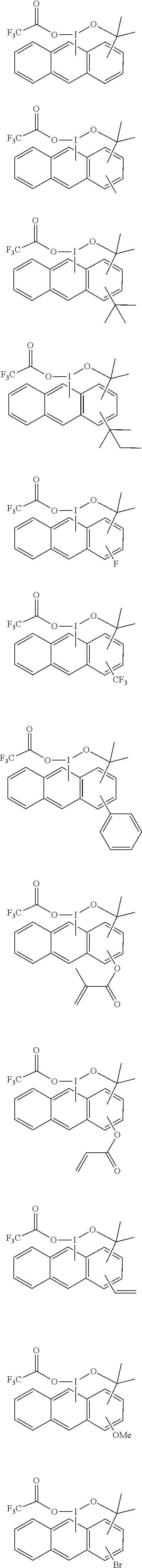

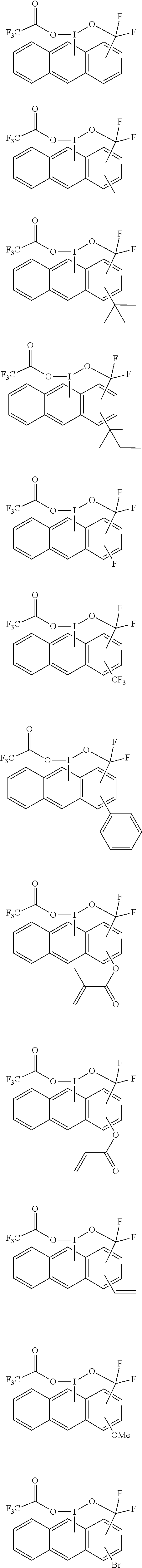

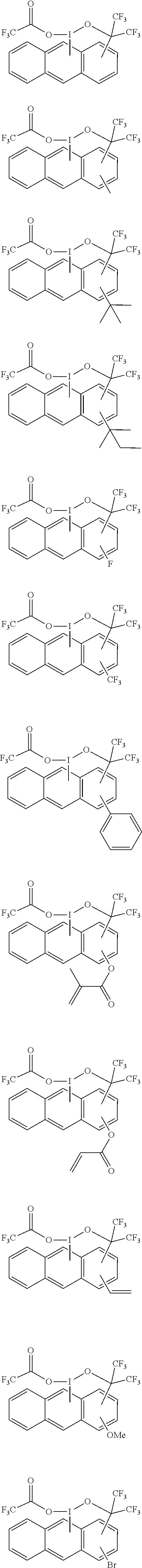

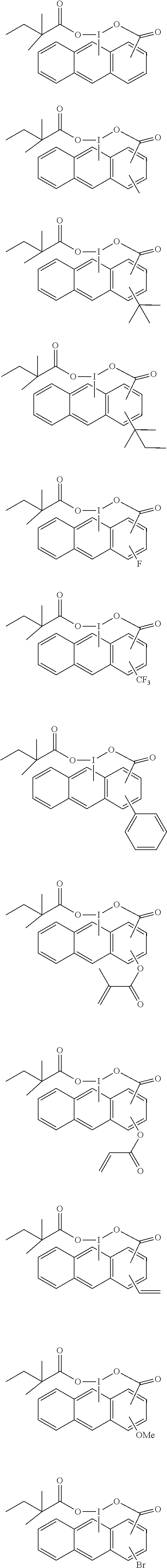

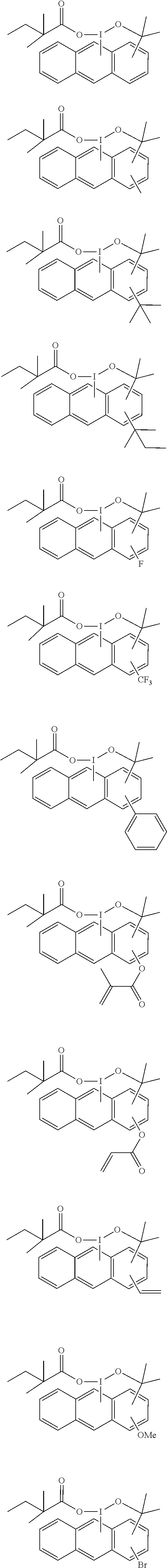

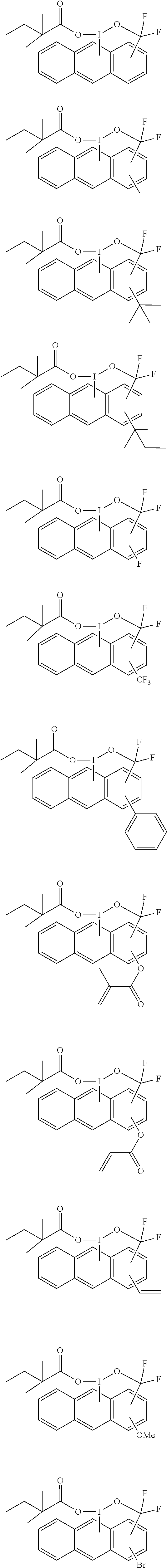

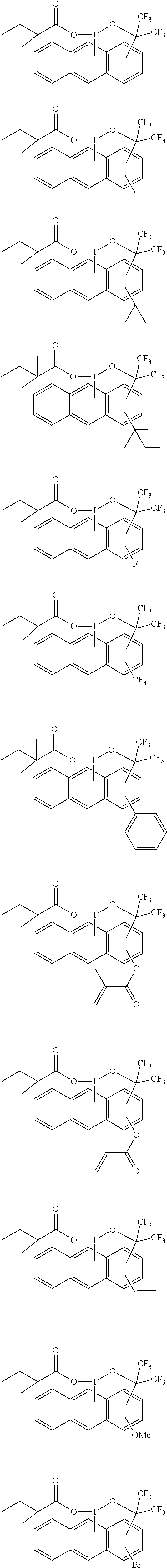

In the general formula (5), m2 represents an integer of 0 to 2.

When m2 is 0, n2 represents an integer of 1 to 3, n3 represents an integer of 0 to 5, and 1≤(n2+n3)≤6 is satisfied.

When m2 is 1, n2 represents an integer of 1 to 3, n3 represents an integer of 0 to 7, and 1≤(n2+n3)≤8 is satisfied.

When m2 is 2, n2 represents an integer of 1 to 3, n3 represents an integer of 0 to 9, and 1≤(n2+n3)≤10 is satisfied.

In the general formula (5), R⁵¹ and R⁵² each independently represent a halogen atom or a hydrocarbyl group having 1 to 10 carbon atoms and optionally having a heteroatom, R⁵¹ and R⁵² may be bonded to each other to form a ring together with the carbon atoms bonded thereto and with an atom between the carbon atoms. Examples of the halogen atom include a fluorine atom, a chlorine atom, a bromine atom, and an iodine atom. The hydrocarbyl group having 1 to 10 carbon atoms may be saturated or unsaturated, and may be linear, branched, or cyclic. Specific examples thereof include: alkyl groups having 1 to 10 carbon atoms, such as a methyl group, an ethyl group, a propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 10 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, and an adamantyl group; alkenyl groups, such as a vinyl group and an allyl group; aryl groups having 6 to 10 carbon atoms, such as a phenyl group and a naphthyl group; and groups obtained by combining these groups. Furthermore, part or all of the hydrogen atoms of the hydrocarbyl groups may be substituted with a group having a heteroatom, such as an oxygen atom, a sulfur atom, a nitrogen atom, or a halogen atom, and part of the —CH₂— of the hydrocarbyl groups may be substituted with a group having a heteroatom, such as an oxygen atom, a sulfur atom, or a nitrogen atom. The resulting hydrocarbyl groups may contain a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc. As R⁵¹ and R⁵², a hydrocarbyl group having 1 to 4 carbon atoms is preferable.

In the general formula (5), R⁵³ represents a halogen atom or a hydrocarbyl group having 1 to 40 carbon atoms and optionally having a heteroatom. Examples of the halogen atom include a fluorine atom, a chlorine atom, a bromine atom, and an iodine atom. The hydrocarbyl group having 1 to 40 carbon atoms may be saturated or unsaturated, and may be linear, branched, or cyclic. Specific examples thereof include: alkyl groups having 1 to 40 carbon atoms, such as a methyl group, an ethyl group, a propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; and aryl groups having 6 to 40 carbon atoms, such as a phenyl group, a naphthyl group, and an anthracenyl group. Furthermore, part or all of the hydrogen atoms of the hydrocarbyl groups may be substituted with a group having a heteroatom, such as an oxygen atom, a sulfur atom, a nitrogen atom, or a halogen atom, and part of the —CH₂— of the hydrocarbyl groups may be substituted with a group having a heteroatom, such as an oxygen atom, a sulfur atom, or a nitrogen atom. The resulting hydrocarbyl groups may contain a hydroxy group, a cyano group, a halogen atom, a carbonyl group, an ether bond, a thioether bond, an ester bond, a sulfonic acid ester bond, a carbonate bond, a carbamate bond, a lactone ring, a sultone ring, a carboxylic acid anhydride (—C(═O)—O—C(═O)—), etc. When “n3” is 2 to 9, the R⁵³s may be identical to or different from each other, and a plurality of R⁵³s may be bonded to each other to form a ring together with the carbon atoms of the aromatic ring bonded thereto.

Specific examples of the hypervalent iodine compound represented by the general formula (5) include the following, but are not limited thereto.

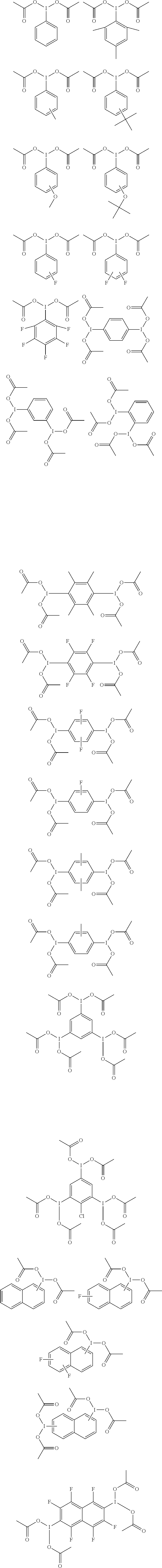

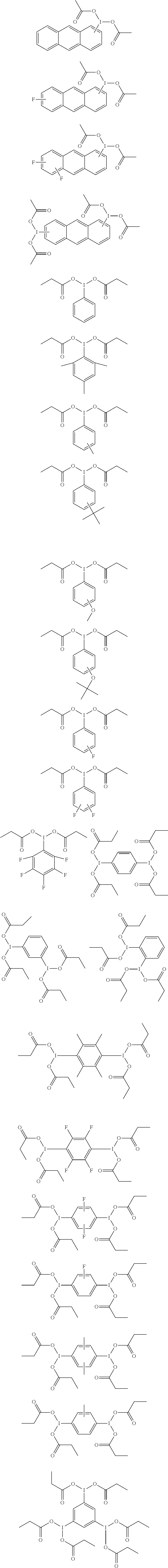

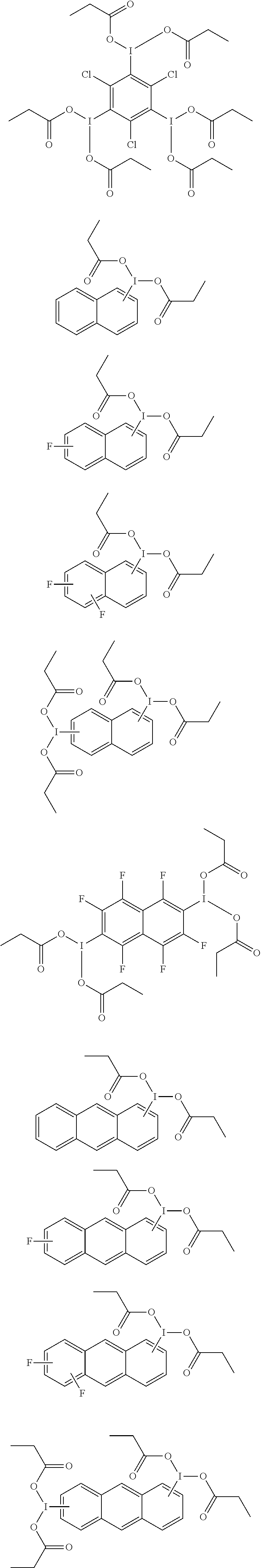

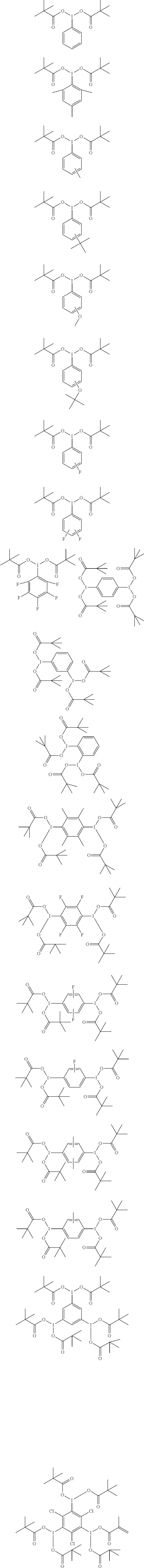

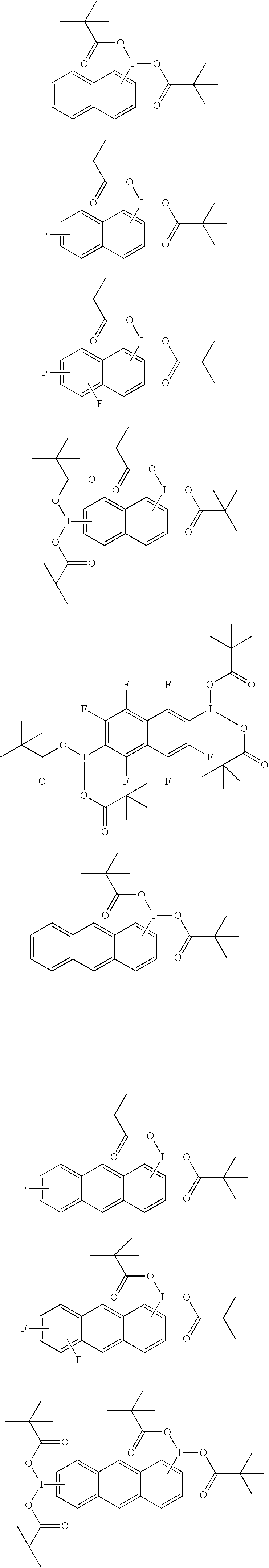

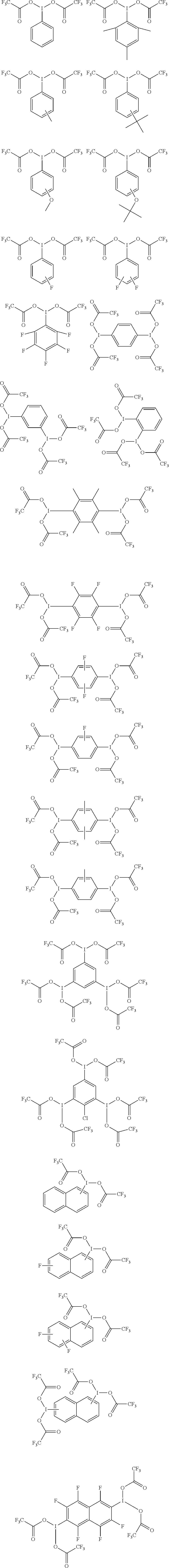

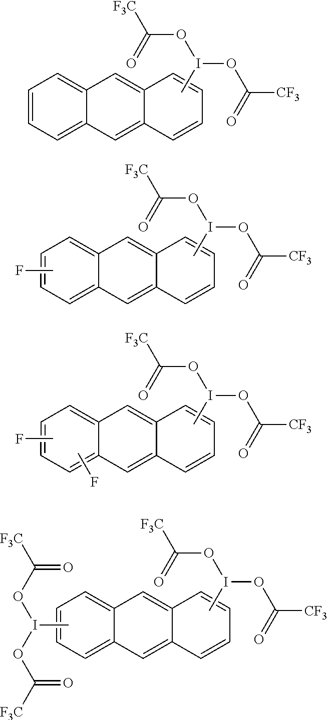

When the inventive resist composition contains another hypervalent iodine compound, the other hypervalent iodine compound to be used may be solely the hypervalent iodine compounds represented by the above general formula (4) or solely another hypervalent iodine compound represented by the general formula (5), or a hypervalent iodine compound represented by the general formula (4) and a hypervalent iodine compound represented by the general formula (5) may be used in combination. Furthermore, one kind of each of the hypervalent iodine compound represented by the general formula (4) and the hypervalent iodine compound represented by the general formula (5) may be used, or different two or more kinds thereof may be used in combination.

When the inventive resist composition contains another hypervalent iodine compound, the content ratio of the hypervalent iodine compound relative to the carboxy group-containing compound (when the carboxy group-containing compound is a carboxy group-containing polymer, the content ratio of the hypervalent iodine compound relative to the carboxylic acid-containing repeating units in the polymer) is preferably 1:99 to 99:1, more preferably 10:90 to 90:10, and further preferably 20:80 to 80:20 in terms of mole ratio. The other hypervalent iodine compound is preferably contained so that the mole ratio of the other hypervalent iodine compound relative to the hypervalent iodine compound represented by the formula (1) is 1:99 to 99:1, and more preferably 1:99 to 50:50 in terms of mole ratio.

### [Solvent]

The inventive resist composition contains a solvent. The solvent is not particularly limited as long as the solvent dissolves the hypervalent iodine compound represented by the formula (1), the carboxy-group-containing polymer, another hypervalent iodine compound, and other components described later and allows film formation. As such a solvent, organic solvents are preferable. Specific examples thereof include: ketones, such as cyclohexanone, methyl-2-n-pentyl ketone, and methyl isoamyl ketone; alcohols, such as 3-methoxybutanol, 3-methyl-3-methoxybutanol, 1-methoxy-2-propanol, 1-ethoxy-2-propanol, diacetone alcohol, 4-methyl-2-pentanol, and methyl 2-hydroxyisobutyrate; ethers, such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters, such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; carboxylic acids, such as formic acid, acetic acid, and propionic acid; lactones, such as y-butyrolactone; and mixed solvents thereof.

In the inventive resist composition, the contained amount of the solvent is preferably such an amount that the concentration of the solid contents in the resist composition is preferably 0.1 to 20 mass %, more preferably 0.1 to 15 mass %, and further preferably 0.1 to 10 mass %. Note that, in the present invention, the solid contents is a general term used to refer to the components other than the solvents out of all the components of the resist composition. One kind of the solvent may be used, or two or more kinds thereof may be used in mixture.

### [Other Components]

The inventive resist composition may further contain a surfactant. As the surfactant, a fluorine-based and/or silicone-based surfactant is preferable. Specific examples of such a surfactant include surfactants disclosed in paragraph [0276] of the description of US2008/0248425A1 description. Furthermore, it is also possible to use surfactants other than the fluorine-based and/or silicone-based surfactants disclosed in paragraph [0280] of the description of US2008/0248425A1.

When the inventive resist composition contains the surfactant, the contained amount is preferably 0.0001 to 2 mass % of all the solid contents. One kind of the surfactant may be used, or two or more kinds thereof may be used in combination.

The inventive resist composition may further contain at least one selected from radical scavengers and crosslinking agents, which makes it possible to control the photoreaction during photolithography and adjust the sensitivity.

Specific examples of the radical scavenger include hindered phenols, quinones, hindered amines, and thiol compounds. Specific examples of the hindered phenols include dibutylhydroxytoluene (BHT) and 2,2′-methylenebis(4-methyl-6-tert-butylphenol). Specific examples of the quinones include 4-methoxyphenol (methoquinone) and hydroquinone. Specific examples of the hindered amines include 2,2,6,6-tetramethylpiperidine and 2,2,6,6-tetramethylpiperidine-N-oxy radical. Specific examples of the thiol compounds include dodecanethiol and hexadecanethiol.

When the inventive resist composition contains the radical scavenger, the contained amount is preferably 0.01 to 10 mass % of all the solid contents. One kind of the radical scavenger may be used, or two or more kinds thereof may be used in combination.

Specific examples of the crosslinking agent include compounds having a carbon-carbon unsaturated bond as a functional group, such as a vinyl group, a (meth)acrylate group, an allyl group, an alkynyl group, and an aromatic ring. Specific examples of the compounds having a vinyl group include linear alkenes, branched alkenes, and cyclic alkenes, each optionally having a substituent. Specific examples of the compounds having a (meth)acrylate group include acrylic acid, methacrylic acid, acrylic acid ester, and methacrylic acid ester, each optionally having a substituent. Specific examples of the compounds having an allyl group include allyl alcohol, allyl ether, allyl ester, allyl amide, allylamine, and allyl-group-containing isocyanurates, each optionally having a substituent. Specific examples of the compounds having an alkynyl group include linear alkynes, branched alkynes, cyclic alkynes, alkynyl alcohols, alkynyl ethers, alkynyl esters, alkynyl amides, alkynyl amines, and alkynyl-group-containing isocyanurates, each optionally having a substituent. Specific examples of the compounds having an aromatic ring include arenes, heteroarenes, styrene, stilbene, phenylacetylene, acenaphthylene, and chalcone, each optionally having a substituent. The crosslinking agent may have only one of the functional groups, or may have a plurality of the functional groups. The number of the functional groups contained in the crosslinking agent is preferably 1 or more and 10 or less, more preferably 2 or more and 8 or less.

When the inventive resist composition contains the crosslinking agent, the contained amount is preferably 0.01 to 50 mass % of all the solid contents. One kind of the crosslinking agent may be used, or two or more kinds thereof may be used in combination.

As described above, the inventive resist composition contains a hypervalent iodine compound and a carboxyl group-containing polymer or low-molecular compound as its main components, but need not contain an acid-labile group-containing base polymer or a photoacid generator, as are contained in conventional chemically amplified resist compositions. However, the inventive resist composition, generates a difference in solubility between the exposed and unexposed areas particularly upon exposure by EB or EUV, enabling the formation of positive or negative patterns. The mechanism behind this is not completely clear, but is speculated to be as follows.

The hypervalent iodine compound represented by the formula (1) is a pentacoordinate compound having a carboxylate ligand. When such a pentacoordinate iodine compound is mixed with a carboxylic acid compound, an exchange of the carboxylate ligands is thought to occur in an equilibrium reaction. In this event, if the original carboxylate ligand can be removed by some method, a hypervalent iodine compound having a new ligand is generated. For example, by mixing Dess-Martin periodinane, a relatively readily available hypervalent iodine compound, with a high molecular weight carboxylic acid compound and removing the resulting low-boiling acetic acid, ligand-exchanging is completed. In this event, the carboxy group-containing compound becomes a polymer crosslinked with the hypervalent iodine compound.

The polymer crosslinked with the hypervalent iodine compound is generated at the time of film formation. Because such a crosslinked polymer is insoluble in many organic solvents when the crosslinked compound is synthesized beforehand, and therefore, a solution cannot be prepared. About this, it is speculated that the solvent solubility of the hypervalent iodine compound, originally having low solvent solubility due to its high polarization, is reduced, due to ligand-change to the carboxy-group-containing compound as a ligand. Accordingly, it is desirable to remove the original low-molecular-weight carboxylic acid component at the time of film formation and in the subsequent baking process, thus, as a step, completing the ligand exchange reaction and also forming a resist film.

The inventive resist film thus formed on the substrate changes in polarity through decomposition of the hypervalent iodine compound, being the main component of the resist film, by light, and thus a pattern is formed in a development process. By selecting the developer appropriately, a positive or negative pattern can be formed.

Based on the above speculation, it can be said that the inventive resist composition is a non-chemically amplified resist composition. Unlike conventional chemically amplified resist compositions, the inventive resist composition does not require an acid labile group-containing base polymer or a photoacid generator, and therefore does not suffer from adverse effects due to acid diffusion (e.g., image blurring), making it possible to resolve fine patterns.

The inventive resist composition is effective particularly in EUV lithography. This is because the inventive resist composition contains iodine atoms having high absorbing capability for EUV light, and the hypervalent iodine compound represented by the formula (1) has three carboxylate ligands, which are capable of undergoing the ligand exchange mentioned above, on one iodine atom, resulting in higher density crosslinking with the carboxy group-containing compound after film formation, and a larger difference in dissolution rate between unexposed and exposed areas, i.e., greater dissolution contrast, compared to when other hypervalent iodine compounds are used alone. That is, due to these characteristics, the inventive resist composition is able to achieve high sensitivity, high resolution, and low LWR.

In contrast, other hypervalent iodine compounds (I(III) compounds) represented by the formulae (4) and (5) have only one or two carboxylate ligands capable of the ligand exchange mentioned above on the same iodine atom, and therefore crosslinking between carboxy group-containing compounds (polymers, low-molecular compounds) does not occur or has difficulty in occurring during film formation, thus I(III) compounds will not achieve high sensitivity, high resolution, and low LWR alone.

As a resist composition for EUV lithography capable of forming a fine pattern, a metal resist containing a metal tin compound as a main component, which has a high absorbing capability for EUV light similar to iodine atoms, has been reported (e.g., Patent Document 2). However, as mentioned above, such metal resists have many problems, such as insufficient solubility in solvents, storage stability, and defects due to etching residues caused by the inclusion of a metal element. On the other hand, the inventive resist composition does not contain a metal element, and therefore is more advantageous than metal resist in terms of defects and has no problem also in light of solubility in a solvent. Furthermore, the inventive resist composition can be applied for both positive-type and negative-type resists, and therefore has a wide range of uses. For example, in the contact hole formation process, a metal resist used in negative-type development requires a reversing process after formation of a pillar pattern, on the other hand, positive-type resist does not require such a process. Therefore, from the perspective of process simplicity, the inventive resist composition can be said to be more useful than a metal resist.

JP2015-180928A and JP2018-95853A disclose resist compositions that contain a hypervalent iodine compound as an additive, and resist compositions in which a hypervalent iodine compound is incorporated into a polymer skeleton of a base polymer. However, these patent documents only describe that the resist composition can improve line edge roughness as a property of the resist composition, and don't mention about neither of possibility of the hypervalent iodine compounds being photodecomposed nor possibility of the hypervalent iodine compounds functioning as materials for non-chemically amplified resist compositions. In addition, according to the descriptions about blending amounts and specific examples, the hypervalent iodine compounds are not the main component. Furthermore, Patent Document 3 proposes a positive-type resist composition using a hypervalent iodine compound, but does not describe the hypervalent iodine compound represented by the formula (1) of the present invention, and does not mention anything about that use of such a compound improves resolution or LWR. Therefore, it is believed that these patent documents do not suggest the inventive non-chemically amplified resist composition, which exhibits extremely high sensitivity and excellent resolution and is extremely effective for precise fine processing. That is, it can be said that the present invention provides a clearly novel resist composition and patterning process.

### [Laminate]

The present invention provides a laminate including a substrate and a resist film which is a film made of the resist composition formed on the substrate. In such a laminate including the resist film obtained from the inventive non-chemically amplified resist composition, the resist film which is a film made of the resist composition mentioned above exhibits extremely high sensitivity and excellent resolution, and is extremely effective in precise fine processing. In addition, the resist film can be applied to both positive and negative patterning. Therefore, the laminate can be used in a wide range of applications and has extremely high usefulness for resist process technology.

In this case, the laminate may further include a resist underlayer film between the substrate and the resist film, as necessary.

Furthermore, in the inventive laminate, the resist film preferably contains a product of a ligand exchange reaction between the hypervalent iodine compound and a carboxy group-containing compound. In other words, the laminate is obtained by forming a substrate and a resist film obtained from the inventive resist composition on the substrate, and it is preferable that the resist film is formed by ligand exchange between the hypervalent iodine compound and a carboxy group-containing compound.

As described above, by removing the low molecular weight carboxylic acid generated secondarily in film formation and the subsequent baking process, the ligand exchange reaction between the hypervalent iodine compound and the carboxy group-containing compound proceeds to form a resist film containing the product of a ligand exchange reaction (i.e., to provide a film). By completion of the ligand exchange, the carboxy group-containing compound becomes a compound crosslinked with the hypervalent iodine compound. In this way, it is preferable to form a resist film with completing the ligand exchange reaction.

### [Patterning Process]

When the inventive resist composition is used for manufacturing of various integrated circuits, publicly known lithography techniques can be applied. For example, the patterning process includes steps of: forming a resist film on a substrate using the resist composition mentioned above, or on the resist underlayer film of the substrate having a resist underlayer film laminated thereon; exposing the resist film by a high-energy beam; and developing the exposed resist film using a developer. Hereinafter, the resist underlayer film will also be simply referred to as an “underlayer film”.

Firstly, the inventive resist composition is applied onto a substrate for manufacturing an integrated circuit, on an underlayer film of a substrate (Si, SiO₂, SiN, SiON, TiN, WSi, BPSG, SOG, organic antireflective film, etc.) on which the underlayer film has been laminated, on a substrate for manufacturing a mask circuit, or on an underlayer film of a substrate (Cr, CrO, CrON, MoSi₂, SiO₂, etc.) on which the underlayer film has been laminated, by an appropriate coating process such as spin coating, roll coating, flow coating, dip coating, spray coating, or doctor coating. The composition is applied so that the thickness of the coating film is 0.01 to 2 μm. The resultant is prebaked on a hot plate preferably at 60 to 200° C. for 10 seconds to 30 minutes, more preferably 80 to 180° C. for 30 seconds to 20 minutes, thus a resist film is formed. Note that an underlayer film means a film formed between a substrate and a resist film in a multilayer resist process. The underlayer film is not particularly limited, and a conventionally publicly known film can be used.

Subsequently, the resist film is exposed by a high-energy beam. Examples of the high-energy beam include an ultraviolet ray (a g-line (436 nm), an h-line (405 nm), an i-line (365 nm), etc.), a deep ultraviolet ray, an EB, an EUV, an X-ray, a soft X-ray, an excimer laser beam (a KrF excimer laser beam, an ArF excimer laser beam, etc.), a γ-ray, and a synchrotron radiation. As the high-energy beam, it is preferable to use an i-line, a KrF excimer laser beam, an ArF excimer laser beam, an electron beam (EB), or an extreme ultraviolet ray. When an ultraviolet ray, a deep ultraviolet ray, an EUV, an X-ray, a soft X-ray, an excimer laser beam, a y-ray, a synchrotron radiation, or the like is employed as the high-energy beam, the irradiation is performed directly or while using a mask for forming a target pattern at an exposure dose of preferably about 1 to 300 mJ/cm², more preferably about 10 to 200 mJ/cm². When EB is employed as the high-energy beam, the writing is performed directly or while using a mask for forming a target pattern at an exposure dose of preferably about 0.1 to 2000 μC/cm², more preferably about 0.5 to 1500 μC/cm². Note that the inventive resist composition is suitable particularly for fine patterning with EB or EUV, among the high-energy beams.

After the exposure, PEB is performed as necessary. In this event, the PEB is preferably performed after the exposure on a hot plate or in an oven under the conditions of 30 to 150° C. for 10 seconds to 30 minutes, more preferably 60 to 120° C. for 30 seconds to 20 minutes.

After the exposure or after the PEB, development is performed by using a developer to perform patterning. Examples of the developer used in this event include: aqueous alkaline solutions, such as an aqueous solution of tetramethylammonium hydroxide; and organic solvents, such as 2-octanone, 2-nonanone, 2-heptanone, 3-heptanone, 4-heptanone, 2-hexanone, 3-hexanone, diisobutyl ketone, methylcyclohexanone, acetophenone, methylacetophenone, isopropyl alcohol, isoamyl alcohol, n-butanol, n-pentanol, cyclohexanol, propyl acetate, butyl acetate, isobutyl acetate, pentyl acetate, butenyl acetate, isopentyl acetate, cyclohexyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, phenylmethyl acetate, phenylethyl acetate, benzyl formate, phenylethyl formate, methyl 3-phenylpropionate, benzyl propionate, 2-phenylethyl acetate, 1-propanol, 3-methoxybutanol, 3-methyl-3-methoxybutanol, 1-methoxy-2-propanol, 1-ethoxy-2-propanol, diacetone alcohol, and 4-methyl-2-pentanol. One kind of these developers may be used, or two or more kinds thereof may be used in mixture.

After the development, rinsing is performed as necessary. The rinsing liquid is preferably a solvent that is miscible with the developer but does not dissolve the resist film. As such a solvent, it is preferable to use an alcohol having 3 to 10 carbon atoms, an ether compound having 8 to 12 carbon atoms, an alkane, alkene, alkyne, and aromatic solvent, each having 6 to 12 carbon atoms. Moreover, water may be used as a rinse liquid instead of an organic solvent.

The rinsing can reduce collapse of a resist pattern and occurrence of defect. Meanwhile, the rinsing is not necessarily essential, and the amount of the solvent used can be reduced by not performing the rinsing.

As described above, the inventive resist composition can form a positive or negative pattern by exposure, by causing a difference in solubility between the exposed portions and unexposed portions. Therefore, it is possible to use a developer that dissolves the exposed portions but not the unexposed portions, or a developer that dissolves the unexposed portions but not the exposed portions. As described above, the inventive patterning process can form a positive or negative pattern by appropriately selecting a developer, and can therefore be widely applied to a variety of fine patterning.

### EXAMPLE

Hereinafter, the present invention will be specifically described with reference to Synthesis Example, Examples, and Comparative Examples. However, the present invention is not limited thereto.

### [1] Hypervalent Iodine(V) Compounds

The hypervalent iodine compounds used in the examples are represented by the following formulae I-1 and I-2.

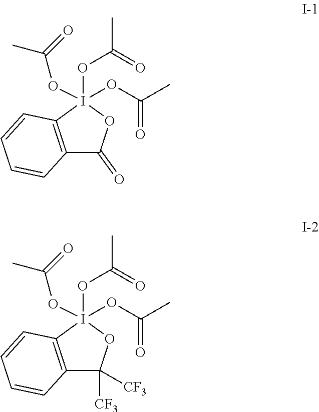 [SMILES: CC(=O)OI1(OC(C)=O)(OC(C)=O)OC(=O)c2ccccc21 ; CC(=O)OI1(OC(C)=O)(OC(C)=O)OC(C(F)(F)F)(C(F)(F)F)c2ccccc21]

The hypervalent iodine compound represented by the formula I-1 was synthesized with reference to Heterocycles, 2021, 103, 694. The hypervalent iodine compound represented by the formula I-2 was synthesized with reference to J. Am. Chem. Soc., 1991, 113, 7277.

### [2] Synthesis of Polymers

The monomers a-1 to a-3, b-1 to b-3, c-1, and c-2 used in the synthesis of polymers are as follows.

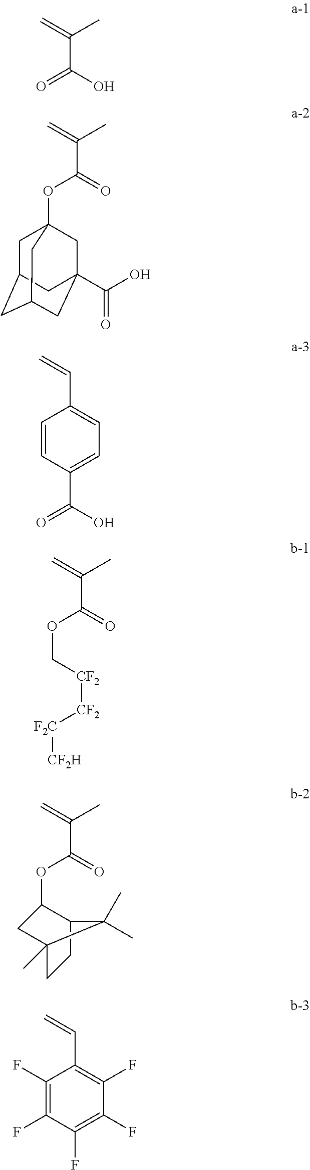

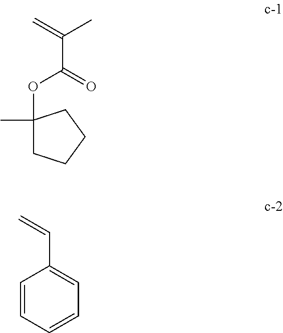

### [Synthesis Example 2-1] Synthesis of Polymer P-1

Monomer a-1 (56 g), monomer b-1 (105 g), 5.4 g of V-601 (FUJIFILM Wako Pure Chemical Industries, Ltd.), and 180 g of MEK were placed in a flask under a nitrogen atmosphere to prepare a monomer-polymerization initiator solution. 55 g of MEK was placed in another flask under a nitrogen atmosphere and heated to 80° C. with stirring, and then the monomer-polymerization initiator solution was added thereto dropwise over 4 hours. After completion of the dropwise addition, the stirring was continued for 2 hours while maintaining the temperature of the polymerization solution at 80° C., and then the polymerization solution was cooled to room temperature. The obtained polymerization solution was added dropwise to 4000 g of vigorously stirred hexane, and the precipitated polymer was separated by filtration. The obtained polymer was further washed twice with 1200 g of hexane and then dried in a vacuum at 50° C. for 20 hours to obtain polymer P-1 in a form of a white powder (yield: 155 g, 96%). The Mw of polymer P-1 was 7700, and Mw/Mn was 1.82. The Mw was value measured by GPC using THF as a solvent in terms of standard polystyrene.

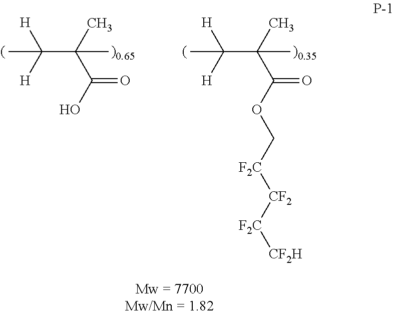

### [Synthesis Examples 2-2 to 2-10] Synthesis of Polymers P-2 to P-10

The polymers shown in Table 1 below were synthesized in the same manner as in Synthesis Example 1, except that the types and blending ratios of the respective monomers were changed.

TABLE 1

| | | | Introduction | | Introduction | | |
|---|---|---|---|---|---|---|---|
| | | | ratio | | ratio | | |
| | Polymer | Unit 1 | (mol %) | Unit 2 | (mol %) | Mw | Mw/Mn |
| Synthesis | P-1 | a-1 | 65 | b-1 | 35 | 7700 | 1.82 |
| Example 1 | | | | | | | |
| Synthesis | P-2 | a-1 | 50 | b-2 | 50 | 8400 | 1.84 |
| Example 2 | | | | | | | |
| Synthesis | P-3 | a-1 | 60 | b-3 | 40 | 8100 | 1.79 |
| Example 3 | | | | | | | |
| Synthesis | P-4 | a-2 | 65 | b-1 | 35 | 8300 | 1.83 |
| Example 4 | | | | | | | |
| Synthesis | P-5 | a-2 | 50 | b-2 | 50 | 8300 | 1.83 |
| Example 5 | | | | | | | |
| Synthesis | P-6 | a-2 | 60 | b-3 | 40 | 8200 | 1.82 |
| Example 6 | | | | | | | |
| Synthesis | P-7 | a-3 | 65 | b-1 | 35 | 8000 | 1.80 |
| Example 7 | | | | | | | |
| Synthesis | P-8 | a-3 | 50 | b-2 | 50 | 8600 | 1.84 |
| Example 8 | | | | | | | |
| Synthesis | P-9 | a-3 | 60 | b-3 | 40 | 7900 | 1.81 |
| Example 9 | | | | | | | |
| Synthesis | P-10 | c-1 | 60 | c-2 | 40 | 9800 | 1.82 |
| Example 10 | | | | | | | |

### [3] Preparation of Resist Compositions

### Examples 1-1 to 1-22 and Comparative Examples 1-1 to 1-4

Resist compositions (R-01 to R-22) and comparative resist compositions (CR-01 to CR-02) were prepared by dissolving the hypervalent iodine compound, other hypervalent iodine compounds, and polymers in a solvent containing 0.01 mass % of a surfactant (PF-636, manufactured by OMNOVA Solutions Inc.) according to the compositions shown in Table 2 below, and filtering the resulting solution through a 0.2 μm Teflon (registered trademark) filter. Comparative resist compositions (CR-03 to CR-04) were prepared by dissolving the polymer, photoacid generator, and sensitivity modifier in a solvent containing 0.01 mass % of a surfactant (PF-636, manufactured by OMNOVA Solutions Inc.) according to the compositions shown in Table 3 below, and filtering the resulting solution through a 0.2 μm Teflon (registered trademark) filter.

TABLE 2

| | | | Other | Carboxy | | |
|---|---|---|---|---|---|---|
| | | Hypervalent | hypervalent | group- | | |
| | | iodine | iodine | containing | | |
| | | compound | compound | compound | Solvent 1 | Solvent 2 |
| | Resist | (parts by | (parts by | (parts by | (parts by | (parts by |
| | composition | mass) | mass) | mass) | mass) | mass) |
| Example 1-1 | R-01 | I-1 | — | P-1 | PGMEA | AcOH |
| | | (10) | | (17.5) | (800) | (200) |
| Example 1-2 | R-02 | I-2 | — | P-1 | PGMEA | AcOH |
| | | (10) | | (13.6) | (800) | (200) |
| Example 1-3 | R-03 | I-1 | — | P-2 | PGMEA | AcOH |
| | | (10) | | (21.8) | (800) | (200) |
| Example 1-4 | R-04 | I-1 | — | P-3 | PGMEA | AcOH |
| | | (10) | | (15.2) | (800) | (200) |
| Example 1-5 | R-05 | I-1 | — | P-4 | PGMEA | AcOH |
| | | (10) | | (24.3) | (800) | (200) |
| Example 1-6 | R-06 | I-1 | — | P-5 | PGMEA | AcOH |
| | | (10) | | (34.4) | (800) | (200) |
| Example 1-7 | R-07 | I-1 | — | P-6 | PGMEA | AcOH |
| | | (10) | | (27.8) | (800) | (200) |
| Example 1-8 | R-08 | I-1 | — | P-7 | PGMEA | AcOH |
| | | (10) | | (21.9) | (800) | (200) |
| Example 1-9 | R-09 | I-1 | — | P-8 | PGMEA | AcOH |
| | | (10) | | (26.2) | (800) | (200) |
| Example 1-10 | R-10 | I-1 | — | P-9 | PGMEA | AcOH |
| | | (10) | | (19.6) | (800) | (200) |
| Example 1-11 | R-11 | I-1 | — | P-1 | HBM | AcOH |
| | | (10) | | (17.5) | (800) | (200) |
| Example 1-12 | R-12 | I-1 | — | P-1 | PGMEA | PA |
| | | (10) | | (17.5) | (800) | (200) |
| Example 1-13 | R-13 | I-1 | — | P-1 | PGMEA | AcOH |
| | | (5) | | (17.5) | (800) | (200) |
| Example 1-14 | R-14 | I-1 | O-1 | P-1 | PGMEA | AcOH |
| | | (5) | (2.5) | (17.5) | (800) | (200) |
| Example 1-15 | R-15 | I-1 (5) | — | P-1 | PGMEA | AcOH |
| | | I-2 (5) | | (17.5) | (800) | (200) |
| Example1-16 | R-16 | I-1 | — | m-1 | PGMEA | AcOH |
| | | (10) | | (8.5) | (800) | (200) |
| Example 1-17 | R-17 | I-1 | — | m-2 | PGMEA | AcOH |
| | | (10) | | (4.1) | (800) | (200) |
| Example 1-18 | R-18 | I-1 | — | m-3 | PGMEA | AcOH |
| | | (10) | | (8.4) | (800) | (200) |
| Example 1-19 | R-19 | I-1 | — | m-4 | PGMEA | AcOH |
| | | (10) | | (7.6) | (800) | (200) |
| Example 1-20 | R-20 | I-1 | — | m-5 | PGMEA | AcOH |
| | | (10) | | (11.6) | (800) | (200) |
| Example 1-21 | R-21 | I-1 | — | m-6 | PGMEA | AcOH |
| | | (10) | | (8.9) | (800) | (200) |
| Example 1-22 | R-22 | I-2 | — | m-6 | PGMEA | AcOH |
| | | (10) | | (6.9) | (800) | (200) |
| Comparative | CR-01 | — | O-1 | P-1 | PGMEA | AcOH |
| Example 1-1 | | | (10) | (15) | (800) | (200) |
| Comparative | CR-02 | — | O-1 | m-1 | PGMEA | AcOH |
| Example 1-2 | | | (10) | (7.5) | (800) | (200) |

TABLE 3

| | | | Photo-acid | Sensitivity | | |
|---|---|---|---|---|---|---|
| | | Polymer | generator | modifier | Solvent 1 | Solvent 2 |
| | Resist | (parts by | (parts by | (parts by | (parts by | (parts by |
| | composition | mass) | mass) | mass) | mass) | mass) |
| Comparative | CR-03 | P-10 | PAG-1 | Q-1 | PGMEA | GBL |
| Example 1-3 | | (80) | (19) | (6) | (1890) | (210) |
| Comparative | CR-04 | P-10 | PAG-1 | I-1 | PGMEA | GBL(210) |
| Example 1-4 | | (80) | (19) | (5) | (1890) | |

In Tables 2 and 3, hypervalent iodine compound 0-1, carboxy group-containing compounds m-1 to m-6, photoacid generator PAG-1, sensitivity modifier Q-1, and solvents are as follows.

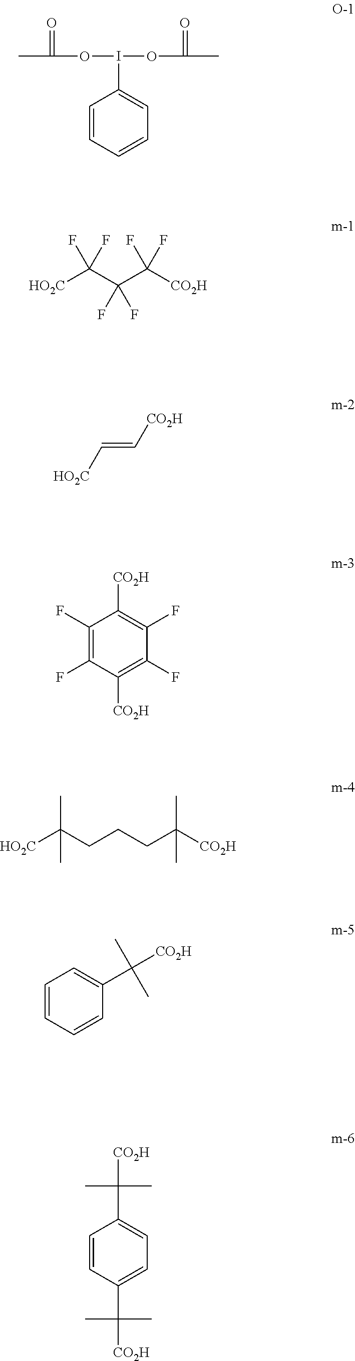

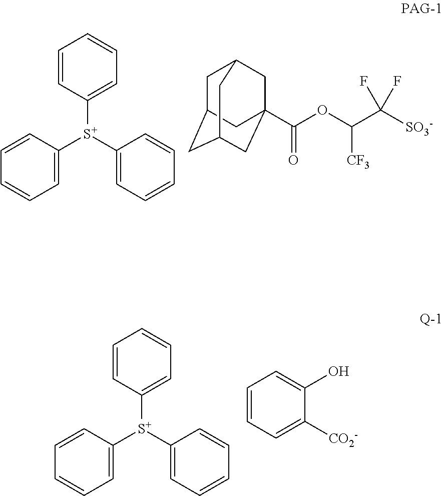

Solvent: PGMEA (Propylene Glycol Monomethyl Ether Acetate)
AcOH (Acetic Acid)
HBM (2-Hydroxyisobutyrate Methyl)
PA (Propionic Acid)
GBL (Gamma-Butyrolactone)

### [4] Evaluation of EUV Lithography (Line-and-Space Pattern, Positive Development)

### Examples 2-1 to 2-22 and Comparative Examples 2-1 to 2-4

One of resist composition (R-01 to R-22 and CR-01 to CR-04) was spin-coated onto a Si substrate on which a silicon-containing spin-on hard mask SHB-A940 (silicon content: 43 mass %) manufactured by Shin-Etsu Chemical Co., Ltd. had been formed with a thickness of 20 nm, and pre-baking (PAB) was performed on a hot plate at the temperature shown in Table 4 for 60 seconds to prepare a resist film with a thickness of 40 nm. Using an EUV scanner NXE3400 (NA 0.33, a 0.9, 90-degree dipole illumination) manufactured by ASML Holding N.V., a 36 nm line and space (LS) 1:1 pattern was exposed, and then PEB was performed on a hot plate at the temperature shown in Table 4 for 60 seconds, followed by development for 30 seconds using a developer shown in Table 4 to form an LS pattern with a space width of 18 nm and a pitch of 36 nm.

The resulting resist patterns were evaluated as follows, and the results are shown in Table 4.

### [Evaluation of Sensitivity]

The LS patterns were observed with a CD-SEM CG-6300 manufactured by Hitachi High-Technologies Corporation, and the optimum exposure dose Eₒₚ(mJ/cm²) at which the LS pattern with a space width of 18 nm and a pitch of 36 nm could be obtained was determined and defined as the sensitivity.

### [Evaluation of LWR]

The dimensions of the LS pattern obtained by the irradiation at the optimum exposure dose was measured at ten positions in the longitudinal direction of the space width with CD-SEM CG-6300 manufactured by Hitachi High-Technologies Corporation. Based on this result, the triple value (3σ) of the standard deviation (σ) was determined as LWR. The smaller this value, the smaller the roughness and the more uniform the line width of the obtained pattern.

### [Evaluation of Limit Resolution]

The limit line width (nm) that can be resolved when forming a pattern by gradually increasing an exposure dose from the optimum exposure dose at which the LS pattern is formed was determined with CD-SEM CG-6300 manufactured by Hitachi High-Technologies Corporation, and was defined as the limit resolution (nm). The smaller this value, the more excellent the limit resolution and the finer the pattern that can be formed.

TABLE 4

| | | | | | | Limit |
|---|---|---|---|---|---|---|
| | Resist | PAB/PEB | | Eop | LWR | resolution |
| | composition | (° C.) | Developer | (mJ/cm²) | (nm) | (nm) |
| Example 2-1 | R-01 | 130/90 | nBA | 27 | 2.5 | 9 |
| Example 2-2 | R-02 | 130/90 | nBA | 28 | 3.0 | 10 |
| Example 2-3 | R-03 | 130/90 | nBA | 28 | 2.9 | 10 |
| Example 2-4 | R-04 | 130/90 | nBA | 30 | 2.8 | 9 |
| Example 2-5 | R-05 | 130/90 | nBA | 32 | 2.5 | 9 |
| Example 2-6 | R-06 | 130/90 | nBA | 33 | 2.7 | 11 |
| Example 2-7 | R-07 | 130/90 | nBA | 32 | 2.8 | 12 |
| Example 2-8 | R-08 | 130/90 | nBA | 33 | 2.6 | 12 |
| Example 2-9 | R-09 | 130/90 | nBA | 28 | 2.5 | 12 |
| Example 2-10 | R-10 | 130/90 | nBA | 30 | 2.7 | 10 |
| Example 2-11 | R-11 | 130/90 | nBA | 26 | 2.4 | 12 |
| Example 2-12 | R-12 | 130/90 | nBA | 25 | 2.4 | 9 |
| Example 2-13 | R-13 | 130/90 | CHA | 20 | 2.4 | 9 |
| Example 2-14 | R-14 | 130/90 | nBA | 24 | 2.2 | 8 |
| Example 2-15 | R-15 | 130/90 | nBA | 27 | 2.3 | 9 |
| Example 2-16 | R-16 | 130/90 | nBA | 28 | 2.7 | 9 |
| Example 2-17 | R-17 | 130/90 | nBA | 25 | 2.6 | 10 |
| Example 2-18 | R-18 | 130/90 | nBA | 29 | 2.8 | 10 |
| Example 2-19 | R-19 | 130/90 | nBA | 26 | 2.6 | 11 |
| Example 2-20 | R-20 | 130/90 | nBA | 26 | 2.5 | 9 |
| Example 2-21 | R-21 | 130/90 | nBA | 25 | 2.9 | 9 |
| Example 2-22 | R-22 | 130/90 | nBA | 27 | 2.2 | 11 |
| Comparative | CR-01 | 130/90 | nBA | 39 | 3.6 | 14 |
| Example 2-1 | | | | | | |
| Comparative | CR-02 | 130/90 | nBA | 40 | 3.8 | 16 |
| Example 2-2 | | | | | | |
| Comparative | CR-03 | 105/90 | TMAH | 80 | 4.5 | 18 |
| Example 2-3 | | | | | | |
| Comparative | CR-04 | 105/90 | TMAH | 85 | 4.8 | 18 |
| Example 2-4 | | | | | | |

Developer: nBA (butyl acetate)
CHA (cyclohexyl acetate)
TMAH (2.38 mass % aqueous solution of tetramethylammonium hydroxide)

### [5] Evaluation of EUV Lithography (Line-and-Space Pattern, Negative Development)

### Examples 3-1 to 3-22 and Comparative Examples 3-1 to 3-4

One of resist composition (R-01 to R-22 and CR-01 to CR-04) was spin-coated onto a Si substrate on which a silicon-containing spin-on hard mask SHB-A940 (silicon content: 43 mass %) manufactured by Shin-Etsu Chemical Co., Ltd. had been formed with a thickness of 20 nm, and pre-baking (PAB) was performed on a hot plate at the temperature shown in Table 5 for 60 seconds to prepare a resist film with a thickness of 40 nm. Using an EUV scanner NXE3400 (NA 0.33, a 0.9, 90-degree dipole illumination) manufactured by ASML Holding N.V., a 36 nm line and space (LS) 1:1 pattern was exposed, and then PEB was performed on a hot plate at the temperature shown in Table 5 for 60 seconds, followed by development for 30 seconds using a developer shown in Table 5 to form an LS pattern with a space width of 18 nm and a pitch of 36 nm.

The resulting resist patterns were evaluated as follows, and the results are shown in Table 5.

### [Evaluation of Sensitivity]

The LS patterns were observed with a CD-SEM CG-6300 manufactured by Hitachi High-Technologies Corporation, and the optimum exposure dose Eₒₚ (mJ/cm²) at which the LS pattern with a space width of 18 nm and a pitch of 36 nm could be obtained was determined and defined as the sensitivity.

### [Evaluation of LWR]

The dimensions of the LS pattern obtained by the irradiation at the optimum exposure dose was measured at ten positions in the longitudinal direction of the space width with CD-SEM CG-6300 manufactured by Hitachi High-Technologies Corporation. Based on this result, the triple value (3σ) of the standard deviation (σ) was determined as LWR. The smaller this value, the smaller the roughness and the more uniform the line width of the obtained pattern.

### [Evaluation of Limit Resolution]

The limit line width (nm) that can be resolved when forming a pattern by gradually increasing an exposure dose from the optimum exposure dose at which the LS pattern is formed was determined with CD-SEM CG-6300 manufactured by Hitachi High-Technologies Corporation, and was defined as the limit resolution (nm). The smaller this value, the more excellent the limit resolution and the finer the pattern that can be formed.

TABLE 5

| | | | | | | Limit |
|---|---|---|---|---|---|---|
| | Resist | PAB/PEB | | Eop | LWR | resolution |
| | composition | (° C.) | Developer | (mJ/cm²) | (nm) | (nm) |
| Example 3-1 | R-01 | 130/90 | TMAH | 29 | 3.0 | 10 |
| Example 3-2 | R-02 | 130/90 | TMAH | 30 | 3.4 | 11 |
| Example 3-3 | R-03 | 130/90 | TMAH | 30 | 3.4 | 10 |
| Example 3-4 | R-04 | 130/90 | TMAH | 31 | 3.3 | 10 |
| Example 3-5 | R-05 | 130/90 | TMAH | 32 | 2.9 | 10 |
| Example 3-6 | R-06 | 130/90 | TMAH | 33 | 3.1 | 12 |
| Example 3-7 | R-07 | 130/90 | TMAH | 32 | 3.2 | 13 |
| Example 3-8 | R-08 | 130/90 | TMAH | 33 | 3.2 | 12 |
| Example 3-9 | R-09 | 130/90 | TMAH | 30 | 3.0 | 13 |
| Example 3-10 | R-10 | 130/90 | TMAH | 30 | 3.1 | 11 |
| Example 3-11 | R-11 | 130/90 | TMAH | 28 | 2.9 | 13 |
| Example 3-12 | R-12 | 130/90 | TMAH | 27 | 2.9 | 9 |
| Example 3-13 | R-13 | 130/90 | TMAH | 22 | 2.9 | 10 |
| Example 3-14 | R-14 | 130/90 | TMAH | 26 | 2.8 | 9 |
| Example 3-15 | R-15 | 130/90 | TMAH | 29 | 2.7 | 11 |
| Example 3-16 | R-16 | 130/90 | TMAH | 30 | 3.2 | 10 |
| Example 3-17 | R-17 | 130/90 | TMAH | 27 | 3.1 | 11 |
| Example 3-18 | R-18 | 130/90 | TMAH | 31 | 3.3 | 11 |
| Example 3-19 | R-19 | 130/90 | TMAH | 28 | 3.1 | 12 |
| Example 3-20 | R-20 | 130/90 | TMAH | 26 | 3.0 | 10 |
| Example 3-21 | R-21 | 130/90 | TMAH | 27 | 3.4 | 10 |
| Example 3-22 | R-22 | 130/90 | TMAH | 29 | 2.7 | 11 |
| Comparative | CR-01 | 130/90 | TMAH | 40 | 4.1 | 16 |
| Example 3-1 | | | | | | |
| Comparative | CR-02 | 130/90 | TMAH | 41 | 4.2 | 17 |
| Example 3-2 | | | | | | |
| Comparative | CR-03 | 105/90 | nBA | 83 | 4.6 | 18 |
| Example 3-3 | | | | | | |
| Comparative | CR-04 | 105/90 | nBA | 86 | 4.9 | 18 |
| Example 3-4 | | | | | | |

The results shown in Tables 4 and 5 demonstrate that the inventive resist composition is excellent in sensitivity, LWR, and resolution in both positive tone and negative tone development when forming a line and space pattern by EUV exposure.

### [6] Evaluation of EUV Lithography (Contact Hole Pattern)

### Examples 4-1 to 4-22 and Comparative Examples 4-1 to 4-4

One of resist composition (R-01 to R-22 and CR-01 to CR-04) was spin-coated onto a Si substrate on which a silicon-containing spin-on hard mask SHB-A940 (silicon content: 43 mass %) manufactured by Shin-Etsu Chemical Co., Ltd. had been formed with a thickness of 20 nm, and pre-baking (PAB) was performed on a hot plate at the temperature shown in Table 6 for 60 seconds to prepare a resist film with a thickness of 50 nm. Next, using an EUV scanner NXE3400 (NA 0.33, σ0.9/0.6, quadrupole illumination, with a mask having a hole pattern with a pitch of 64 nm and +20% bias, in terms of on-wafer size) manufactured by ASML Holding N.V., the resist film was exposed and baked (PEB) on a hot plate at the temperature shown in Table 6 for 60 seconds, followed by development for 30 seconds using a developer shown in Table 6 to form a hole pattern with a dimension of 32 nm.

The resulting resist patterns were evaluated as follows, and the results are shown in Table 6.

### [Evaluation of Sensitivity]

The hole patterns were observed with a CD-SEM CG-6300 manufactured by Hitachi High-Technologies Corporation, and the optimum exposure dose Eₒₚ(mJ/cm²) at which the hole pattern with a dimension of 32 nm could be obtained was determined.

### [Evaluation of CD Uniformity (CDU)]

Dimensions of 50 hole patterns obtained by the irradiation at the optimum exposure dose were measured, and a tripled value (3σ) of a standard variation (σ) calculated from the results was defined as CDU. The smaller this value, the more uniform the hole diameter that can be obtained.

### [Evaluation of Limit Resolution]

The limit hole diameter (nm) that can be resolved when forming a hole pattern by gradually decreasing an exposure dose from the optimum exposure dose at which the hole pattern is formed was determined with CD-SEM CG-6300 manufactured by Hitachi High-Technologies Corporation, and was defined as the limit resolution (nm). The smaller this value, the more excellent the limit resolution and the finer the hole pattern that can be formed.

TABLE 6

| | | | | | | Limit |
|---|---|---|---|---|---|---|
| | Resist | PAB/PEB | | Eop | CDU | resolution |
| | composition | (° C.) | Developer | (mJ/cm²) | (nm) | (nm) |
| Example 4-1 | R-01 | 130/90 | nBA | 17 | 2.0 | 19 |
| Example 4-2 | R-02 | 130/90 | nBA | 18 | 2.3 | 20 |
| Example 4-3 | R-03 | 130/90 | nBA | 18 | 2.2 | 20 |
| Example 4-4 | R-04 | 130/90 | nBA | 20 | 2.3 | 19 |
| Example 4-5 | R-05 | 130/90 | nBA | 22 | 2.0 | 19 |
| Example 4-6 | R-06 | 130/90 | nBA | 21 | 2.2 | 21 |
| Example 4-7 | R-07 | 130/90 | nBA | 22 | 2.3 | 22 |
| Example 4-8 | R-08 | 130/90 | nBA | 22 | 2.1 | 22 |
| Example 4-9 | R-09 | 130/90 | nBA | 18 | 2.0 | 22 |
| Example 4-10 | R-10 | 130/90 | nBA | 20 | 2.2 | 20 |
| Example 4-11 | R-11 | 130/90 | nBA | 16 | 1.9 | 22 |
| Example 4-12 | R-12 | 130/90 | nBA | 15 | 1.9 | 19 |
| Example 4-13 | R-13 | 130/90 | CHA | 13 | 1.9 | 19 |
| Example 4-14 | R-14 | 130/90 | nBA | 14 | 1.7 | 18 |
| Example 4-15 | R-15 | 130/90 | nBA | 17 | 1.8 | 19 |
| Example 4-16 | R-16 | 130/90 | nBA | 18 | 2.2 | 19 |
| Example 4-17 | R-17 | 130/90 | nBA | 15 | 2.1 | 20 |
| Example 4-18 | R-18 | 130/90 | nBA | 19 | 2.2 | 20 |
| Example 4-19 | R-19 | 130/90 | nBA | 16 | 2.1 | 21 |
| Example 4-20 | R-20 | 130/90 | nBA | 16 | 2.0 | 19 |
| Example 4-21 | R-21 | 130/90 | nBA | 15 | 2.1 | 19 |
| Example 4-22 | R-22 | 130/90 | nBA | 17 | 1.7 | 21 |
| Comparative | CR-01 | 130/90 | nBA | 25 | 2.7 | 26 |
| Example 4-1 | | | | | | |
| Comparative | CR-02 | 130/90 | nBA | 26 | 2.9 | 28 |
| Example 4-2 | | | | | | |
| Comparative | CR-03 | 105/90 | TMAH | 42 | 3.8 | 32 |
| Example 4-3 | | | | | | |
| Comparative | CR-04 | 105/90 | TMAH | 40 | 4.0 | 32 |
| Example 4-4 | | | | | | |

The results shown in Table 6 demonstrate that the inventive resist composition is excellent in sensitivity, CDU, and resolution when forming a contact hole pattern by EUV exposure.

The present description includes the following embodiments.

[1]: A resist composition comprising a hypervalent iodine compound represented by the following formula (1), a carboxy group-containing compound, and a solvent,

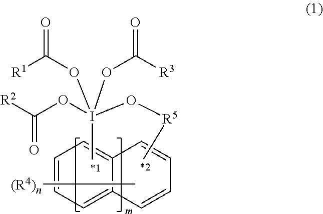

wherein “m” represents an integer of 0 to 2; “n” represents an integer of 0 to 4 when “m” is 0, an integer of 0 to 6 when “m” is 1, and an integer of 0 to 8 when “m” is 2; R¹, R², and R³ represent each independently a halogen atom or a hydrocarbyl group having 1 to 10 carbon atoms and optionally having a heteroatom, and R¹, R², and R³ may be bonded to each other to form a ring; R⁴ represents a halogen atom or a hydrocarbyl group having 1 to 40 carbon atoms and optionally having a heteroatom, R⁴s may be identical to or different from each other when “n” is 2 or greater, and a plurality of R⁴s may be bonded to each other to form a ring together with the carbon atoms of the aromatic ring bonded thereto; R⁵ represents a carbonyl group or a hydrocarbylene group having 1 to 10 carbon atoms and optionally having a heteroatom; and *1 and *2 represent an attachment point to a carbon atom of the aromatic ring in the formula, and *1 and *2 are bonded to adjacent carbon atoms of the aromatic ring.
[2]: The resist composition of the above [1], wherein the carboxy group-containing compound is one or both of a polymer having a repeating unit represented by the following formula (2) and a compound represented by the following formula (3),

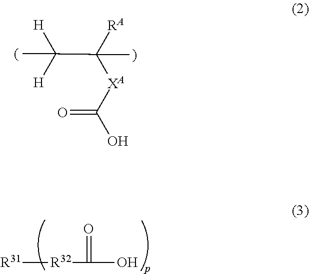

wherein R^{A} represents a hydrogen atom, a halogen atom, a methyl group, or a trifluoromethyl group; X^{A} represents a single bond, a phenylene group, a naphthylene group, or *—C(═O)—O—X^{A1}—, X^{A1} represents a saturated hydrocarbylene group, a phenylene group, or a naphthylene group, each having 1 to 10 carbon atoms, the saturated hydrocarbylene group may have a hydroxy group, an ether bond, an ester bond, or a lactone ring, and “*” represents an attachment point to a carbon atom of the main chain; “p” represents 1, 2, 3, or 4; R³¹ represents a p-valent hydrocarbon group having 1 to 40 carbon atoms or a p-valent heterocyclic group having 2 to 40 carbon atoms, and when “p” is 2, R³¹ may be an ether bond, a carbonyl group, an azo group, a thioether bond, a carbonate bond, a carbamate bond, a sulfinyl group, or a sulfonyl group; part or all of the hydrogen atoms of the p-valent hydrocarbon group or p-valent heterocyclic group may be substituted with a group having a heteroatom, and part of the —CH₂— of the p-valent hydrocarbon group may be substituted with a group having a heteroatom; R³² is a single bond or a hydrocarbylene group having 1 to 20 carbon atoms, and part or all of the hydrogen atoms of the hydrocarbylene group may be substituted with a group having a heteroatom, or part of the —CH₂— of the hydrocarbylene group may be substituted with a group having a heteroatom; and when “p” is 2, 3, or 4, R³²s may be identical to or different from each other.
[3]: The resist composition of the above [1] or [2], further comprising at least one kind of hypervalent iodine compounds represented by the following formula (4) or (5),

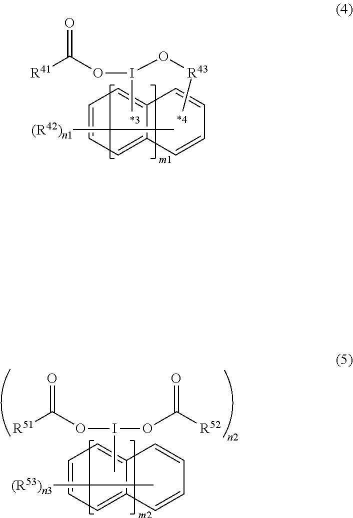

wherein m1 and m2 represent integers from 0 to 2; n1 represents an integer from 0 to 4 when m1 is 0, an integer from 0 to 6 when m1 is 1, and an integer from 0 to 8 when m1 is 2; when m2 is 0, n2 represents an integer from 1 to 3, n3 represents an integer from 0 to 5, and 1≤(n2+n3)≤6 is satisfied, when m2 is 1, n2 represents an integer from 1 to 3, and n3 represents an integer from 0 to 7, and 1≤(n2+n3)≤8 is satisfied, and when m2 is 2, n2 represents an integer from 1 to 3, and n3 represents an integer from 0 to 9, and 1≤(n2+n3)≤10 is satisfied; R⁴¹ represents a halogen atom or a hydrocarbyl group having 1 to 10 carbon atoms and optionally having a heteroatom; R⁴² represents a halogen atom or a hydrocarbyl group having 1 to 40 carbon atoms and optionally having a heteroatom, R⁴²s may be identical to or different from each other when n1 is 2 to 6, and a plurality of R⁴²s may be bonded to each other to form a ring together with the carbon atoms of the aromatic ring bonded thereto; R⁴³ is a carbonyl group or a hydrocarbylene group having 1 to 10 carbon atoms and optionally having a heteroatom; *3 and *4 represent an attachment point to a carbon atom of the aromatic ring in the formula, and *3 and *4 must be bonded to adjacent carbon atoms of the aromatic ring; R⁵¹ and R⁵² represent each independently a halogen atom or a hydrocarbyl group having 1 to 10 carbon atoms and optionally having a heteroatom, R⁵¹ and R⁵² may be bonded to each other to form a ring together with the carbon atoms bonded thereto and with an atom between the carbon atoms, and when n2 is 2 to 3, R⁵¹ and R⁵² may be identical to or different from each other; R⁵³ represents a halogen atom or a hydrocarbyl group having 1 to 40 carbon atoms and optionally having a heteroatom, R⁵³s may be identical to or different from each other when n3 is 2 to 9, and a plurality of R⁵³s may be bonded to each other to form a ring together with the carbon atoms of the aromatic ring bonded thereto.
[4]: A laminate comprising a substrate and a resist film which is a film made of the resist composition formed on the substrate of any one of the above [1] to [3].
[5]: The laminate of the above [4], further comprising a resist underlayer film between the substrate and the resist film.
[6]: The laminate of the above [4] or [5], wherein the resist film contains a product of a ligand exchange reaction between the hypervalent iodine compound and the carboxy group-containing compound.
[7]: A patterning process comprising steps of: forming a resist film on a substrate or on a resist underlayer film of a substrate having a resist underlayer film laminated thereon, using the resist composition of any one of the above [1] to [3]; exposing the resist film by a high-energy beam; and developing the exposed resist film by using a developer.
[8]: The patterning process of the above [7], wherein an i-line, a KrF excimer laser beam, an ArF excimer laser beam, an electron beam, or an extreme ultraviolet ray is used as the high-energy beam.
[9]: The patterning process of the above [7] or [8], wherein the developer used is one that dissolves exposed areas and does not dissolve unexposed areas.
[10]: The patterning process of the above [7] or [8], wherein the developer used is one that dissolves unexposed areas and does not dissolve exposed areas.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A resist composition comprising a hypervalent iodine compound represented by the following formula (1), a carboxy group-containing compound, and a solvent, 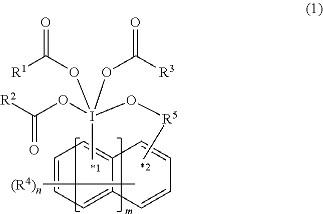
wherein “m” represents an integer of 0 to 2; “n” represents an integer of 0 to 4 when “m” is 0, an integer of 0 to 6 when “m” is 1, and an integer of 0 to 8 when “m” is 2; R¹, R², and R³ represent each independently a halogen atom or a hydrocarbyl group having 1 to 10 carbon atoms and optionally having a heteroatom, and R¹, R², and R³ may be bonded to each other to form a ring; R⁴ represents a halogen atom or a hydrocarbyl group having 1 to 40 carbon atoms and optionally having a heteroatom, R⁴s may be identical to or different from each other when “n” is 2 or greater, and a plurality of R⁴s may be bonded to each other to form a ring together with the carbon atoms of the aromatic ring bonded thereto; R⁵ represents a carbonyl group or a hydrocarbylene group having 1 to 10 carbon atoms and optionally having a heteroatom; and *1 and *2 represent an attachment point to a carbon atom of the aromatic ring in the formula, and *1 and *2 are bonded to adjacent carbon atoms of the aromatic ring.

2. The resist composition according to claim 1, wherein the carboxy group-containing compound is one or both of a polymer having a repeating unit represented by the following formula (2) and a compound represented by the following formula (3), 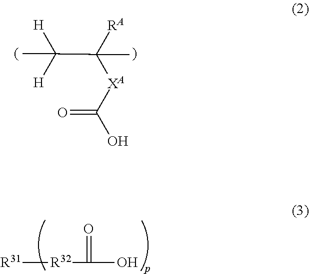
wherein R^{A} represents a hydrogen atom, a halogen atom, a methyl group, or a trifluoromethyl group; X^{A} represents a single bond, a phenylene group, a naphthylene group, or *—C(═O)—O—X^{A1}—, X^{A1} represents a saturated hydrocarbylene group, a phenylene group, or a naphthylene group, each having 1 to 10 carbon atoms, the saturated hydrocarbylene group may have a hydroxy group, an ether bond, an ester bond, or a lactone ring, and “*” represents an attachment point to a carbon atom of the main chain; “p” represents 1, 2, 3, or 4; R³¹ represents a p-valent hydrocarbon group having 1 to 40 carbon atoms or a p-valent heterocyclic group having 2 to 40 carbon atoms, and when “p” is 2, R³¹ may be an ether bond, a carbonyl group, an azo group, a thioether bond, a carbonate bond, a carbamate bond, a sulfinyl group, or a sulfonyl group; part or all of the hydrogen atoms of the p-valent hydrocarbon group or p-valent heterocyclic group may be substituted with a group having a heteroatom, and part of the —CH₂— of the p-valent hydrocarbon group may be substituted with a group having a heteroatom; R³² is a single bond or a hydrocarbylene group having 1 to 20 carbon atoms, and part or all of the hydrogen atoms of the hydrocarbylene group may be substituted with a group having a heteroatom, or part of the —CH₂— of the hydrocarbylene group may be substituted with a group having a heteroatom; and when “p” is 2, 3, or 4, R³²s may be identical to or different from each other.

3. The resist composition according to claim 1, further comprising at least one kind of hypervalent iodine compounds represented by the following formula (4) or (5), 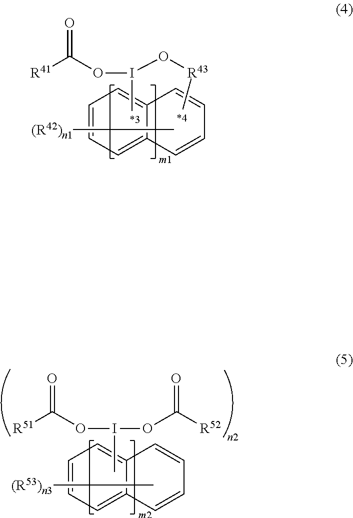
wherein m1 and m2 represent integers from 0 to 2; n1 represents an integer from 0 to 4 when m1 is 0, an integer from 0 to 6 when m1 is 1, and an integer from 0 to 8 when m1 is 2; when m2 is 0, n2 represents an integer from 1 to 3, n3 represents an integer from 0 to 5, and 1≤(n2+n3)≤6 is satisfied, when m2 is 1, n2 represents an integer from 1 to 3, and n3 represents an integer from 0 to 7, and 1≤(n2+n3)≤8 is satisfied, and when m2 is 2, n2 represents an integer from 1 to 3, and n3 represents an integer from 0 to 9, and 1≤(n2+n3)≤10 is satisfied; R⁴¹ represents a halogen atom or a hydrocarbyl group having 1 to 10 carbon atoms and optionally having a heteroatom; R⁴² represents a halogen atom or a hydrocarbyl group having 1 to 40 carbon atoms and optionally having a heteroatom, R⁴²s may be identical to or different from each other when n1 is 2 to 6, and a plurality of R⁴²s may be bonded to each other to form a ring together with the carbon atoms of the aromatic ring bonded thereto; R⁴³ is a carbonyl group or a hydrocarbylene group having 1 to 10 carbon atoms and optionally having a heteroatom; *3 and *4 represent an attachment point to a carbon atom of the aromatic ring in the formula, and *3 and *4 must be bonded to adjacent carbon atoms of the aromatic ring; R⁵¹ and R⁵² represent each independently a halogen atom or a hydrocarbyl group having 1 to 10 carbon atoms and optionally having a heteroatom, R⁵¹ and R⁵² may be bonded to each other to form a ring together with the carbon atoms bonded thereto and with an atom between the carbon atoms, and when n2 is 2 to 3, R⁵¹ and R⁵² may be identical to or different from each other; R⁵³ represents a halogen atom or a hydrocarbyl group having 1 to 40 carbon atoms and optionally having a heteroatom, R⁵³s may be identical to or different from each other when n3 is 2 to 9, and a plurality of R⁵³s may be bonded to each other to form a ring together with the carbon atoms of the aromatic ring bonded thereto.

4. The resist composition according to claim 2, further comprising at least one kind of hypervalent iodine compounds represented by the following formula (4) or (5), 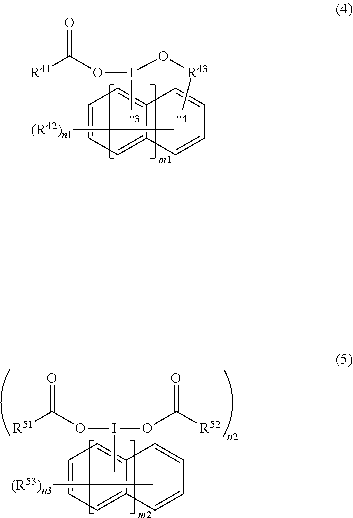
wherein m1 and m2 represent integers from 0 to 2; n1 represents an integer from 0 to 4 when m1 is 0, an integer from 0 to 6 when m1 is 1, and an integer from 0 to 8 when m1 is 2; when m2 is 0, n2 represents an integer from 1 to 3, n3 represents an integer from 0 to 5, and 1≤(n2+n3)≤6 is satisfied, when m2 is 1, n2 represents an integer from 1 to 3, and n3 represents an integer from 0 to 7, and 1≤(n2+n3)≤8 is satisfied, and when m2 is 2, n2 represents an integer from 1 to 3, and n3 represents an integer from 0 to 9, and 1≤(n2+n3)≤10 is satisfied; R⁴¹ represents a halogen atom or a hydrocarbyl group having 1 to 10 carbon atoms and optionally having a heteroatom; R⁴² represents a halogen atom or a hydrocarbyl group having 1 to 40 carbon atoms and optionally having a heteroatom, R⁴²s may be identical to or different from each other when n1 is 2 to 6, and a plurality of R⁴²s may be bonded to each other to form a ring together with the carbon atoms of the aromatic ring bonded thereto; R⁴³ is a carbonyl group or a hydrocarbylene group having 1 to 10 carbon atoms and optionally having a heteroatom; *3 and *4 represent an attachment point to a carbon atom of the aromatic ring in the formula, and *3 and *4 must be bonded to adjacent carbon atoms of the aromatic ring; R⁵¹ and R⁵² represent each independently a halogen atom or a hydrocarbyl group having 1 to 10 carbon atoms and optionally having a heteroatom, R⁵¹ and R⁵² may be bonded to each other to form a ring together with the carbon atoms bonded thereto and with an atom between the carbon atoms, and when n2 is 2 to 3, R⁵¹ and R⁵² may be identical to or different from each other; R⁵³ represents a halogen atom or a hydrocarbyl group having 1 to 40 carbon atoms and optionally having a heteroatom, R⁵³s may be identical to or different from each other when n3 is 2 to 9, and a plurality of R⁵³s may be bonded to each other to form a ring together with the carbon atoms of the aromatic ring bonded thereto.

5. A laminate comprising a substrate and a resist film which is a film made of the resist composition formed on the substrate according to claim 1.

6. A laminate comprising a substrate and a resist film which is a film made of the resist composition formed on the substrate according to claim 2.

7. A laminate comprising a substrate and a resist film which is a film made of the resist composition formed on the substrate according to claim 3.

8. The laminate according to claim 5, further comprising a resist underlayer film between the substrate and the resist film.

9. The laminate according to claim 6, further comprising a resist underlayer film between the substrate and the resist film.

10. The laminate according to claim 5, wherein the resist film contains a product of a ligand exchange reaction between the hypervalent iodine compound and the carboxy group-containing compound.

11. The laminate according to claim 6, wherein the resist film contains a product of a ligand exchange reaction between the hypervalent iodine compound and the carboxy group-containing compound.

12. A patterning process comprising steps of:
forming a resist film on a substrate or on a resist underlayer film of a substrate having a resist underlayer film laminated thereon, using the resist composition according to claim 1;
exposing the resist film by a high-energy beam; and
developing the exposed resist film by using a developer.

13. A patterning process comprising steps of:
forming a resist film on a substrate or on a resist underlayer film of a substrate having a resist underlayer film laminated thereon, using the resist composition according to claim 2;
exposing the resist film by a high-energy beam; and
developing the exposed resist film by using a developer.

14. A patterning process comprising steps of:
forming a resist film on a substrate or on a resist underlayer film of a substrate having a resist underlayer film laminated thereon, using the resist composition according to claim 3;
exposing the resist film by a high-energy beam; and
developing the exposed resist film by using a developer.

15. The patterning process according to claim 12, wherein an i-line, a KrF excimer laser beam, an ArF excimer laser beam, an electron beam, or an extreme ultraviolet ray is used as the high-energy beam.

16. The patterning process according to claim 13, wherein an i-line, a KrF excimer laser beam, an ArF excimer laser beam, an electron beam, or an extreme ultraviolet ray is used as the high-energy beam.

17. The patterning process according to claim 12, wherein the developer used is one that dissolves exposed areas and does not dissolve unexposed areas.

18. The patterning process according to claim 15, wherein the developer used is one that dissolves exposed areas and does not dissolve unexposed areas.

19. The patterning process according to claim 12, wherein the developer used is one that dissolves unexposed areas and does not dissolve exposed areas.

20. The patterning process according to claim 15, wherein the developer used is one that dissolves unexposed areas and does not dissolve exposed areas.
